(19) United States
(12) Patent Application Publication
(10) Pub. No.: US 2018/0136379 A1
(43) Pub. Date: May 17, 2018

(54) LAMINATE, SOLID-STATE IMAGING DEVICE, METHOD FOR PRODUCING LAMINATE, AND KIT

(71) Applicant: FUJIFILM Corporation, Tokyo (JP)

(72) Inventors: Hirotaka TAKISHITA, Kanagawa (JP); Kazuto SHIMADA, Kanagawa (JP); Keisuke ARIMURA, Kanagawa (JP); Takahiro OKAWARA, Kanagawa (JP); Daisuke SASAKI, Kanagawa (JP); Keiji YAMAMOTO, Kanagawa (JP); Masaru YOSHIKAWA, Kanagawa (JP); Ryoji GOTO, Kanagawa (JP)

(73) Assignee: FUJIFILM Corporation, Tokyo (JP)

(21) Appl. No.: 15/853,859

(22) Filed: Dec. 25, 2017

Related U.S. Application Data
(63) Continuation of application No. PCT/JP2016/061382, filed on Apr. 7, 2016.

(30) Foreign Application Priority Data
Jul. 30, 2015 (JP) 2015-151334
Mar. 29, 2016 (JP) 2016-066281

(51) Int. Cl. G02B 5/20; B32B 7/02; G02B 1/113; G02B 1/02; G02B 5/26; H01L 27/146

(52) U.S. Cl. CPC G02B 5/208; B32B 7/02; G02B 1/113; B32B 2307/418; G02B 5/26; H01L 27/1462; H01L 27/14685; G02B 1/02

(57) ABSTRACT

Provided are a laminate having an antireflection layer including inorganic particles, and an infrared light reflecting layer, in which the infrared light reflecting layer includes a first selective reflection layer which is formed by fixing a liquid crystal phase having a helical axis which rotates in a right direction, and a second selective reflection layer which is formed by fixing a liquid crystal phase having a helical axis which rotates in a left direction, a method for producing the laminate, a solid-state imaging device including the laminate, and a kit used for producing the laminate.

### CROSS-REFERENCE TO RELATED APPLICATIONS

This application is a Continuation of PCT International Application No. PCT/JP2016/061382, filed on Apr. 7, 2016, which claims priority under 35 U.S.C. § 119(a) to Japanese Patent Application No. 2015-151334, filed on Jul. 30, 2015, and Japanese Patent Application No. 2016-66281, filed on Mar. 29, 2016. Each of the above application(s) is hereby expressly incorporated by reference, in its entirety, into the present application.

### BACKGROUND OF THE INVENTION

### 1. Field of the Invention

The present invention relates to a laminate, a solid-state imaging device, a method for producing a laminate, and a kit.

### 2. Description of the Related Art

In a video camera, a digital still camera, a cellular phone with a camera function, and the like, a charge coupled device (CCD) or a complementary metal oxide semiconductor (CMOS), which is a solid-state imaging device for a color image is used. In such a solid-state imaging device, typically, a silicon photodiode having sensitivity to infrared light in a light receiving portion thereof is used. Therefore, visibility correction is required and an infrared light cut filter is frequently used.

As the infrared light cut filter, there is an infrared light cut filter in which an infrared light reflecting film is formed on the surface of a transparent substrate of glass or the like. The infrared light reflecting film is required to have a high transmittance with respect to light having a visible wavelength and from this viewpoint, as the infrared light reflecting film, a dielectric multilayer film in which a plurality of layers of high refractive index material and low refractive index material are laminated is used (refer to JP2011-100084A).

### SUMMARY OF THE INVENTION

On the other hand, in the dielectric multilayer film disclosed in JP2011-100084A, a layer of high refractive index material and a layer of low refractive index material are formed by vapor deposition. Thus, it requires time and effort for production and the cost increases.

In addition, in recent years, along with an increasing demand for performance requirements for a solid-state imaging device, the requirement characteristics demand for an infrared light cut filter have been also increased. Particularly, it is required to make the transmittance in a visible light range higher than the transmittance in an infrared range.

The present invention has been made in consideration of the above circumstances and an object thereof is to provide a laminate which can be easily produced and has a higher transmittance in a visible light range than in an infrared range.

Another object of the present invention is to provide a method for producing the laminate, a solid-state imaging device including the laminate, and a kit used for producing the laminate.

As a result of conducting intensive investigations to achieve the above objects, the present inventors have found that the above objects can be achieved by using an antireflection layer and a predetermined infrared light reflecting layer and thus have completed the present invention.

That is, the present inventors have found that the above objects can be achieved by adopting the following constitutions.

(1) A laminate comprising: an antireflection layer having a refractive index of 1.45 or less; and an infrared light reflecting layer, in which the infrared light reflecting layer includes a first selective reflection layer which is formed by fixing a liquid crystal phase having a helical axis which rotates in a right direction, and a second selective reflection layer which is formed by fixing a liquid crystal phase having a helical axis which rotates in a left direction.

(2) The laminate according to (1), in which at least one of the first selective reflection layer or the second selective reflection layer includes a liquid crystal compound having a refractive index anisotropy Δn of 0.25 or more at 30° C.

(3) The laminate according to (1) or (2), in which at least one of the first selective reflection layer or the second selective reflection layer is a layer that is formed by using a compound represented by Formula (5),

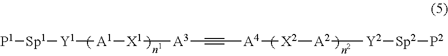

in Formula (5), A¹ to A⁴ each independently represent an aromatic carbon ring or heterocyclic ring which may have a substituent; X¹ and X² each independently represent a single bond, —COO—, —OCO—, —CH₂CH₂—, —OCH₂—, —CH₂O—, —CH═CH—, —CH═CH—COO—, —OCO—CH═CH—, or —C≡C—; Y¹ and Y² each independently represent a single bond, —O—, —S—, —CO—, —COO—, —OCO—, —CONH—, —NHCO—, —CH═CH—, —CH═CH—COO—, —OCO—CH═CH—, or —C≡C—; Sp¹ and Sp² each independently represent a single bond, or a carbon chain having 1 to 25 carbon atoms; P¹ and P² each independently represent a hydrogen atom or a polymerizable group; at least one of P¹ or P² represents a polymerizable group; n¹ and n² each independently represent an integer of 0 to 2; and in a case where n¹ or n² is 2, a plurality of A^{1'}s, A^{2'}s, X^{1'}s and X^{2'}s may be the same as each other or different from each other.

(4) The laminate according to any one of (1) to (3), in which the antireflection layer or the infrared light reflecting layer includes an infrared absorber, or an infrared light absorbing layer including an infrared absorber is further provided.

(5) The laminate according to (4), in which the infrared absorber has maximum absorption in a wavelength range of 600 to 1200 nm.

(6) The laminate according to any one of (1) to (5), in which the antireflection layer includes inorganic particles.

(7) The laminate according to (6), in which the inorganic particles are formed of silica.

(8) The laminate according to (6) or (7), in which a content of the inorganic particles with respect to a total mass of the antireflection layer is 70% by mass or more.

(9) The laminate according to any one of (1) to (8), in which the antireflection layer is a layer that is formed by using a particle aggregate in which a plurality of silica particles are linked in a chain shape.

(10) The laminate according to any one of (1) to (9), in which the antireflection layers are respectively arranged on both surfaces of the infrared light reflecting layer.

(11) The laminate according to any one of (1) to (10), in which a refractive index of the antireflection layer is 1.35 or less.

(12) The laminate according to any one of (1) to (11), in which a refractive index of the antireflection layer is 1.25 or less.

(13) The laminate according to any one of (1) to (12), further comprising: a base layer which is arranged to be adjacent to the infrared light reflecting layer.

(14) The laminate according to any one of (1) to (13) used for an infrared light (infrared ray) cut filter.

(15) A solid-state imaging device comprising: the laminate according to any one of (1) to (14).

(16) A method for producing the laminate according to (4) comprising: a step of applying a liquid crystal composition including at least a liquid crystal compound and a right rotation chiral agent, and a liquid crystal composition including at least a liquid crystal compound and a left rotation chiral agent in a random order to form the infrared light reflecting layer; a step of applying an infrared light absorbing composition including an infrared absorber to the infrared light reflecting layer to form the infrared light absorbing layer; and a step of applying an antireflection layer forming composition including inorganic particles to the infrared light absorbing layer to form the antireflection layer.

(17) A kit comprising: a liquid crystal composition including at least a liquid crystal compound and a right rotation chiral agent; a liquid crystal composition including at least a liquid crystal compound and a left rotation chiral agent; an infrared light absorbing composition including an infrared absorber; and an antireflection layer forming composition including inorganic particles.

According to the present invention, it is possible to provide a laminate which can be easily produced and has a higher transmittance in a visible light range than in an infrared range.

In addition, according to the present invention, it is possible to provide a method for producing the laminate, a solid-state imaging device including the laminate, and a kit used for producing the laminate.

### BRIEF DESCRIPTION OF THE DRAWINGS

FIG. 1 is a cross-sectional view of a laminate according to a first embodiment of the present invention.

FIG. 2 is a cross-sectional view of a laminate according to a second embodiment of the present invention.

FIG. 3 is a cross-sectional view of a laminate according to a third embodiment of the present invention.

FIG. 4 is a transmission spectrum diagram of cholesteric liquid crystal films (FR1), (FR2), (FR3), and (FR4) prepared in examples.

FIG. 5 is a transmission spectrum diagram of cholesteric liquid crystal films (FL1), (FL2), (FL3), and (FL4) prepared in examples.

### DESCRIPTION OF THE PREFERRED EMBODIMENTS

Hereinafter, preferred aspects of a laminate will be described.

The description of elements described below will be made based on representative embodiments of the present invention, but the present invention is not limited to those embodiments. In addition, the numerical value range expressed by using “to” in the present specification means a range including the numerical values described before and after “to” as the lower limit and the upper limit, respectively.

The term “infrared light” used in the present specification means light at least in a range of about 700 to 1200 nm although the wavelength varies depending on the sensitivity a solid-state imaging device. In addition, the term “visible light” means light at least in a range of 400 to 700 nm.

Incidentally, the term “group (atom group)” as used in the present specification is intended to include both unsubstituted and substituted ones unless designated as “unsubstituted” or “substituted”. For example, the term “alkyl group” includes not only an alkyl group having no substituent (an unsubstituted alkyl group) but also an alkyl group having a substituent (a substituted alkyl group).

### First Embodiment

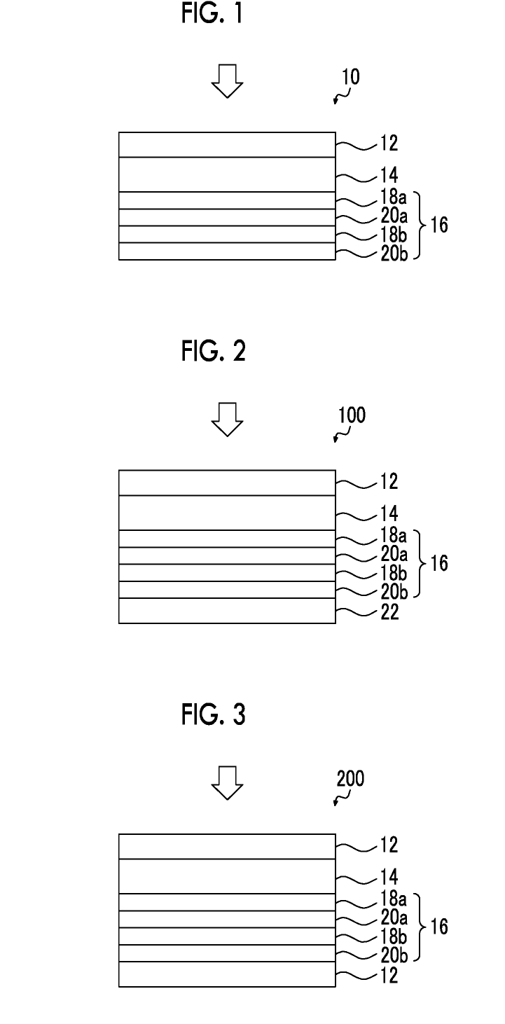

FIG. 1 shows a cross-sectional view of a laminate according to a first embodiment of the present invention.

As shown in FIG. 1, a laminate 10 includes an antireflection layer 12, an infrared light absorbing layer 14, and an infrared light reflecting layer 16 in this order. The infrared light reflecting layer 16 includes first selective reflection layers 18a and 18b formed by fixing a liquid crystal phase having a helical axis which rotates in a right direction and second selective reflection layers 20a and 20b formed by fixing a liquid crystal phase having a helical axis which rotates in a left direction.

In a case where light is incident on the laminate 10 in a direction indicated by a white arrow shown in FIG. 1, the antireflection layer 12 is the outermost layer and thus the light (particularly, visible light) to be reflected on the surface of the laminate 10 is reduced. In addition, infrared light of light which passes through the antireflection layer 12 is absorbed by the infrared light absorbing layer 14 or reflected by the infrared light reflecting layer 16. As a result, visible light easily penetrates the laminate 10 and infrared light does not easily penetrate the laminate 10, thereby obtaining a desired effect.

Hereinafter, each member constituting the laminate 10 will be described in detail.

<Antireflection Layer 12>

The antireflection layer 12 is arranged on a side close to the outermost layer of the laminate 10 and reduces light to be reflected on the surface of the laminate 10.

The refractive index of the antireflection layer 12 is 1.45 or less, and is preferably 1.35 or less, more preferably less than 1.30, and even more preferably 1.25 or less from the viewpoint of further increasing the transmittance of the laminate in a visible light range. Although the lower limit is not particularly limited, typically, the lower limit is 1.00 or more in many cases and is 1.20 or more in many cases. The refractive index means a refractive index at a wavelength of 633 nm as described below.

The refractive index of the antireflection layer 12 is measured using an ellipsometer (VUV-vase [trade name] manufactured by J.A. Woollam CO.) (at a wavelength of 633 nm and a measurement temperature of 25° C.).

The material constituting the antireflection layer 12 is not particularly limited and organic materials or inorganic materials may be used. From the viewpoint of durability, it is preferable to use inorganic materials (for example, inorganic resin (siloxane resin) and inorganic particles). Among these, it is preferable that the antireflection layer 12 includes inorganic particles.

The siloxane resin can be obtained through a hydrolysis reaction and a condensation reaction using a known alkoxysilane material.

For the hydrolysis reaction and the condensation reaction, known methods can be used, and as necessary, a catalyst of acid or base may be used. The catalyst is not particularly limited and any catalyst may be used as long as the catalyst can change a pH. Specifically, examples of acid (organic acid or inorganic acid) include nitric acid, oxalic acid, acetic acid, formic acid, and hydrochloric acid. Examples of alkali include ammonia, triethylamine, and ethylenediamine.

As necessary, a solvent may be added to a reaction system of the hydrolysis reaction and the condensation reaction. The solvent is not particularly limited as long as the hydrolysis reaction and the condensation reaction can be conducted. Examples of the solvent include water, alcohols such as methanol, ethanol, and propanol, ethers such as ethylene glycol monomethyl ether, ethylene glycol monoethyl ether, and ethylene glycol monopropyl ether, esters such as methyl acetate, ethyl acetate, butyl acetate, and propylene glycol monomethyl ether acetate, and ketones such as acetone, methyl ethyl ketone, methyl isobutyl ketone and methyl isoamyl ketone.

As for the conditions (temperature, time, and amount of solvent) for the hydrolysis reaction and the condensation reaction, optimum conditions are appropriately selected in accordance with the kind of materials to be used.

The weight-average molecular weight of the siloxane resin is preferably 1000 to 50000. In the range, the weight-average molecular weight is more preferably 2000 to 45000, even more preferably 2500 to 25000, and particularly preferably 3000 to 25000. In a case where the weight-average molecular weight is equal to or more than the lower limit, the coatability to a substrate is particularly satisfactory and the surface state and flatness after coating is preferably maintained at a satisfactory level.

The weight-average molecular weight is a value that is obtained by measurement using a known gel permeation chromatography (GPC) and standard polystyrene conversion. Unless indicated differently, the GPC measurement is conducted as follows. Waters 2695 and GPC column KF-805 L (3 columns in tandem) manufactured by Shodex are used as columns. To the column having a column temperature of 40° C., 50 μl of a tetrahydrofuran solution having a sample concentration of 0.5% by mass is poured. Tetrahydrofuran is caused to flow as an eluate solvent at the flow rate of 1 ml per minute. A sample peak is detected using a differential refractive index (RI) detecting device (Waters 2414) and an ultraviolet (UV) detecting device (Waters 2996).

Examples of the material constituting the inorganic particle include silica (silicon oxide), lanthanum fluoride, calcium fluoride, magnesium fluoride, and cerium fluoride. More specifically, preferable examples of the inorganic particles include silica particles hollow silica particles, and porous silica particles. The term “hollow particles” refers to particles having a structure having a cavity inside, the cavity being surrounded by an outer shell. The term “porous particles” refers to porous particles having a large number of cavities.

The inorganic particles may be used alone or may be used in combination of two or more thereof.

The particle diameter of the inorganic particles is not particularly limited and from the viewpoint of handleability, the average particle diameter is preferably 1 nm or more and more preferably 10 nm or more. The upper limit is preferably 200 nm or less and more preferably 100 nm or less.

Herein, the average particle diameter of the inorganic particles can be obtained by a micrograph obtained by observing the inorganic particles with a transmission electron microscope. Projected areas of the inorganic particles are obtained and an equivalent circle diameter is obtained from the projected areas and is defined as the average particle diameter. For the term “average particle diameter” in the present specification, projected areas of 300 or more particles are measured and an equivalent circle diameter is obtained to calculate a number average particle diameter thereof.

The content of the inorganic particles in the antireflection layer 12 is not particularly limited and is 70% by mass or more in many cases. From the viewpoint of further increasing the transmittance of the laminate in a visible light range and improving the solvent resistance of the laminate, the content is preferably 80% by mass or more, more preferably 90% by mass or more, and even more preferably 95% by mass or more. The upper limit is not particularly limited and may be 100% by mass.

The refractive index of the inorganic particles is preferably 1.00 to 1.45, more preferably 1.10 to 1.40, even more preferably 1.15 to 1.35, and particularly preferably 1.15 to 1.30 from the viewpoint of further increasing the transmittance of the laminate in a visible light range.

In the present specification, the refractive index of the inorganic particles can be measured by the following method. Mixed solution samples of a matrix resin and inorganic particles having a concentration of solid contents of 10% in which the content of the inorganic particles is controlled to 0% by mass, 20% by mass, 30% by mass, 40% by mass, and 50% by mass are prepared. Each of the mixed solution samples is applied to on a silicon wafer by using a spin coater so as to have a thickness of 0.3 to 1.0 μm. Subsequently, the mixed solution is heated and dried on a hot plate at 200° C. for 5 minutes to obtain a coating film. Next, for example, the refractive index of the inorganic particles can be obtained by obtaining the refractive index of the coating film using an ellipsometer (VUV-vase [trade name] manufactured by J.A. Woollam CO.) at a wavelength of 633 nm (25° C.), and extrapolating a value of 100% by mass of the inorganic particles.

The average thickness of the antireflection layer 12 is not particularly limited and is preferably 0.01 to 1.00 μm and more preferably 0.05 to 0.5 μm from the viewpoint of further increasing the transmittance of the laminate in a visible light range.

The average thickness is a value obtained by measuring the thickness of the antireflection layer 12 at arbitrary 10 points or more and arithmetically averaging the thickness values.

As necessary, the antireflection layer 12 may include components other than the inorganic particles and may include, for example, a so-called binder such as fluororesin or polysiloxane (particularly, a binder of low refractive index).

In FIG. 1, the antireflection layer 12 has a single layer structure but may have a laminated structure as necessary.

(Method for Producing Antireflection Layer)

The method for producing the antireflection layer 12 is not particularly limited and examples thereof include a dry method (for example, a sputtering method and a vacuum vapor deposition), and a wet method (for example, a coating method). From the viewpoint of productivity, a wet method is preferable.

For example, as the wet method, a method of applying an antireflection layer forming composition including an inorganic material (preferably inorganic particles) to a predetermined substrate and as necessary, performing a drying treatment to produce an antireflection layer may be suitably used.

The content of the inorganic particles in the antireflection layer forming composition is not particularly limited and is preferably 10% to 50% by mass, more preferably 15% to 40% by mass, and even more preferably 15% to 30% by mass.

In addition, a solvent (water or an organic solvent) is appropriately included in the antireflection layer forming composition.

As the coating method, a spin coating method, a dip coating method, a roller blade method, a spray method, and the like can be applied.

The method of the drying treatment is not particularly limited and heating treatment or air drying treatment may be used. Heating treatment is preferable. The conditions for the heating treatment are not particularly limited and the temperature is preferably 50° C. or higher, more preferably 65° C. or higher, and even more preferably 70° C. or higher. The upper limit is preferably 200° C. or lower, more preferably 150° C. or lower, and even more preferably 120° C. or lower. The heating time is not particularly limited and is preferably 0.5 minutes or more and 60 minutes or less and more preferably 1 minute or more and 10 minutes or less.

The method of the heating treatment is not particularly limited and heating can be performed by using a hot plate, an oven, a furnace, and the like.

The atmosphere at the time of the heating treatment is not particularly limited and an inert atmosphere, an oxidizing atmosphere, and the like can be applied. The inert atmosphere can be realized by inert gases such as nitrogen, helium, and argon. The oxidizing atmosphere can be realized by using mixed gases of these inert gases and oxidizing gases and may be realized by using air. Examples of the oxidizing gases include oxygen, carbon monoxide, and oxygen dinitride. The heating treatment can be performed under any of increased pressure, normal pressure, reduced pressure, or vacuum pressure.

(Preferred Aspects)

As a preferred aspect of the antireflection layer 12, a layer that is formed by using a particle aggregate in which a plurality of silica particles are linked in a chain shape (hereinafter, also referred to as bead-like silica) may be adopted from the viewpoint of enhancing the solvent resistance of the laminate by further increasing the transmittance of the laminate in a visible light range. More specifically, it is more preferable to use a composition (sol) in which bead-like silica is dispersed in a solvent.

In general, as the silica particles included in silica sol, in addition to bead-like silica particles, spherical, needle-like, and plate-like silica particles are widely known and in the embodiment, it is preferable to use a composition (silica sol) in which bead-like silica is dispersed in a solvent. By using the bead-like silica, holes can be easily formed in an antireflection layer to be formed and the refractive index can be decreased.

The bead-like silica is preferably silica obtained by bonding a plurality of silica particles having an average particle diameter of 5 to 50 nm (preferably 5 to 30 nm) with metal oxide-containing silica.

In addition, it is preferable that a ratio D₁/D₂ between the number average particle diameter (D₁ nm) of the silica particles measured by a dynamic light scattering method and the average particle diameter (D₂ nm) from the specific surface area Sm²/g of the silica particles measured by a nitrogen adsorption method by Equation D₂=2720/S of the bead-like silica is 3 or more, D₁ is 30 to 300 nm, and the silica particles are linked in only one plane. From the viewpoint that the particles are hardly aggregate and an increase in haze of the antireflection layer can be suppressed, D₁/D₂ is preferably 3 to 20. D₁ is preferably 35 to 150 nm.

In addition, examples of the metal oxide-containing silica for bonding silica particles include amorphous silica or amorphous alumina. Examples of the solvent in which the bead-like silica is dispersed include methanol, ethanol, isopropyl alcohol (IPA), ethylene glycol, propylene glycol monomethyl ether, and propylene glycol monomethyl ether acetate. A solvent having a SiO₂ concentration of 5% to 40% by mass is preferable.

Examples of the composition (silica sol) containing the bead-like silica include a silica sol disclosed in JP4328935B or JP2013-253145A.

As the method for producing the antireflection layer using the composition containing the bead-like silica, the above-described wet method can be appropriately adopted.

In addition, the antireflection layer can be formed by using a commercially available material of low refractive index. Examples of the commercially available material of low refractive index, OPSTAR-TU series manufactured by JSR Corporation, low refractive index polysiloxane LS series manufactured by Toray Industries, Inc., and fluorine resin CYTOP series manufactured by Asahi Glass Co., Ltd.

<Infrared Light Absorbing Layer>

The infrared light absorbing layer 14 is a layer that absorbs infrared light. By the laminate being including the infrared light absorbing layer 14, the angular dependence can be reduced. The term “angular dependence” indicates a difference between the transmission characteristics of light incident on the laminate from a front direction and the transmission characteristics of light incident on the laminate in an oblique direction. For example, a large angular dependence means that a difference between the transmission characteristics of light is large, that is, a difference in transmission characteristics depending on the light incidence direction is large, and a small angular dependence means that a difference between the transmission characteristics of light is small, that is, a difference in transmission characteristics depending on the light incidence direction is small.

The infrared light absorbing layer 14 is an arbitrary constituent member.

The infrared light absorbing layer 14 includes an infrared absorber. The term “infrared absorber” means a compound having a peak in an infrared light wavelength range.

The infrared absorber is preferably a compound having a maximum absorption wavelength in a wavelength range of 600 to 1200 nm. The maximum absorption wavelength can be measured by, for example, using a Cary 5000 UV-Vis-NIR (spectrophotometer, manufactured by Agilent Technologies).

The content of the infrared absorber in the infrared light absorbing layer 14 is not particularly limited and is preferably 1% to 80% by mass and more preferably 5% to 60% by mass with respect to the total mass of the infrared light absorbing layer 14.

In the present invention, the infrared absorber is preferably an organic dye. In the present invention, the term “organic dye” means a dye consisting of an organic compound.

In addition, the infrared absorber is preferably at least one selected from a copper compound, a cyanine compound, a pyrrolopyrrole compound, a squarylium compound, a phthalocyanine compound, and a naphthalocyanine compound, and is more preferably a copper compound, a cyanine compound, or a pyrrolopyrrole compound.

In the present invention, the infrared absorber is preferably a compound that is dissolved in water at 25° C. in an amount of 1% by mass or more and more preferably a compound that is dissolved in water at 25° C. in an amount of 10% by mass or more. The use of such a compound improves solvent resistance.

A copper compound, a cyanine compound, and a pyrrolopyrrole compound, which are preferred aspects of the infrared absorber, will be described in detail below.

<Copper Compound>

The copper compound is a copper compound having a maximum absorption wavelength in a wavelength range of 700 to 1200 nm (in a near infrared range).

The copper compound may be a copper complex or may not be a copper complex. The copper compound is preferably a copper complex.

In a case where the copper compound used in the present invention is a copper complex, a ligand L coordinated to copper is not specifically limited so long the ligand can form a coordinate bond with copper ions, and examples thereof include sulfonic acids, phosphoric acids, phosphoric acid esters, phosphonic acids, phosphonic acid esters, phosphinic acids, phosphinic acid esters, carboxylic acids, and compounds containing carbonyl (esters, ketones), amine, amide, sulfonamide, urethane, urea, alcohol or thiol and the like.

Specifically, phosphorus-containing copper compounds include the compounds described at, for example, page 5, line 27 to page 7, line 20 of WO2005/030898A, and the contents thereof are incorporated in the present specification by reference.

In addition, the copper compound may be a compound represented by Formula (A).

Cu(L)ₙ₁·(X)ₙ₂ Formula (A)

In Formula (A), L represents a ligand coordinated to copper, X is absent or represents a counter ion to neutralize the electric charge of the copper complex, as necessary. n1 and n2 each independently represent an integer of 0 or more.

The ligand L has a substituent containing an atom capable of being coordinated to copper such as a C atom, a N atom, an O atom, or a S atom, and more preferably the ligand has a group containing a lone pair of electrons such as a N atom, an O atom or a S atom. Preferable ligands L are as defined above for the ligand L. The ligand may contain one or more than one group capable of being coordinated to copper in the molecule, and may be dissociated or not.

As the counter ions, counter ions included in the copper complex described layer, and will be described in detail later.

(Copper Complex)

The copper complex is preferably a compound having a maximum absorption wavelength in a wavelength range of 700 to 1200 nm. The maximum absorption wavelength of the copper complex is more preferably in a wavelength range of 720 to 1200 nm and even more preferably in a wavelength range of 800 to 1100 nm.

The molar light absorption coefficient of the copper complex at the maximum absorption wavelength in the above-described wavelength range is preferably 120 (L/mol·cm) or more, more preferably 150 (L/mol·cm) or more, even more preferably 200 (L/mol·cm) or more, still even more preferably 300 (L/mol·cm) or more, and particularly preferably 400 (L/mol·cm) or more. The upper limit is not particularly limited and can be set to, for example, 30000 (L/mol·cm) or less. In a case where the molar light absorption coefficient of the copper complex is 100 (L/mol·cm) or more, an infrared light absorbing layer having excellent infrared light blocking performance can be formed as a thin film.

The gram light absorption coefficient of the copper complex at 800 nm is preferably 0.11 (L/g·cm) or more, more preferably 0.15 (L/g·cm) or more, and even more preferably 0.24 (L/g·cm) or more.

In the present invention, the molar light absorption coefficient and the gram light absorption coefficient of the copper complex can be obtained such a manner that the copper complex is dissolved in a solvent to prepare a solution having a concentration of 1 g/L, and the absorption spectrum of the solution in which the copper complex is dissolved is measured. As a measurement device, UV-1800 (wavelength range of 200 to 1100 nm) manufactured by Shimadzu Corporation, or Cary 5000 (wavelength range of 200 to 1300 nm) manufactured by Agilent Technologies, Inc. can be used. Examples of a measurement solvent include water, N, N-dimethylformamide, propylene glycol monomethyl ether, 1,2,4-trichlorobenzene, and acetone. In the present invention, among the above-described measurement solvents, a solvent that can dissolve the copper complex of an object to be measured is selected and used. Among these, in a case of a copper complex that dissolves in propylene glycol monomethyl ether, propylene glycol monomethyl ether is preferably used as the measurement solvent. The term “dissolving” means a state in which solubility of the copper complex with respect to the solvent at 25° C. is more than 0.01 g/100 g Solvent.

In the present invention, the molar light absorption coefficient and the gram light absorption coefficient of the copper complex are preferably values measured by using any one of the measurement solvents described above and more preferably values measured by using propylene glycol monomethyl ether.

Examples of a method for setting the molar light absorption coefficient of the copper complex to 100 (L/mol·cm) or more include a method using a pentacoordinate copper complex, a method using a ligand having high π donation, and a method using a copper complex having low symmetry.

A mechanism of achieving a molar light absorption coefficient of 100 (L/mol·cm) or more by using a pentacoordinate copper complex is assumed as follows. That is, in a case where a pentacoordinate copper complex, preferably a pentacoordinate copper complex having a trigonal bipyramidal structure, or a pentacoordinate copper complex having a square pyramidal structure) is used, the symmetry of the complex decreases. Accordingly, a mixed state of a p orbital and a d orbital is easily obtained in a mutual interaction between the ligand and copper. At this time, d-d transition (absorption in the infrared range) is no more pure d-d transition and p-d transition which is allowed transition is mixed therewith. Accordingly, it is thought that the molar light absorption coefficient is improved and can be 100 (L/mol·cm) or more.

The pentacoordinate copper complex can be prepared, for example, by causing two bidentate ligands (may be the same as each other or different from each other) and one unidentate ligand to react with copper ion, by causing one tridentate ligands and two bidentate ligands (may be the same as each other or different from each other) to react with copper ion, by causing one tridentate ligand and one bidentate ligand to react with copper ion, by causing one quadridentate ligand and one unidentate ligand to react with copper ion, or by causing one pentadentate ligand to react with copper ion. At this time, a unidentate ligand performing coordination by an unshared electron pair may be used as a reaction solvent. For example, when two bidentate ligands are reacted with copper ion in a solvent including water, a pentacoordinate complex in which the two bidentate ligands and water as a unidentate ligand are coordinated is obtained.

In addition, a mechanism of achieving a molar light absorption coefficient of 100 (L/mol·cm) or more by using a ligand having high π donation is assumed as follows. That is, when a ligand having high π donation (a ligand in which a π orbital or p orbital of the ligand is at a position having low energy) is used, a mixed state of a p orbital of metal and a p orbital (or π orbital) of the ligand is easily obtained. At this time, d-d transition is no more pure d-d transition and ligand to metal charge transfer (LMCT) transition which is allowed transition is mixed therewith. Accordingly, it is thought that the light absorption coefficient is improved and can be 100 (L/mol·cm) or more.

Examples of the ligand having high π donation include a halogen ligand, an oxygen anion ligand, and a sulfur anion ligand. As a copper complex using the ligand having high π donation, for example, a copper complex including Cl ligands as unidentate ligands is used.

In addition, a copper complex having low symmetry can be obtained by using ligands having low symmetry or by asymmetrically introducing ligands to copper ion. For example, specific descriptions are as follows.

For examples, in a case of using a tridentate ligand L¹-L²-L³ and two unidentate ligands L⁴ and L⁵, a copper complex having low symmetry is obtained by using a ligand having low symmetry, for example, a ligand in which L¹ and L³ are different from each other, as shown in Formula (1). In addition, in a case where the ligands are asymmetrically introduced with respect to the copper ion, for example, in a case where L⁴ and L⁵ are different from each other, a copper complex having low symmetry is obtained, rather than in a case where L⁴ and L⁵ are the same as each other.

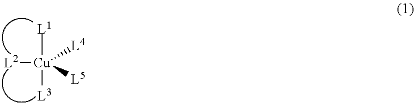

In a case where L⁴ and L⁵ are the same as each other in a square pyramidal complex, a complex having low symmetry is obtained, in a case where L⁴ and L⁵ are adjacent to each other on a bottom surface of the square pyramid as shown in Formula (3) or one unidentate ligand is on the top of the square pyramid as shown in Formula (4), rather than in a case where L⁴ and L⁵ are on a diagonal line on the bottom surface of the square pyramid as shown in Formula (2)

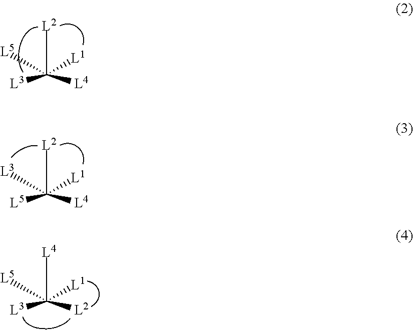

In a case of using two bidentate ligands L⁶-L⁷ and L⁸-L⁹ and a unidentate ligand L¹⁰, a copper complex having low symmetry is obtained by using ligands having low symmetry, for example, by using a ligand in which L⁶ and L⁷ are different from each other and/or a ligand in which L⁸ and L⁹ are different from each other, as shown in Formula (5).

In addition, in a case where the ligands are asymmetrically introduced with respect to the copper ion, for example, in a case where L⁶-L⁷ and L⁸-L⁹ are different from each other, a copper complex having low symmetry is obtained, rather than in a case where L⁶-L⁷ and L⁸-L⁹ are the same as each other. In a case where L⁶-L⁷ and L⁸-L⁹ are the same as each other, a copper complex having low symmetry is obtained, in a case where L⁶=L⁹ and L⁷=L⁸, rather than in a case where L⁶=L⁸ and L⁷=L9.

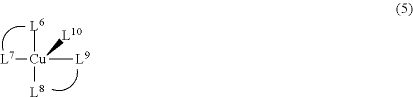

The copper complex is preferably a compound having at least two or more coordination sites (hereinafter, also referred to as a compound (A)) as the ligand. The compound (A) is more preferably has at least three or more coordination sites and even more preferably 3 to 5 coordination sites. The compound (A) functions as a chelating ligand with respect to a copper component. That is, it is considered that at least two coordination atoms of the compound (A) chelating-coordinates with copper, the structure of the copper complex is thus distorted, high transmittance in a visible light range is obtained, infrared light absorption power is improved, and a color valency is also improved. Accordingly, even in a case where the laminate is used for a long period of time, the characteristics thereof are not deteriorated, and it is also possible to stably produce a camera module.

The copper complex may include two or more compounds (A). In a case of having two or more compounds (A), the respective compounds (A) may be the same as each other or different from each other.

As the coordination site of the compound (A), a coordination site performing coordination by an anion, a coordination site performing coordination by an unshared electron pair, and the like may be used.

As the copper complex, a tetracoordinate copper complex, a pentacoordinate copper complex, and a hexacoordinate copper complex are exemplified, a tetracoordinate copper complex and a pentacoordinate copper complex are more preferable, and a pentacoordinate copper complex is even more preferable.

In addition, in the copper complex, it is preferable that a 5-membered ring and/or a 6-membered ring is formed by copper and ligands. Such a copper complex has a stable form and has excellent complex stability.

For example, the copper in the copper complex used in the present invention can be obtained by mixing and reacting the compound (A) with a copper component (copper or a compound containing copper).

The copper component is preferably a compound containing divalent copper. Only one copper component may be used or two or more copper components may be used.

For example, as the copper component, copper oxide or a copper salt can be used. For example, as the copper salt, copper carboxylate (for example, copper acetate, copper ethyl acetoacetate, copper formate, copper benzoate, copper stearate, copper naphthenate, copper citrate, and copper 2-ethyl hexanoate), copper sulfonate (for example, copper methane sulfonate), copper phosphate, copper phosphoric acid ester, copper phosphonate, copper phosphonic acid ester, copper phosphinate, copper amide, copper sulfone amide, copper imide, copper acyl sulfone imide, copper bissulfone imide, copper methide, alkoxy copper, phenoxy copper, copper hydroxide, copper carbonate, copper sulfate, copper nitrate, copper perchlorate, copper fluoride, copper chloride, or copper bromide is preferable, copper carboxylate, copper acyl sulfone imide, phenoxy copper, the copper chloride, copper sulfate, or copper nitrate is more preferable, and copper carboxylate, copper acyl sulfone imide, copper chloride, or copper sulfate is particularly preferable.

Regarding the amount of the copper component to react with the compound (A), the molar ratio (compound (A): copper component) is preferably 1:0.5 to 1:8 and more preferably 1:0.5 to 1:4.

In the reaction conditions in a case of reacting the copper component and the compound (A) with each other, it is preferable that the temperature is 20° C. to 100° C. and the time is 0.5 hours or longer, for example.

The copper complex used in the present invention may have a ligand other than the compound (A). As the ligand other than the compound (A), a unidentate ligand performing coordination by an anion or an unshared electron pair may be used. Examples of a ligand performing coordination by an anion include a halide anion, a hydroxide anion, an alkoxide anion, a phenoxide anion, an amide anion (including amide substituted with an acyl group or a sulfonyl group), an imide anion (including imide substituted with an acyl group or a sulfonyl group), an anilide anion (including anilide substituted with an acyl group or a sulfonyl group), a thiolate anion, a hydrogen carbonate anion, a carboxylate anion, a thiocarboxylate anion, a dithiocarboxylate anion, a hydrogen sulfate anion, a sulfonate anion, a dihydrogen phosphate anion, a phosphoric acid diester anion, a phosphonic acid monoester anion, a hydrogen phosphonate anion, a phosphinate anion, nitrogen-containing heterocyclic anion, a nitrate anion, a hypochlorite anion, a cyanide anion, a cyanate anion, an isocyanate anion, a thiocyanate anion, an isothiocyanate anion, and an azide anion. Examples of a unidentate ligand performing coordination by an unshared electron pair include water, alcohol, phenol, ether, amine, aniline, amide, imide, imine, nitrile, isonitrile, thiol, thioether, a carbonyl compound, a thiocarbonyl compound, sulfoxide, a hetero ring, a carbonic acid, a carboxylic acid, a sulfuric acid, a sulfonic acid, a phosphoric acid, a phosphonic acid, a phosphinic acid, a nitric acid, or ester thereof.

The kind and the number of unidentate ligands can be suitably selected according to the compound (A) coordinating with a copper complex.

Specific examples of the unidentate ligands used as the ligands other than the compound (A) are as follows, but there is no limitation thereto. Hereinafter, Ph represents a phenyl group and Me represents a methyl group.

| | |
|---|---|
| —Cl | A1-1 |
| —Br | A1-2 |
| —F | A1-3 |
| —OH | A1-4 |
| —OMe | A1-5 |
| —OPh | A1-6 |
| —NH₂ | A1-7 |
| —NHCOCH₃ | A1-8 |
| —NHCOCF₃ | A1-9 |
| —NHSO₂CH₃ | A1-10 |
| —NHSO₂CF₃ | A1-11 |
| —N(COCH₃)₂ | A1-12 |
| —N(SO₂CF₃)₂ | A1-13 |
| —SC(═S)CH₃ | A1-14 |
| —OP(═O)(OMe)Ph | A1-15 |
| —OS(═O)₃CF₂ | A1-16 |
| —NMe₂ | A1-17 |
| —(SIMe₃)₂ | A1-18 |
| —NHPh | A1-19 |
| —SPh | A1-20 |
| —OS(═O)(OH)₂ | A1-21 |
| —OS(═O)₂CH₃ | A1-22 |
| —OCOCH₃ | A1-23 |
| —OCOPh | A1-24 |
| —OP(═O)(OH)₂ | A1-25 |
| —OP(═O)(OPh)₂ | A1-26 |
| —OP(═O)Me₂ | A1-27 |
| —ONO₂ | A1-28 |
| —NCO | A1-29 |
| —OCN | A1-30 |
| —NCS | A1-31 |
| —SCN | A1-32 |
| —CN | A1-33 |
| —N₂ | A1-34 |
| 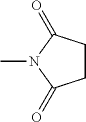 | A1-35 |
| 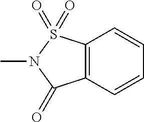 | A1-36 |
| 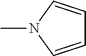 | A1-37 |
| 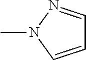 | A1-38 |
| 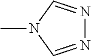 | A1-39 |
| 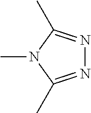 | A1-40 |
| —OH₂ | A1-41 |
| —OHMe | A1-42 |
| —OHPh | A1-43 |
| —NH₃ | A1-44 |
| —NEt₃ | A1-45 |
| —NH₂Ph | A1-46 |
| —NCMe | A1-47 |
| —O═C(CH₃)₂ | A1-48 |
| —O═S(CH₃)₂ | A1-49 |
| —SHPh | A1-50 |
| 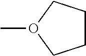 | A1-51 |
| 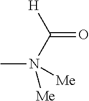 | A1-52 |
| 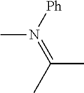 | A1-53 |
| 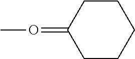 | A1-54 |
| 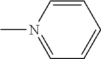 | A1-55 |
| 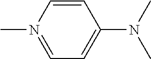 | A1-56 |
| 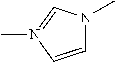 | A1-57 |
| —OCOCF₃ | A1-58 |

The copper complex be a cationic complex or an anionic complex in addition to a neutral complex not having an electric charge according to the number of coordination sites performing coordination by anions in a case where the compound (A) as the ligand has coordination sites performing coordination by anions. In this case, in order to neutralize the electric charge of the copper complex, as necessary, counter ions are present.

In a case where the counter ion is a negative counter ion, for example, the counter ion may be an inorganic anion or an organic anion. Specific examples of the counter ion include a hydroxide ion, a halogen anion (for example, a fluoride ion, a chloride ion, a bromide ion, and an iodide ion), a substituted alkyl carboxylate ion or an unsubstituted alkyl carboxylate ion (for example, an acetate ion, and a trifluoroacetate ion), a substituted aryl carboxylate ion or an unsubstituted aryl carboxylate ion (a benzoate ion and the like), a substituted alkyl sulfonate ion or an unsubstituted alkyl sulfonate ion (a methane sulfonate ion, a trifluoromethanesulfonate ion, and the like), a substituted aryl sulfonate ion or an unsubstituted aryl sulfonate ion (for example, a p-toluene sulfonate ion, and a p-chlorobenzene sulfonate ion), an aryl disulfonate ion (for example, a 1,3-benzene disulfonate ion, a 1,5-naphthalene disulfonate ion, and a 2,6-naphthalene disulfonate ion), an alkyl sulfate ion (for example, a methyl sulfate ion), a sulfate ion, a thiocyanate ion, a nitrate ion, a perchlorate ion, a tetrafluoroborate ion, a tetraaryl borate ion, a hexafluorophosphate ion, a picrate ion, an amide ion (including amide substituted with an acyl group or a sulfonyl group), and a methide ion (including methide substituted with an acyl group or a sulfonyl group). Among these, a halogen anion, a substituted alkyl carboxylate ion or an unsubstituted alkyl carboxylate ion, a sulfate ion, a nitrate ion, a tetrafluoroborate ion, a tetraaryl borate ion, a hexafluorophosphate ion, an amide ion (including amide substituted with an acyl group or a sulfonyl group), or a methide ion (including methide substituted with an acyl group or a sulfonyl group) is preferable.

In a case where the counter ion is a positive counter ion, examples of the counter ion include an inorganic ammonium ion or an organic ammonium ion (for example, a tetraalkyl ammonium ion such as a tetrabutyl ammonium ion, a triethyl benzyl ammonium ion, and a pyridinium ion), a phosphonium ion (for example, a tetraalkyl phosphonium ion such as a tetrabutyl phosphonium ion, an alkyl triphenyl phosphonium ion, and a triethyl phenyl phosphonium ion), an alkali metal ion, and a proton.

In addition, the counter ion may be a metal complex ion, and in particular, the counter ion may be a copper complex, that is, may be a salt of a cationic copper complex and an anionic copper complex.

As the copper complex used in the present invention, the following aspects (1) to (5) are used as preferable examples, the aspects (2) to (5) are more preferable, the aspects (3) to (5) are even more preferable, and the aspect (4) is particularly preferable.

(1) Copper complex having one or two compounds having two coordination sites as a ligand

(2) Copper complex having a compound having three coordination sites as a ligand

(3) Copper complex having a compound having three coordination sites and a compound having two coordination sites as ligands

(4) Copper complex including a compound having four coordination sites as a ligand

(5) Copper complex including a compound having five coordination sites as a ligand

In the aspect (1), the compound having two coordination sites is preferably a compound having two coordination sites performing coordination by an unshared electron pair or a compound having a coordination site performing coordination by an anion and the coordination site performing coordination by an unshared electron pair. In a case of having two compounds having two coordination sites as ligands, the compounds as the ligands may be the same as each other or different from each other.

In addition, in the aspect (1), the copper complex can further have the unidentate ligand described above. The number of the unidentate ligands can be 0 and can also be 1 to 3. As the kind of the unidentate ligand, both of a unidentate ligand performing coordination by an anion and a unidentate ligand performing coordination by an unshared electron pair are preferable. In a case where the compound having two coordination sites is a compound having two coordination sites performing coordination by an unshared electron pair, the unidentate ligand performing coordination by an anion is more preferable from the reason of a strong coordination force. In a case where the compound having two coordination sites is a compound having a coordination site performing coordination by an anion and a coordination site performing coordination by an unshared electron pair, the unidentate ligand performing coordination by an unshared electron pair is more preferable from a viewpoint in which the entire complex does not have an electric charge.

In the aspect (2), the compound having three coordination sites is preferably a compound having a coordination site performing coordination by an unshared electron pair and more preferably a compound having three coordination sites performing coordination by an unshared electron pair.

In addition, in the aspect (2), the copper complex can further have the unidentate ligand described above. The number of the unidentate ligands can be 0. The number of the unidentate ligands can be 1 or more, is more preferably 1 to 3, even more preferably 1 to 2, and particularly preferably 2. As the kind of the unidentate ligand, both of a unidentate ligand performing coordination by an anion and a unidentate ligand performing coordination by an unshared electron pair are preferable, and a unidentate ligand performing coordination by an anion is more preferable from the viewpoint described above.

In the aspect (3), the compound having three coordination sites is preferably a compound having a coordination site performing coordination by an anion and a coordination site performing coordination by an unshared electron pair and more preferably a compound having two coordination sites performing coordination by an anion and one coordination site performing coordination by an unshared electron pair. In addition, it is particularly preferable that the two coordination sites performing coordination by an anion are different from each other. The compound having two coordination sites is preferably a compound having a coordination site performing coordination by an unshared electron pair and more preferably a compound having two coordination sites performing coordination by an unshared electron pair. Among these, a combination in which the compound having three coordination sites is a compound having two coordination sites performing coordination by an anion and one coordination site performing coordination by an unshared electron pair and the compound having two coordination sites is a compound having two coordination sites performing coordination by an unshared electron pair is particularly preferable.

In addition, in the aspect (3), the copper complex can further have the unidentate ligand described above. The number of the unidentate ligands can be 0 and can also be 1 or more. The number thereof is more preferably 0.

In the aspect (4), the compound having four coordination sites is preferably a compound having a coordination site performing coordination by an unshared electron pair, more preferably a compound having two or more coordination sites performing coordination by an unshared electron pair, and even more preferably a compound having four coordination sites performing coordination by an unshared electron pair.

In addition, in the aspect (4), the copper complex can further have the unidentate ligand described above. The number of the unidentate ligands can be 0, can be 1 or more, or can be 2 or more. The number thereof is preferably 1. As the kind of the unidentate ligand, both of a unidentate ligand performing coordination by an anion and a unidentate ligand performing coordination by an unshared electron pair are preferable.

In the aspect (5), the compound having five coordination sites is preferably a compound having a coordination site performing coordination by an unshared electron pair, more preferably a compound having two or more coordination sites performing coordination by an unshared electron pair, and even more preferably a compound having five coordination sites performing coordination by an unshared electron pair.

In addition, in the aspect (5), the copper complex can further have the unidentate ligand described above. The number of the unidentate ligands can be 0 and can also be 1 or more. The number of the unidentate ligands is preferably 0.

Specific examples of the copper complex are as follows.

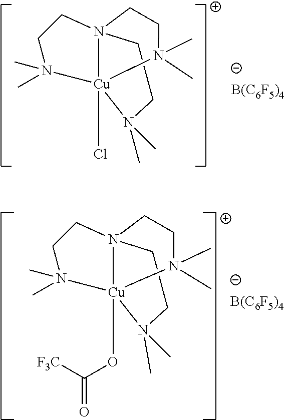

The copper complex may be carried by a polymer.

(Pyrrolopyrrole Compound: Compound Represented by Formula 1)

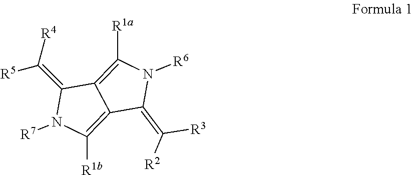

In Formula 1, R^{1a} and R^{1b} each independently represent an alkyl group, an aryl group, or a heteroaryl group,

R² to R⁵ each independently represent a hydrogen atom or a substituent, R² and R³, and R⁴ and R⁵ may be respectively bonded to form rings,

R⁶ and R⁷ each independently represent a hydrogen atom, an alkyl group, an aryl group, a heteroaryl group, —BR^{A}R^{B}, or a metal atom, R^{A} and R^{B} each independently represent a hydrogen atom or a substituent,

R⁶ may form a covalent bond or a coordinate bond with R^{1a} or R³, and R⁷ may form a covalent bond or a coordinate bond with R^{1b} or R⁵.

In Formula 1, R^{1a} and R^{1b} each independently represent an alkyl group, an aryl group, or a heteroaryl group, preferably represent an aryl group or a heteroaryl group, and more preferably represent an aryl group.

The number of carbon atoms of the alkyl group represented by R^{1a} and R^{1b} is preferably 1 to 40, more preferably 1 to 30, and even more preferably 1 to 25. The alkyl group may a linear alkyl group, a branched alkyl group, or a cyclic alkyl group. A linear alkyl group or a branched alkyl group is preferable and a branched alkyl group is more preferable.

The number of carbon atoms of the aryl group represented by R^{1a} and R^{1b} is preferably 6 to 30, more preferably 6 to 20, and even more preferably 6 to 12. The aryl group is preferably a phenyl group.

The heteroaryl group represented by R^{1a} and R^{1b} is preferably a monocyclic ring or a fused ring, more preferably a monocyclic ring or a fused ring having 2 to 8 condensations, and even more preferably a monocyclic ring or a fused ring having 2 to 4 condensations. The number of hetero atoms that form the ring of the heteroaryl group is preferably 1 to 3. The hetero atom that forms the ring of the heteroaryl group is preferably a nitrogen atom, a sulfur atom, or an oxygen atom. The number of carbon atoms that forms the heteroaryl group is preferably 3 to 30, more preferably 3 to 18, even more preferably 3 to 12, and particularly preferably 3 to 10. The heteroaryl group is preferably a 5-membered or 6-membered ring.

The above-described aryl group and heteroaryl group may have a substituent or may not have a substituent. From the viewpoint of being capable of improving solubility to a solvent, the aryl group and the heteroaryl group preferably have a substituent.

Examples of the substituent include a hydrocarbon group which may contain an oxygen atom, an amino group, an acylamino group, a sulfonylamino group, a sulfamoyl group, a carbamoyl group, an alkylthio group, an alkylsulfonyl group, a sulfinyl group, a ureido group, a phosphoric acid amide group, a mercapto group, a sulfo group, a carboxyl group, a nitro group, a hydroxamic acid group, a sulfino group, a hydrazino group, an imino group, a silyl group, a hydroxy group, a halogen atom, and a cyano group.

Examples of the halogen atom include a fluorine atom, a chlorine atom, a bromine atom, and an iodine atom.

Examples of the hydrocarbon group include an alkyl group, an alkenyl group, and an aryl group.

The number of carbon atoms of the alkyl group is preferably 1 to 40. The lower limit is more preferably 3 or more, even more preferably 5 or more, still even more preferably 8 or more, and particularly preferably 10 or more. The upper limit is more preferably 35 or less and even more preferably 30 or less. The alkyl group may be any one of a linear alkyl group, a branched alkyl group, and a cyclic alkyl group, and is preferably a linear alkyl group or a branched alkyl group and more preferably a branched alkyl group. The number of carbon atoms of the branched alkyl group is preferably 3 to 40. For example, the lower limit is more preferably 5 or more, even more preferably 8 or more, and particularly preferably 10 or more. The upper limit is more preferably 35 or less and even more preferably 30 or less. For example, the number of branches of the branched alkyl group is preferably 2 to 10 and more preferably 2 to 8. As long as the number of branches is in the above range, the solvent solubility is satisfactory.

The number of carbon atoms of the alkenyl group is preferably 2 to 40. For example, the lower limit is more preferably 3 or more, even more preferably 5 or more, still even more preferably 8 or more, and particularly preferably 10 or more. The upper limit is more preferably 35 or less and still even more preferably 30 or less. The alkenyl group may be any one of a linear alkenyl group, a branched alkenyl group, and a cyclic alkenyl group, and is preferably a linear alkenyl group or a branched alkenyl group and particularly preferably a branched alkenyl group. The number of carbon atoms of the branched alkenyl group is preferably 3 to 40. For example, the lower limit is more preferably 5 or more, even more preferably 8 or more, and particularly preferably 10 or more. The upper limit is more preferably 35 or less and even more preferably 30 or less. The number of branches of the branched alkenyl group is preferably 2 to 10 and more preferably 2 to 8. As long as the number of branches is in the above range, the solvent solubility is satisfactory.

The number of carbon atoms of the aryl group is preferably 6 to 30, more preferably 6 to 20, and even more preferably 6 to 12.

As hydrocarbon group including an oxygen atom, a group represented by -L-R^{x1} may be exemplified.

L represents —O—, —CO—, —COO—, —OCO—, —(OR^{x2})ₘ-, or —(R^{x2}O)ₘ-. R^{x1} represents an alkyl group, an alkenyl group, or an aryl group. R^{x2} represents an alkylene group or an arylene group. m represents an integer of 2 or more and m R^{x2}'s are the same as each other or different from each other.

L is preferably —O—, —(OR^{x2})ₘ-, or —(R^{x2}O)ₘ- and more preferably —O—.

The alkyl group, the alkenyl group, or the aryl group represented by R^{x1} has the same meaning as described above, and preferable ranges thereof are also the same. R^{x1} is preferably an alkyl group or an alkenyl group and more preferably an alkyl group.

The number of carbon atoms of the alkylene group represented by R^{x2} is preferably 1 to 20, more preferably 1 to 10, and even more preferably 1 to 5. The alkylene group may be any one of a linear alkylene group, a branched alkylene group, and a cyclic alkylene group and is preferably a linear alkylene group or a branched alkylene group. The number of carbon atoms of the arylene group represented by R^{x2} is preferably 6 to 20 and more preferably 6 to 12. R^{x2} is preferably an alkylene group.

m represents an integer of 2 or more and is preferably 2 to 20 and more preferably 2 to 10.

A substituent that the aryl group and the heteroaryl group may have is preferably a group having a branched alkyl structure. According to the aspect, the solvent solubility is further improved. In addition, the substituent is preferably a hydrocarbon group which may include an oxygen atom, and more preferably a hydrocarbon group including an oxygen atom. The hydrocarbon group including an oxygen atom is preferably a group represented by —O—R^{x1}. R^{x1} is preferably an alkyl group or an alkenyl group, more preferably an alkyl group, and particularly preferably a branched alkyl group. That is, the substituent is more preferably an alkoxy group and even more preferably a branched alkoxy group. By using the alkoxy group as the substituent, an infrared absorber having excellent heat resistance and light resistance can be obtained. In addition, by using the branched alkoxy group, the solvent solubility is satisfactory.

The number of carbon atoms of the alkoxy group is preferably 1 to 40. For example, lower limit is more preferably 3 or more, even more preferably 5 or more, still even more preferably 8 or more, and particularly preferably 10 or more. The upper limit is more preferably 35 or less and even more preferably 30 or less. The alkoxy group may be any one of a linear alkoxy group, a branched alkoxy group, and a cyclic alkoxy group, and is preferably a linear alkoxy group or a branched alkoxy group and more preferably a branched alkoxy group. The number of carbon atoms of the branched alkoxy group is preferably 3 to 40. For example, the lower limit is more preferably 5 or more, even more preferably 8 or more, and still even more preferably 10 or more. The upper limit is more preferably 35 or less and even more preferably 30 or less. The number of branches of the branched alkoxy group is preferably 2 to 10 and more preferably 2 to 8.

R² to R⁵ each independently represent a hydrogen atom or a substituent. Examples of the substituent include an alkyl group, an alkenyl group, an alkynyl group, an aryl group, an heteroaryl group, an amino group (including an alkylamino group, an arylamino group, and a heterocyclic amino group), an alkoxy group, an aryloxy group, a heteroaryloxy group, an acyl group, an alkylcarbonyl group, an arylcarbonyl group, an alkoxycarbonyl group, an aryloxycarbonyl group, an acyloxy group, an acylamino group, an alkoxycarbonylamino group, an aryloxycarbonylamino group, a sulfonylamino group, a sulfamoyl group, a carbamoyl group, an alkylthio group, an arylthio group, a heteroarylthio group, an alkylsulfonyl group, an arylsulfonyl group, a sulfinyl group, a ureido group, a phosphoric acid amide group, a hydroxyl group, a mercapto group, a halogen atom, a cyano group, a sulfo group, a carboxyl group, a nitro group, a hydroxamic acid group, a sulfino group, a hydrazino group, an imino group, and a silyl group.

It is preferable that any one of R² and R³ and any one of R⁴ and R⁵ represent an electron-withdrawing group.

A substituent of which a Hammett σp value (sigma-para value) is positive functions as an electron-withdrawing group.

In the present invention, a substituent of which a Hammett σp value is 0.2 or greater can be exemplified as an electron-withdrawing group. The σp value is preferably 0.25 or greater, more preferably 0.3 or greater, and particularly preferably 0.35 or greater. The upper limit is not particularly limited, but preferably 0.80.

Specific examples of the electron-withdrawing group include a cyano group (0.66), a carboxyl group (—COOH: 0.45), an alkoxycarbonyl group (—COOMe: 0.45), an aryloxycarbonyl group (—COOPh: 0.44), a carbamoyl group (—CONH₂: 0.36), an alkylcarbonyl group (—COMe: 0.50), an arylcarbonyl group (—COPh: 0.43), an alkylsulfonyl group (—SO₂Me: 0.72), or an arylsulfonyl group (—SO₂Ph: 0.68). Particularly preferably, an example is a cyano group. Here, Me represents a methyl group, and Ph represents a phenyl group.

With respect to the Hammett σp value, paragraphs 0024 and 0025 of JP2009-263614A are referred to, and the contents thereof are incorporated to the present specification.

It is preferable that any one of R² and R³ and any one of R⁴ and R⁵ are R² represent a heteroaryl group.

The heteroaryl group is preferably a single ring or a fused ring, is preferably a single ring or a fused ring having 2 to 8 condensations, and more preferably a single ring or a fused ring having 2 to 4 condensations. The number of hetero atoms that form the heteroaryl group is preferably 1 to 3. The hetero atom that forms a heteroaryl group is preferably a nitrogen atom, an oxygen atom, or a sulfur atom. The heteroaryl group preferably has one or more nitrogen atoms. The number of carbon atoms of the heteroaryl group is preferably 3 to 30, more preferably 3 to 18, more preferably 3 to 12, and particularly preferably 3 to 10. The heteroaryl group is preferably a 5-membered or 6-membered ring. Specific examples of the heteroaryl group include an imidazolyl group, a pyridyl group, a pyrazyl group, a pyrimidyl group, a pyridazyl group, a triazyl group, a quinolyl group, a quinoxalyl group, an isoquinolyl group, an indolenyl group, a furyl group, a thienyl group, a benzoxazolyl group, a benzimidazolyl group, a benzthiazolyl group, a naphthothiazolyl group, a m-carbazolyl group, an azepinyl group, and a benzo-condensed ring group or a naphtha-condensed ring group of these groups.

The heteroaryl group may have a substituent or may not have a substituent. Examples of the substituent include the substituents represented by R² to R⁵ described above. A halogen atom, an alkyl group, an alkoxy group, or an aryl group is preferable.

As the halogen atom, a fluorine atom, a chlorine atom, a bromine atom, or an iodine atom is preferable and a chlorine atom is more preferable.

The number of carbon atoms the alkyl group and the alkoxy group is preferably 1 to 40, more preferably 1 to 30, and even more preferably 1 to 25. The alkyl group and the alkoxy group are preferably linear or branched and are more preferably liner.

The number of carbon atoms of the aryl group is preferably 6 to 30, more preferably 6 to 20, and even more preferably 6 to 12.

In Formula 1, R² and R³, and R⁴ and R⁵ may be respectively bonded to each other to form a ring. In a case where R² and R³, and R⁴ and R⁵ are bonded to each other to form rings, it is preferable to form a 5-membered to 7-membered ring (preferably 5-membered or 6-membered ring). It is preferable that the formed ring is used as an acidic nucleus in a merocyanine dye. Specific examples thereof include structures described in paragraph 0026 of JP2010-222557A, and the contents thereof are incorporated in the present specification.

Examples of the ring that is formed by bonding R² and R³, and R⁴ and R⁵ to each other preferably include a 1,3-dicarbonyl nucleus, a pyrazolinone nucleus, a 2,4,6-triketohexahydropyrimidine nucleus (including a thioketone product), a 2-thio-2,4-thiazolidinedione nucleus, a 2-thio-2,4-oxazolidinedione nucleus, a 2-thio-2,5-thiazolidinedione nucleus, a 2,4-thiazolidinedione nucleus, a 2,4-imidazolidinedione nucleus, a 2-thio-2,4-imidazolidinedione nucleus, a 2-imidazolin-5-one nucleus, a 3,5-pyrazolidinedione nucleus, a benzothiophen-3-one nucleus, and an indanone nucleus and more preferably include a 1,3-dicarbonyl nucleus, a 2,4,6-triketohexahydropyrimidine nucleus (including a thioketone product), a 3,5-pyrazolidinedione nucleus, a benzothiophen-3-one nucleus, and an indanone nucleus.

R⁶ and R⁷ each independently represent a hydrogen atom, an alkyl group, an aryl group, a heteroaryl group, —BR^{A}R^{B}, or a metal atom and more preferably represent —BR^{A}R^{B}.

The number of carbon atoms of the alkyl group represented by R⁶ and R⁷ is preferably 1 to 40, more preferably 1 to 30, and even more preferably 1 to 25. The alkyl group may be any one of a linear alkyl group, a branched alkyl group, and a cyclic alkyl group and is preferably a linear alkyl group or a branched alkyl group and more preferably a linear alkyl group. The alkyl group may not have a substituent or may have a substituent. Examples of the substituent include the substituents represented by R² to R⁵ described above.

The number of carbon atoms of the aryl group represented by R⁶ and R⁷ is preferably 6 to 30, more preferably 6 to 20, and even more preferably 6 to 12. The aryl group may not have a substituent or may have a substituent. Examples of the substituent include the substituents represented by R² to R⁵ described above.

The heteroaryl group represented by R⁶ and R⁷ is preferably a monocyclic ring or a fused ring and more preferably a monocyclic ring. The number of hetero atoms that form the heteroaryl group is preferably 1 to 3. The hetero atom that forms the ring of the heteroaryl group is preferably a nitrogen atom, an oxygen atom, or a sulfur atom. The number of carbon atoms that forms the heteroaryl group is preferably 3 to 30, more preferably 3 to 18, even more preferably 3 to 12, and particularly preferably 3 to 5. The heteroaryl group is preferably a 5-membered or 6-membered ring. The heteroaryl group may not have a substituent or may have a substituent. Examples of the substituent include the substituents represented by R² to R⁵ described above.

As the metal atom represented by R⁶ and R⁷, magnesium, aluminum, calcium, barium, zinc, tin, vanadium, iron, cobalt, nickel, copper, palladium, iridium, or platinum is preferable and aluminum, zinc, vanadium, iron, copper, palladium, iridium, or platinum is more preferable.

In the group represented by —BR^{A}R^{B}, and R^{B} each independently represent a hydrogen atom or a substituent.

Examples of the substituent represented by R^{A} and R^{B} include the substituents represented by R² to R⁵ described above. A halogen atom, an alkyl group, an alkoxy group, an aryl group, and a heteroaryl group are preferable.

As the halogen atom, a fluorine atom, a chlorine atom, a bromine atom, or an iodine atom is preferable and a fluorine atom is more preferable.

The number of carbon atoms of the alkyl group and the alkoxy group is preferably 1 to 40, more preferably 1 to 30, and even more preferably 1 to 25. The alkyl group and the alkoxy group are preferably linear or branched and more preferably linear. The alkyl group and the alkoxy group may have a substituent or may not have a substituent. Examples of the substituent include an aryl group, a heteroaryl group, and a halogen atom.

The number of carbon atoms of the aryl group is preferably 6 to 20 and more preferably 6 to 12. The aryl group may have a substituent or may not have a substituent. Examples of the substituent include an alkyl group, an alkoxy group, and a halogen atom.

The heteroaryl group may be a monocyclic ring or a polycyclic ring. The number of hetero atoms that form the heteroaryl group is preferably 1 to 3. The hetero atom that forms the heteroaryl group is preferably a nitrogen atom, an oxygen atom, or a sulfur atom. The number of carbon atoms that forms the heteroaryl group is preferably 3 to 30, more preferably 3 to 18, even more preferably 3 to 12, and particularly preferably 3 to 5. The heteroaryl group is preferably a 5-membered or 6-membered ring. The heteroaryl group may have a substituent or may not have a substituent. Examples of the substituent include an alkyl group, an alkoxy group, and a halogen atom.

In Formula 1, R⁶ may form a covalent bond or a coordinate bond with R^{1a} or R³. In addition, R⁷ may form a covalent bond or a coordinate bond with R^{1b} or R⁵.

Examples of the pyrrolopyrrole compound represented by Formula 1 include compounds D-1 to D-162 described in paragraphs 0049 to 0062 of JP2010-222557A, and the contents thereof are incorporated in the present specification.

A preferred aspect of the pyrrolopyrrole compound represented by Formula 1 includes a pyrrolopyrrole compound represented by Formula 1-1.

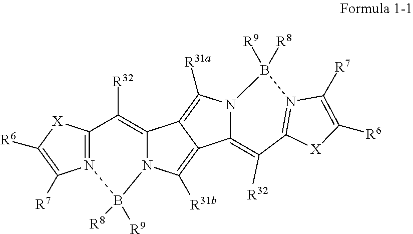

In the formula, R^{31a} and R^{31b} each independently represent an alkyl group having 1 to 20 carbon atoms, an aryl group having 6 to 20 carbon atoms, or a heteroaryl group having 3 to 20 carbon atoms. R³² represents a cyano group, an acyl group having 1 to 6 carbon atoms, an alkoxycarbonyl group having 1 to 6 carbon atoms, an alkyl or arylsulfinyl group having 1 to 10 carbon atoms, or a nitrogen-containing heteroaryl group having 3 to 10 carbon atoms. R⁶ and R⁷ each independently represent a hydrogen atom, an alkyl group having 1 to 10 carbon atoms, an aryl group having 6 to 10 carbon atoms, or a heteroaryl group having 4 to 10 carbon atoms, R⁶ and R⁷ may be bonded to each other to form a ring, and the ring to be formed is an alicyclic ring having 5 to 10 carbon atoms, an aryl ring having 6 to 10 carbon atoms, or a heteroaryl ring having 3 to 10 carbon atoms. R⁸ and R⁹ each independently represent an alkyl group having 1 to 10 carbon atoms, an alkoxy group having 1 to 10 carbon atoms, an aryl group having 6 to 20 carbon atoms, or a heteroaryl group having 3 to 10 carbon atoms. X represents an oxygen atom, a sulfur atom, —NR—, —CRR′, or —CH═CH—, and R and R′ each independently represent a hydrogen atom, an alkyl group having 1 to 10 carbon atoms, or an aryl group having 6 to 10 carbon atoms.

In Formula 1-1, R^{31a} and R^{31b} each independently represent an alkyl group having 1 to 20 carbon atoms, an aryl group having 6 to 20 carbon atoms, or a heteroaryl group having 3 to 20 carbon atoms. Specifically, examples of R^{31a} and R^{31b} are the same as the examples described in R^{1a} and R^{1b} in Formula 1 and the preferable ranges thereof are also the same. R^{31a} and R^{31b} are preferably the same.

R³² represents a cyano group, an alkoxycarbonyl group having 1 to 6 carbon atoms, an alkyl or arylsulfinyl group having 1 to 10 carbon atoms, or a nitrogen-containing heteroaryl group having 3 to 10 carbon atoms. Specifically, examples of R³² are the same as the examples of R² in Formula 1 and the preferable range thereof is also the same.

R⁶ and R⁷ each independently represent a hydrogen atom, an alkyl group having 1 to 10 carbon atoms, an aryl group having 6 to 10 carbon atoms, or a heteroaryl group having 4 to 10 carbon atoms. Specifically, examples of substituents of R⁶ and R7 are the same as the examples of the substituents described in R² and R³ in Formula 1 and the preferable ranges thereof are also the same. R⁶ and R⁷ may be bonded to each other to form a ring, and the ring to be formed is an alicyclic ring having 5 to 10 carbon atoms, an aryl ring having 6 to 10 carbon atoms, or a heteroaryl ring having 3 to 10 carbon atoms. Preferable examples thereof include a benzene ring, a naphthalene ring, and a pyridine ring.

It is possible to realize an infrared absorbing dye with both of high fastness and invisibility by introducing a 5-membered nitrogen-containing hetero ring substituted with R⁶ and R⁷ to be used as a boron complex.

R⁸ and R⁹ each independently represent an alkyl group having 1 to 10 carbon atom, an alkoxy group having 1 to 10 carbon atoms, an aryl group having 6 to 20 carbon atoms, or a heteroaryl group having 3 to 10 carbon atoms. Specifically, examples of substituents of R⁸ and R⁹ are the same as the examples of the substituents of R² and R³ in Formula 1 and the preferable ranges thereof are also the same.

X represents an oxygen atom, a sulfur atom, —NR—, —CRR′, or —CH═CH—. Here, R and R′ each independently represent a hydrogen atom, an alkyl group having 1 to 10 carbon atoms, or an aryl group having 6 to 10 carbon atoms and preferably represent a hydrogen atom, an alkyl group having 1 to 6 carbon atoms, or a phenyl group.

(Cyanine Compound: Compound Represented by Formula 2)

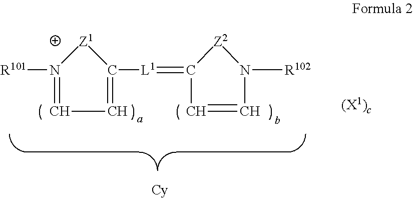

In Formula 2, Z¹ and Z² each independently represent a non-metal atom group forming a 5-membered or 6-membered nitrogen-containing heterocyclic ring which may be condensed,

R¹⁰¹ and R102 each independently represent an alkyl group, an alkenyl group, an alkynyl group, an aralkyl group, or an aryl group,

L¹ represents a methine chain constituted of an odd number of methines,

a and b each independently represent 0 or 1,

in a case where a is 0, the carbon atom and the nitrogen atom are bonded by a double bond and in a case where b is 0, the carbon atom and the nitrogen atom are bonded by a single bond,

in a case where a moiety represented by Cy in the formula is a cation moiety, X¹ represents an anion, and c represents a number required for balancing electric charge, in a case where the moiety represented by Cy in the formula is an anion moiety, X¹ represents a cation, and c represents a number required for balancing electric charge, and in a case where the electric charge of the moiety represented by Cy in the formula is neutralized in the molecule, c is 0.

In Formula 2, Z¹ and Z² each independently represent a non-metal atom group forming a 5-membered or 6-membered nitrogen-containing heterocyclic ring which may be condensed.

With the nitrogen-containing heterocyclic ring, another heterocyclic ring, an aromatic ring, or an alicyclic group may be condensed. The nitrogen-containing heterocyclic ring is preferably a 5-membered ring. A structure in which a benzene ring or a naphthalene ring is condensed with the 5-membered nitrogen-containing heterocyclic ring is more preferable. Specific examples of the nitrogen-containing heterocyclic ring include an oxazole ring, an isoxazole ring, a benzoxazole ring, a naphtoxazole ring, an oxazolone carbazole ring, an oxazolone dibenzofuran ring, a thiazole ring, a benzothiazole ring, a naphthothiazole ring, an indolenine ring, a benzoindolenine ring, an imidazole ring, a benzoimidazole ring, a naphthimidazole ring, a quinoline ring, a pyridine ring, a pyrrolopyridine ring, a furopyrrole ring, an indolizine ring, an imidazoquinoxaline ring and a quinoxaline ring. Among these, a quinoline ring, an indolenine ring, a benzoindolenine ring, a benzoxazole ring, a benzothiazole ring, or a benzoimidazole ring is preferable and an indolenine ring, and a benzothiazole ring, or a benzoimidazole ring is more preferable.

The nitrogen-containing heterocyclic ring and the rings condensed therewith may have substituents. Examples of the substituent groups include a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c5}R^{c6}, —NHCOR^{c7}, —CONR^{c8}R^{c9}, —NHCONR^{c10}R^{c11}, —NHCOOR^{c12}, —SR^{c13}, —SO₂R^{c14}, —SO₂OR^{c15}, —NHSO₂R^{c16}, and —SO₂NR^{c17}R^{c18}. R^{c1} to R^{c18} each independently represent a hydrogen atom an alkyl group, an alkenyl group, an alkynyl group, an aryl group, or a heteroaryl group. In a case where R^{c3} of —COOR^{c3} is a hydrogen atom (that is, a carboxyl group), the hydrogen atom may be decomposed (that is, a carbonate group) or —COOR^{c3} may be in a salt state. In addition, in a case where R^{c15} of —SO₂OR^{c15} is a hydrogen atom (that is, a sulfo group), the hydrogen atom may be decomposed (that is, a sulfonate group) or —SO₂OR^{c15} may be in a salt state.

Examples of the halogen atom include a fluorine atom, a chlorine atom, a bromine atom, and an iodine atom.

The number of carbon atoms of the alkyl group is preferably 1 to 20, more preferably 1 to 12, and even more preferably 1 to 8. The alkyl group may be any one of a linear alkyl group, a branched alkyl group, and a cyclic alkyl group. The alkyl group may not have a substituent or may have a substituent. Examples of the substituent include a halogen atom, a hydroxyl group, a carboxyl group, a sulfo group, an alkoxy group, and an amino group, a carboxyl group or a sulfo group is preferable, and a sulfo group is more preferable. In the carboxyl group and the sulfo group, the hydrogen atom may be decomposed or the carboxyl group and the sulfo group may be in a salt state.

The number of carbon atoms of the alkenyl group is preferably 2 to 20, more preferably 2 to 12, and even more preferably 2 to 8. The alkenyl group may be any one of a linear alkenyl group, a branched alkenyl group, and a cyclic alkenyl group. The alkenyl group may not have a substituent or may have a substituent. Examples of the substituent include the substituents that the alkyl group may have and the preferable range thereof is also the same.

The number of carbon atoms of the alkynyl group is preferably 2 to 20, more preferably 2 to 12, and even more preferably 2 to 8. The alkynyl group may be any one of a linear alkynyl group, a branched alkynyl group, and a cyclic alkynyl group. The alkynyl group may not have a substituent or may have a substituent. Examples of the substituent include the substituents that the alkyl group may have and the preferable range thereof is also the same.

The number of carbon atoms of the aryl group is preferably 6 to 25, more preferably 6 to 15, and even more preferably 6 to 10. The aryl group may not have a substituent or may have a substituent. Examples of the substituent include the substituents that the alkyl group may have and the preferable range thereof is also the same.

The alkyl moiety of the aralkyl group has the same meaning as that of the alkyl group. The alkyl moiety of the aralkyl group has the same meaning as that of the aryl group. The number of carbon atoms of the aralkyl group is preferably 7 to 40, more preferably 7 to 30, and even more preferably 7 to 25.

The heteroaryl group is preferably a monocyclic ring or a fused ring, more preferably a monocyclic ring or a fused ring having 2 to 8 condensations, and even more preferably a monocyclic ring or a fused ring having 2 to 4 condensations. The number of hetero atoms forming the ring of the heteroaryl group is preferably 1 to 3. The hetero atoms forming the ring of the heteroaryl group is preferably a nitrogen atom, an oxygen atom, or a sulfur atom. The heteroaryl group is preferably a 5-membered ring or a 6-membered ring. The number of carbon atoms that form the ring of the heteroaryl group is preferably 3 to 30, more preferably 3 to 18, and even more preferably 3 to 12. The heteroaryl group may not have a substituent or may have a substituent. Examples of the substituent include the substituents that the alkyl group may have and the preferable range thereof is also the same.

In Formula 2, _{R}¹⁰¹ and R¹⁰² each independently represent an alkyl group, an alkenyl group, an alkynyl group, an aralkyl group, or an aryl group. Examples of the alkyl group, the alkenyl group, the alkynyl group, the aralkyl group, and the aryl group include the substituents described above, and the preferable ranges thereof are also the same. The alkyl group, the alkenyl group, the alkynyl group, the aralkyl group, and the aryl group may have substituents or may not have substituents. Examples of the substituents include a halogen atom, a hydroxyl group, a carboxyl group, a sulfo group, an alkoxy group, and an amino group, a carboxyl group or a sulfo group is preferable, and a sulfo group is more preferable. In the carboxyl group and the sulfo group, the hydrogen atom may be decomposed or the carboxyl group and the sulfo group may be in a salt state.

In Formula 2, L¹ represents a methine chain constituted of an odd number of methines. L¹ is preferably a methine chain constituted of a 3, 5, or 7 methine groups.

The methine group may have a substituent group. The methine group having a substituent is preferably a methine group present at the center (at the meso position). Specific examples of the substituent are the same as the examples of the substituent which the nitrogen-containing heterocyclic ring of Z¹ and Z² may have and a group represented by Formula (a). Two substituents of the methine chain may bond together to form a 5-membered or 6-membered ring.

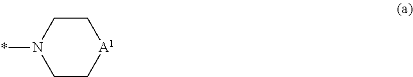

In Formula (a), * represents a linking portion with the methine chain and A¹ represents an oxygen atom or a sulfur atom.

In Formula 2, a and b each independently represents 0 or 1. In a case where a is 0, the carbon atom and the nitrogen atom are bonded by a double bond and in a case where b is 0, the carbon atom and the nitrogen atom are bonded by a single bond. a and b are preferably 0. In a case where a and b are 0, Formula 2 is represented as follows.

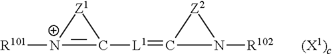

In Formula 2, in a case where a moiety represented by Cy in the formula is a cation moiety, X¹ represents an anion, and c represents a number required for balancing electric charge. Examples of the anion include halide ions (Cl⁻, Br⁻, I⁻), p-toluenesulfonic acid ion, an ethylsulfuric acid ion, PF₆⁻, BF₄⁻, ClO₄⁻, tris(halogenoalkyl sulfonyl)methide anion (for example, (CF₃SO₂)₃C⁻), di(halogenoalkyl sulfonyl)imide anion (for example, (CF₃SO₂)₂N), and tetracyanoborate anion.

In Formula 2, in a case where the moiety represented by Cy in the formula is an anion moiety, X¹ represents a cation, and c represents a number required for balancing electric charge. Examples of the cation include alkali metal ions (Li⁺, Na⁺, K⁺, and the like), alkali earth metal ions (Mg²⁺, Ca²⁺, Ba²⁺, Sr²⁺ and the like), transition metal ions (Ag⁺, Fe²⁺, Co ²⁺, Ni²⁺, Cu²⁺, Zn²⁺, and the like), other metal ions (Al³⁺ and the like), ammonium ion, triethyl ammonium ion, tributyl ammonium ion, pyridinium ion, tetrabutyl ammonium ion, guanidinium ion, tetramethylguanidinium ion, and diazabicycloundecene. As the cation, Na⁺, K⁺, Mg²⁺, Ca²⁺, Zn²⁺, or diazabicycloundecene is preferable.

In Formula 2, in a case where the electric charge of the moiety represented by Cy in the formula is neutralized in the molecule, X¹ is not present. That is, c is 0.

A compound represented by Formula 2 is preferably a compound represented by Formula (3-1) or (3-2). The compound has excellent heat resistance.

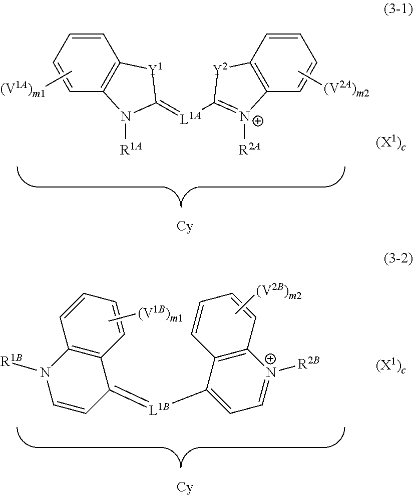

In Formulae (3-1) and (3-2), R^{1A}, R^{2A}, R^{1B}, and R^{2B} each independently represent an alkyl group, an alkenyl group, an alkynyl group, an aralkyl group, or an aryl group,

L^{1A} and L^{1B} each independently represent a methine chain constituted of an odd number of methines,

Y¹ and Y² each independently represent —S—, —O—, —NR^{x1}—, or —CR^{x2}R^{x3}—,

R^{x1}, R^{x2}, and R^{x3} each independently represent a hydrogen atom or an alkyl group,

V^{1A}, V^{2A}, V^{1B}, and V^{2B} each independently represent a halogen atom, a cyano group, a nitro group, an alkyl group, an alkenyl group, an alkynyl group, an aralkyl group, an aryl group, a heteroaryl group, —OR^{c1}, —COR^{c2}, —COOR^{c3}, —OCOR^{c4}, —NR^{c 5}, —NHCOR^{c7}, —CONR^{c8}R^{c9}, —NHCOOR^{c12}, —SR^{c13}, —SO_{c}R^{c15}, —NHSO₂R^{c16}, or —SO₂NR^{c17}R^{c18}, V^{1A}, V^{2A}, V^{1B}, and V^{2B} may form a fused ring,

R^{cl} to R^{c18} each independently represent a hydrogen atom, an alkyl group, an alkenyl group, an alkynyl group, an aryl group, or a heteroaryl group,

in a case where R^{c3} of —COOR^{c3} is a hydrogen atom and in a case where R^{c15} of —SO₂OR^{c15} is a hydrogen atom, the hydrogen atom may be decomposed or —COOR^{c3} and —SO₂OR^{c15} may be in a salt state,

ml and m2 each independently represent an integer of 0 to 4,

in a case where a moiety represented by Cy in the formula is a cation moiety, X¹ represents an anion, and c represents a number required for balancing electric charge,

in a case where the moiety represented by Cy in the formula is an anion moiety, X¹ represents a cation, and c represents a number required for balancing electric charge, and

in a case where the electric charge of the moiety represented by Cy in the formula is neutralized in the molecule, X¹ is not present.

The groups represented by R^{1A}, R^{2A}, R^{1B}, and R^{2B} are the same as the alkyl group, the alkenyl group, the alkynyl group, the aralkyl group, and the aryl group described in R¹⁰¹ and R¹⁰² of Formula 2, and the preferable ranges thereof are also the same. These groups may not have a substituent or may have a substituent. Examples of the substituent include a halogen atom, a hydroxyl group, a carboxyl group, a sulfo group, an alkoxy group, and an amino group, a carboxyl group or a sulfo group is preferable, and a sulfo group is more preferable. In the carboxyl group and the sulfo group, the hydrogen atom may be decomposed or the carboxyl group and the sulfo group may be in a salt state.

In a case where R^{1A}, R^{2A}, R^{1B}, and R^{2B} each represent an alkyl group, the alkyl group is preferably a linear alkyl group.

Y¹ and Y² each independently represent —S—, —O—, —NR^{x1}—, or —CR^{x2}R^{x3}—, and —NR^{x1}— is preferable.

R^{x1}, R^{x2}, and R^{x3} each independently represent a hydrogen atom or an alkyl group, and an alkyl group is preferable. The number of carbon atoms of the alkyl group is preferably 1 to 10, more preferably 1 to 5, and even more preferably 1 to 3. The alkyl group may be any one of a linear alkyl group, a branched alkyl group, and a cyclic alkyl group and is preferably a linear alkyl group or a branched alkyl group and more preferably a linear alkyl group. The alkyl group is even more preferably a methyl group or an ethyl group.

L^{1A} and L^{1B} have the same meaning as L¹ of Formula 2, and the preferable ranges thereof are also the same.

The range of the group represented by V^{1A}, V^{2A}, V^{1B}, and V^{2B} is the same as the range described in the substituent which the nitrogen-containing heterocyclic ring of Z¹ and Z² of Formula 2 may have and the preferable range thereof is also the same.

m1 and m2 each independently represent an integer of 0 to 4 and preferably represent an integer of 0 to 2.

The ranges of the anion and the cation represented by X¹ are the same as the ranges described in X¹ of Formula 2, and the preferable ranges thereof are also the same.

The compound represented by Formula 2 includes compounds described in paragraphs 0044 to 0045 of JP2009-108267A, and the contents thereof are incorporated in the present specification.

(Squarylium Dye)

In the present invention, a squarylium dye is preferably a compound represented by Formula (1).

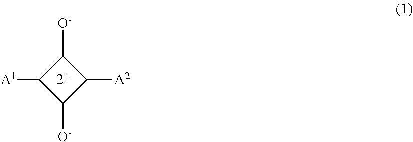

In Formula (1), A¹ and A² each independently represent an aryl group, a heterocyclic group, or a group represented by Formula (2).

In Formula (2), Z¹ represents a non-metal atom group forming a nitrogen-containing heterocyclic ring, R² represents an alkyl group, an alkenyl group, or an aralkyl group, d represents 0 or 1, and the broken line represents a linking portion with Formula (1).

In Formula (1), A¹ and A² each independently represent an aryl group, a heterocyclic group, or a group represented by Formula (2), and a group represented by Formula (2) is preferable.

The number of carbon atoms of the aryl group represented by A¹ and A² is preferably 6 to 48, more preferably 6 to 24, and even more preferably 6 to 12. Specific examples thereof include a phenyl group, and a naphthyl group. In a case where the aryl group may have a substituent, the number of carbon atoms of the aryl group means a number excluding the number of carbon atoms of the substituent.

The heterocyclic group represented by A¹ and A² is preferably a 5-membered ring or a 6-membered ring. In addition, the heterocyclic group is preferably a monocyclic ring or a fused ring, more preferably a monocyclic ring or a fused ring having 2 to 8 condensations, even more preferably a monocyclic ring or a fused ring having 2 to 4 condensations, and particularly preferably a monocyclic ring or a fused ring having 2 or 3 condensations. Examples of the hetero atom included in the heterocyclic group include a nitrogen atom, an oxygen atom, and a sulfur atom, and a nitrogen atom or a sulfur atom is preferable. The number of the hetero atoms is preferably 1 to 3 and more preferably 1 or 2. Specific examples thereof include heterocyclic groups induced from a 5-membered or 6-membered monocyclic ring containing at least one of a nitrogen atom, an oxygen atom, or a sulfur atom, and a polycyclic aromatic ring.

The aryl group and the heterocyclic group may have a substituent. Examples of the substituent include a substituent T group shown below.

(Substituent T Group)

Examples of the substituent include a halogen atom (for example, a fluorine atom, a chlorine atom, a bromine atom, and an iodine atom);

a linear or branched alkyl group (a linear or branched substituted or unsubstituted alkyl group, and preferably an alkyl group having 1 to 30 carbon atoms, for example, a methyl group, an ethyl group, an n-propyl group, an isopropyl group, a tert-butyl group, an n-octyl group, a 2-chloroethyl group, a 2-cyanoethyl group, and a 2-ethylhexyl group);

a cycloalkyl group (preferably a substituted or unsubstituted cycloalkyl group having 3 to 30 carbon atoms, for example, a cyclohexyl group, a cyclopentyl group, or a polycycloalkyl group, for example, a group having a polycyclic structure such as a bicycloalkyl group (preferably a substituted or unsubstituted bicycloalkyl group having 5 to 30 carbon atoms, for example, a bicyclo[1,2,2]heptane-2-yl group, and a bicyclo[2,2,2]octane-3-yl group), and a tricycloalkyl group, preferably a monocyclic cycloalkyl group and a bicycloalkyl group, and more preferably a monocyclic cycloalkyl group);

a linear or branched alkenyl group (a linear or branched substituted or unsubstituted alkenyl group, and preferably an alkenyl group having 2 to 30 carbon atoms, for example, a vinyl group, an allyl group, a prenyl group, a geranyl group, and an oleyl group);

a cycloalkenyl group (preferably a substituted or unsubstituted cycloalkenyl group having 3 to 30 carbon atoms, for example, a 2-cyclopenten-1-yl group, and a 2-cyclohexen-1-yl group, a polycycloalkenyl group, for example, a bicycloalkenyl group (preferably a substituted or unsubstituted bicycloalkenyl group having 5 to 30 carbon atoms, for example, a bicyclo[2,2,1]hept-2-en-1-yl group, and a bicyclo[2,2,2]oct-2-en-4-yl group), and a tricycloalkenyl group, and preferably a monocyclic cycloalkenyl group);

an alkynyl group (preferably a substituted or unsubstituted alkynyl group having 2 to 30 carbon atoms, for example, an ethynyl group, a propargyl group, and a trimethylsilylethynyl group);

an aryl group (preferably a substituted or unsubstituted aryl group having 6 to 30 carbon atoms, for example, a phenyl group, a para-tolyl group, a naphthyl group, a meta-chlorophenyl group, and an ortho-hexadecanoyl aminophenyl group);

a heteroaryl group (preferably a 5-membered to 7-membered substituted or unsubstituted monocyclic or condensed heteroaryl group, more preferably heteroaryl group which has a ring constituting atom selected from a carbon atom, a nitrogen atom, and a sulfur atom, and has at least one of any hetero atom of a nitrogen atom, an oxygen atom, and a sulfur atom, and even more preferably a 5-membered or 6-membered heteroaryl group having 3 to 30 carbon atoms, for example, a 2-furyl group, a 2-thienyl group, a 2-pyridyl group, a 4-pyridyl group, a 2-pyrimidinyl group, and a 2-benzothiazolyl group);

a cyano group;

a hydroxyl group;

a nitro group;

a carboxyl group (in which the hydrogen atom may be decomposed (that is, a carbonate group) or which may be in a salt state);

an alkoxy group (preferably a substituted or unsubstituted alkoxy group having 1 to 30 carbon atoms, for example, a methoxy group, an ethoxy group, an isopropoxy group, a tert-butoxy group, an n-ocytloxy group, and a 2-methoxyethoxy group);

an aryloxy group (preferably a substituted or unsubstituted aryloxy group having 6 to 30 carbon atoms, for example, a phenoxy group, a 2-methylphenoxy group, 2,4-di-tert-amylphenoxy group, a 4-tert-butylphenoxy group, a 3-nitrophenoxy group, and a 2-tetradecanoylaminophenoxy group);

a silyloxy group (preferably a silyloxy group having 3 to 20 carbon atoms, for example, a trimethylsilyloxy group, and a tert-butyldiraethylsilyloxy group);

a heteroaryloxy group (preferably a substituted or unsubstituted heteroaryloxy group having 2 to 30 carbon atoms, in which the heteroaryl moiety is preferably any of those heterocyclic moieties described in the above heteroaryl groups, for example, a 1-phenyl-tetrazole-5-oxy group, and a 2-tetrahydropyranyloxy group);

an acyloxy group (preferably a substituted or unsubstituted alkylcarbonyloxy group having 2 to 30 carbon atoms, or a substituted or unsubstituted arylcarbonyloxy group having 6 to 30 carbon atoms, for example, a formyloxy group, an acetyloxy group, a pivaloyloxy group, a stearoyloxy group, a benzoyloxy group, and a p-methoxyphenylcarbonyloxy group);

a carbamoyloxy group (preferably a substituted or unsubstituted carbamoyloxy group having 1 to 30 carbon atoms, for example, an N,N-dimethylcarbamoyloxy group, an N,N-diethylcarbamoyloxy group, a morpholino carbonyloxy group, an N,N-di-n-octylaminocarbonyloxy group, and an N-n-octylcarbamoyloxy group);

an alkoxycarbonyloxy group (preferably a substituted or unsubstituted alkoxycarbonyloxy group having 2 to 30 carbon atoms, for example, a methoxycarbonyloxy group, an ethoxycarbonyloxy group, a tert-butoxycarbonyloxy group, and an n-octylcarbonyloxy group);

an aryloxycarbonyloxy group (preferably a substituted or unsubstituted aryloxycarbonyloxy group having 7 to 30 carbon atoms, for example, a phenoxycarbonyloxy group, a p-methoxyphenoxycarbonyloxy group, and a para-n-hexadecyloxyphenoxycarbonyloxy group);

an amino group (preferably an amino group, and more preferably a substituted or unsubstituted alkylamino group having 1 to 30 carbon atoms, a substituted or unsubstituted arylamino group having 6 to 30 carbon atoms, or a heteroarylamino group having 0 to 30 carbon atoms, for example, an amino group, a methylamino group, a dimetylamino group, an anilino group, an N-methyl-anilino group, a diphenylamino group, and an N-1,3,5-triazine-2-yl amino group);

an acylamino group (preferably a substituted or unsubstituted alkylcarbonylamino group having 1 to 30 carbon atoms, or a substituted or unsubstituted arylcarbonylamino group having 6 to 30 carbon atoms, for example, a formylamino group, an acetylamino group, a pivaroylamino group, a lauroylamino group, a benzoylamino group, and a 3,4,5-tri-n-octyloxyphenylcarbonylamino group);

an aminocarbonylamino group (preferably a substituted or unsubstituted aminocarbonylamino group having 1 to 30 carbon atoms, for example, a carbamoylamino group, an N,N-dimethylaminocarbonylamino group, an N,N-diethylaminocarbonylamino group, and a morpholinocarbonylamino group);

an alkoxycarbonylamino group (preferably a substituted or unsubstituted alkoxycarbonylamino group having 2 to 30 carbon atoms, for example, a methoxycarbonylamino group, an ethoxycarbonylamino group, a tert-butoxycarbonylamino group, an n-octadecyloxycarbonylamino group, an N-methyl-methoxycarbonylamino group);

an aryloxycarbonylamino group (preferably a substituted or unsubstituted aryloxycarbonylamino group having 7 to 30 carbon atoms, for example, a phenoxycarbonylamino group, a para-chlorophenoxycarbonylamino group, and a meta-n-octyloxyphenoxycarbonylamino group);

a sulfamoylamino group (preferably a substituted or unsubstituted sulfamoylamino group having 0 to 30 carbon atoms, for example, a sulfamoylamino group, an N,N-dimethylaminosulfonylamino group, and an N-n-octylaminosulfonylamino group);

an alkylsulfonylamino or arylsulfonylamino group (preferably a substituted or unsubstituted alkylsulfonylamino group having 1 to 30 carbon atoms, or a substituted or unsubstituted arylsulfonylamino group having 6 to 30 carbon atoms, for example, a methylsulfonylamino group, a butylsulfonylamino group, a phenylsulfonylamino group, a 2,3,5-trichlorophenylsulfonylamino group, and a para-methylphenylsulfonylamino group);

a mercapto group;

an alkylthio group (preferably a substituted or unsubstituted alkylthio group having 1 to 30 carbon atoms, for example, a methylthio group, an ethylthio group, and an n-hexadecylthio group);

an arylthio group (preferably a substituted or unsubstituted arylthio group having 6 to 30 carbon atoms, for example, a phenylthio group, a para-chlorophenylthio group, and an meta-methoxyphenylthio group);

a heteroarylthio group (preferably a substituted or unsubstituted heteroarylthio group having 2 to 30 carbon atoms, in which the heteroaryl moiety is preferably any of those heterocyclic moieties described in the above heteroaryl groups, for example, a 2-benzothiazolylthio group, and a 1-phenyltetrazole-5-yl thio group);

a sulfamoyl group (preferably a substituted or unsubstituted sulfamoyl group having 0 to 30 carbon atoms, for example, an N-ethylsulfamoyl group, an N-(3-dodecyloxypropyl)sulfamoyl group, an N,N-dimethylsulfamoyl group, an N-acetylsulfamoyl group, an N-benzoylsulfamoyl group, and an N-(N′-phenylcarbamoyl)sulfamoyl group);

a sulfo group (in which the hydrogen atom may be decomposed (that is, a sulfonate group) or which may be in a salt state);

an alkylsulfinyl or arylsulfinyl group (preferably a substituted or unsubstituted alkylsulfinyl group having 1 to 30 carbon atoms, or a substituted or unsubstituted arylsulfinyl group having 6 to 30 carbon atoms, for example, a methylsulfinyl group, an ethylsulfinyl group, a phenylsulfinyl group, and a para-methylphenylsulfinyl group);

an alkylsulfonyl or arylsulfonyl group (preferably a substituted or unsubstituted alkylsulfonyl group having 1 to 30 carbon atoms, or a substituted or unsubstituted arylsulfonyl group having 6 to 30 carbon atoms, for example, a methylsulfonyl group, an ethylsulfonyl group, a phenylsulfonyl group, and a para-methylphenylsulfonyl group);

an acyl group (preferably a formyl group, a substituted or unsubstituted alkylcarbonyl group having 2 to 30 carbon atoms, or a substituted or unsubstituted arylcarbonyl group having 7 to 30 carbon atoms, for example, an acetyl group, a pivaloyl group, a 2-chloracetyl group, a stearoyl group, a benzoyl group, and a para-n-octyloxyphenylcarbonyl group);

an aryloxycarbonyl group (preferably a substituted or unsubstituted aryloxycarbonyl group having 7 to 30 carbon atoms, for example, a phenoxycarbonyl group, an o-chlorophenoxycarbonyl group, a meta-nitrophenoxycarbonyl group, and a para-tert-butylphenoxycarbonyl group);

an alkoxycarbonyl group (preferably a substituted or unsubstituted alkoxycarbonyl group having 2 to 30 carbon atoms, for example, a methoxycarbonyl group, an ethoxycarbonyl group, a tert-butoxycarbonyl group, and an n-octadecyloxycarbonyl group);

a carbamoyl group (preferably a substituted or unsubstituted carbamoyl group having 1 to 30 carbon atoms, for example, a carbamoyl group, an N-methylcarbamoyl group, an N,N-dimethylcarbamoyl group, an N,N-di-n-octylcarbamoyl group, and an N-(methylsulfonyl)carbamoyl group);

an arylazo or heteroarylazo group (preferably a substituted or unsubstituted arylazo group having 6 to 30 carbon atoms, or a substituted or unsubstituted heteroarylazo group having 3 to 30 carbon atoms (in which the heteroaryl moiety is preferably any of those heteroaryl moieties described in the above heteroaryl group), for example, a phenylazo group, a para-chlorophenylazo group, and a 5-ethylthio-1,3,4-thiadiazole-2-yl azo group);

an imide group (preferably a substituted or unsubstituted imide group having 2 to 30 carbon atoms, for example, an N-succinimide group, and an N-phthalimide group);

a phosphino group (preferably a substituted or unsubstituted phosphino group having 2 to 30 carbon atoms, for example, a dimethylphosphino group, a diphenylphosphino group, and a methylphenoxyphosphino group);

a hosphinyl group (preferably a substituted or unsubstituted phosphinyl group having 2 to 30 carbon atoms, for example, a phosphinyl group, a dioctyloxyphosphinyl group, and a diethoxyphosphinyl group);

a phosphinyloxy group (preferably, a substituted or unsubstituted phosphinyloxy group having 2 to 30 carbon atoms, for example, a diphenoxyphosphinyloxy group, and a dioctyloxyphosphinyloxy group);

a phosphinylamino group (preferably a substituted or unsubstituted phosphinylamino group having 2 to 30 carbon atoms, for example, a dimethoxyphosphinylamino group, and a dimethylaminophosphinylamino group); and

a silyl group (preferably a substituted or unsubstituted silyl group having from 3 to 30 carbon atoms, for example, a trimethylsilyl group, a tert-butyidimethylsilyl group, a phenyldimethylsilyl group).

The substituent that the aryl group and the heterocyclic group may have is preferably a halogen atom, an alkyl group, a hydroxy group, an amino group, or an acylamino group.

The halogen atom is preferably a chlorine atom.

The number of carbon atoms of the alkyl group is preferably 1 to 20, more preferably 1 to 10, even more preferably 1 to 5, and particularly preferably 1 to 4. The alkyl group is preferably a linear or branched alkyl group.

The amino group is preferably a group represented by —NR¹⁰⁰R¹⁰⁰. R¹⁰⁰ and R¹⁰¹ each independently represent a hydrogen atom or an alkyl group having 1 to 30 carbon atoms. The number of carbon atoms of the alkyl group is preferably 1 to 30, more preferably 1 to 20, even more preferably 1 to 10, and particularly preferably 1 to 8. The alkyl group is preferably a linear or branched alkyl group and more preferably a linear alkyl group.

The acylamino group is preferably a group represented by —NR¹⁰²—C(═O)—R¹⁰³. R¹⁰² represents a hydrogen atom or an alkyl group and preferably represents a hydrogen atom. R¹⁰³ represents an alkyl group. The number of carbon atoms of the alkyl group represented by R¹⁰² and R¹⁰³ is preferably 1 to 20, more preferably 1 to 10, even more preferably 1 to 5, and particularly preferably 1 to 4.

In a case where the aryl group and the heterocyclic group have two or more substituents, a plurality of substituents may be the same as each other or may be different from each other.

Next, the group represented by A¹ and A² and represented by Formula (2) will be described.

In Formula (2), R² represents an alkyl group, an alkenyl group, or an aralkyl group and preferably represents an alkyl group.

The number of carbon atoms of the alkyl group is preferably 1 to 30, more preferably 1 to 20, even more preferably 1 to 12, and particularly preferably 2 to 8.

The number of carbon atoms of the alkenyl group is preferably 2 to 30, more preferably 2 to 20, and even more preferably 2 to 12.

The alkyl group and the alkenyl group may be linear, branched, or cyclic and are preferably linear or branched.

The number of carbon atoms of the aralkyl group is preferably 7 to 30 and more preferably 7 to 20.

In Formula (2), the nitrogen-containing heterocyclic ring formed by Z¹ is preferably a 5-membered or 6-membered ring. In addition, the nitrogen-containing heterocyclic ring is preferably a monocyclic ring or a fused ring, more preferably a monocyclic ring or a fused ring having 2 to 8 condensations, even more preferably a monocyclic ring or a fused ring having 2 to 4 condensations, and particularly preferably a fused ring having 2 or 3 condensations. The nitrogen-containing heterocyclic ring may include, in addition to a nitrogen atom, a sulfur atom. Further, the nitrogen-containing heterocyclic ring may have a substituent. Examples of the substituent include the groups described in the substituent T group above. For example, a halogen atom, an alkyl group, a hydroxy group, an amino group, or an acylamino group is preferable, and a halogen atom or an alkyl group is more preferable. The halogen atom is preferably a chlorine atom. The number of carbon atoms of the alkyl group is preferably 1 to 30, more preferably 1 to 20, and even more preferably 1 to 12. The alkyl group is preferably a linear or branched alkyl group.

The group represented by Formula (2) is preferably a group represented by Formula (3) or (4).

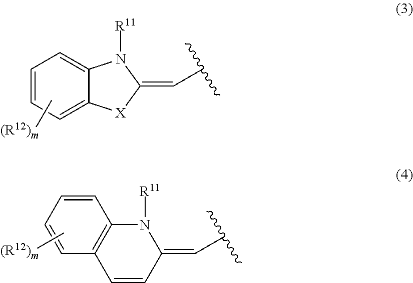

In Formulae (3) and (4), represents an alkyl group, an alkenyl group, or an aralkyl group, R¹² represents a substituent, in a case where m is 2 or more, R¹²'s may be linked to form a ring, X represents a nitrogen atom or CR¹³R¹⁴, R¹³ and R¹⁴ each independently represent a hydrogen atom or a substituent, m represents an integer of 0 to 4, and the broken line represents a linking portion with Formula (1).

R¹¹ in Formulae (3) and (4) is the same as R² in Formula (2) and the preferable range thereof is also the same.

R¹² in Formulae (3) and (4) represents a substituent. Examples of the substituent include the groups described in the substituent T group above. For example, a halogen atom, an alkyl group, a hydroxy group, an amino group, or an acylamino group is preferable and a halogen atom or an alkyl group is more preferable. The halogen atom is preferably a chlorine atom. The number of carbon atoms of the alkyl group is preferably 1 to 30, more preferably 1 to 20, and even more preferably 1 to 12. The alkyl group is preferably a linear or branched alkyl group.

In a case where m is 2 or more, R¹²'s may be linked to form a ring. Examples of the ring include an alicyclic ring (a non-aromatic hydrocarbon ring), an aromatic ring, and a heterocyclic ring. The ring may be a monocyclic ring or may be a bicyclic ring. As the linking group in a case where the substituents are linked to form a ring, a divalent linking group selected from the group consisting of —CO—, —O—, —NH—, a divalent aliphatic group, a divalent aromatic group, and combinations thereof can be used for linking. For example, it is preferable that R¹²'s are linked to form a benzene ring.

X in Formula (3) represents a nitrogen atom or CR¹³R¹⁴, and R¹³ and R¹⁴ each independently represent a hydrogen atom or a substituent. Examples of the substituent include the groups described in the substituent T group above. For example, an alkyl group or the like may be exemplified. The number of carbon atoms of the alkyl group is preferably 1 to 20, more preferably 1 to 10, even more preferably 1 to 5, particularly preferably 1 to 3, and most preferably 1. The alkyl group is preferably a linear or branched alkyl group and more preferably a linear alkyl group.

m represents an integer of 0 to 4 and preferably represents an integer of 0 to 2.

The cation in Formula (1) is present in a delocalized manner as shown below.

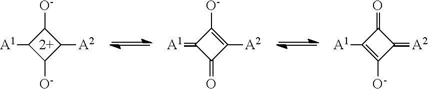

The infrared light absorbing layer 14 may include other components as well as the infrared absorber. Regarding other components, components that an infrared light absorbing composition, which will be described later, may include may be exemplified, and the detailed description will be made later.

(Method for Producing Infrared Light Absorbing Layer 14)

The method for producing the infrared light absorbing layer 14 is not particularly limited and for example, the infrared light absorbing layer 14 can be formed by applying an infrared light absorbing composition containing the infrared absorber to a predetermined substrate, and drying the composition as necessary.

The infrared light absorbing composition includes the infrared absorber and may further include a binder (for example, resin and gelatin), a polymerizable compound, an initiator, or a surfactant, in addition to the infrared absorber.

Examples of the binder (resin) include a (meth)acrylic resin, a styrene resin, an epoxy resin, an ene-thiol resin, a polycarbonate resin, a polyether resin, a polyacylate resin, a polysulfone resin, a polyethersulfone resin, a polyparaphenylene resin, a polyarylene ether phosphine oxide resin, a polyimide resin, a polyamideimide resin, a polyolefin resin, a cyclic olefin resin, and a polyester resin. As the binder, one resin selected from these resins may be used or two or more resins may be mixed and used.

The weight-average molecular weight (Mw) of the resin is preferably 2,000 to 2,000,000. The upper limit is more preferably 1,000,000 or less and even more preferably 500,000 or less. The lower limit is more preferably 3,000 or more and even more preferably 5,000 or more.

In a case of an epoxy resin, the weight-average molecular weight (Mw) of the epoxy resin is preferably 100 or more and more preferably 200 to 2,000,000. The upper limit is more preferably 1,000,000 or less and particularly preferably 500,000 or less.

The 5% thermal mass reduction temperature at heating the resin from 25° C. at 20° C./min is preferably 200° C. or higher and more preferably 260° C. or higher.

In addition, as the resin, a polymer having one repeating unit selected from a repeating unit represented by Formula (MX2-1), a repeating unit represented by Formula (MX2-2), and a repeating unit represented by Formula (MX2-3) can be used.

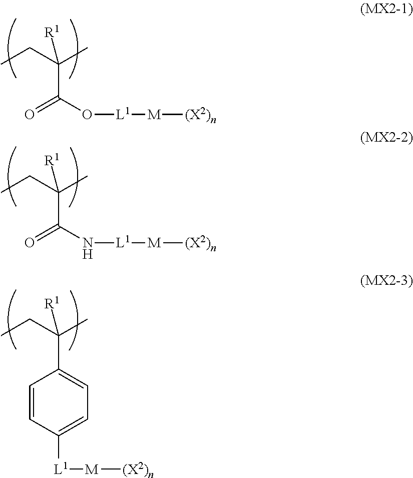

M represents an atom selected from Si, Ti, Zr, and Al, X² represents a substituent or a ligand, at least one of n X²'s is one of a hydroxy group, an alkoxy group, an acyloxy group, a phosphoryloxy group, a sulfonyloxy group, an amino group, an oxime group, and O=C(R^{a})(R^{b}), X²'s may be bonded to each other to form a ring, R^{a} and R^{b} each independently represent a monovalent organic group, R¹ represents a hydrogen atom or an alkyl group, L¹ represents a single bond or a divalent linking group, and n represents the number of linking portions of M with X².

M represents an atom selected from Si, Ti, Zr, and Al, preferably represents Si, Ti, or Zr, and more preferably represents Si.

X² represents a substituent or a ligand, at least one of n X²'s is one of a hydroxy group, an alkoxy group, an acyloxy group, a phosphoryloxy group, a sulfonyloxy group, an amino group, an oxime group, and O=C(R^{a})(R^{b}), and X²'s may be bonded to each other to form a ring.

It is preferable that at least one of n X²'s is one of an alkoxy group, an acyloxy group, and an oxime group, it is more preferable that at least one of n X²'s is an alkoxy group, and it is even more preferable that all X²'s are alkoxy groups. In a case where X² is O=C(R^{a})(R^{b}), X² is bonded to M by an unshared electron pair of an oxygen atom of a carbonyl group (—CO—). R^{a} and R^{b} each independently represent a monovalent organic group.

The number of carbon atoms of the alkoxy group represented by X² is preferably 1 to 20, more preferably 1 to 10, even more preferably 1 to 5, and particularly preferably 1 to 2. The alkoxy group may be any one of a linear alkoxy group, a branched alkoxy group, and a cyclic alkoxy group, and is preferably a linear alkoxy group or a branched alkoxy group and more preferably a linear alkoxy group. The alkoxy group may have a substituent or may not have a substituent and preferably does not have a substituent. Examples of the substituent include a halogen atom (preferably a fluorine atom), a polymerizable group (for example, a vinyl group, a (meth)acryloyl group, a styryl group, an epoxy group, and an oxetane group), an amino group, an isocyanate group, an isocyanurate group, an ureido group, a mercapto group, a sulfide group, a sulfo group, a carboxyl group, and a hydroxyl group.

Examples of the acyloxy group represented by X² include a substituted or unsubstituted alkylcarbonyloxy group having 2 to 30 carbon atoms, and a substituted or unsubstituted arylcarbonyloxy group having 6 to 30 carbon atoms. For example, a formyloxy group, an acetyloxy group, a pivaloyloxy group, stearoyloxy group, a benzoyloxy group, a p-methoxyphenylcarbonyloxy group, and the like may be exemplified. Examples of the substituent include the followings.

The number of carbon atoms of the oxime group represented by X² is preferably 1 to 20, more preferably 1 to 10, and even more preferably 1 to 5. Examples thereof include an ethyl methyl ketoxime group.

Examples of the amino group represented by X² include an amino group, a substituted or unsubstituted alkylamino group having 1 to 30 carbon atoms, a substituted or unsubstituted arylamino group having 6 to 30 carbon atoms, and a heterocylic amino group having 0 to 30 carbon atoms. For example, an amino group, a mehtylamino group, a dimethylamino group, an anilino group, an N-mehtyl-anilino group, a diphenylamino group, and an N-1,3,5-triazine-2-yl amino group, and the like may be exemplified. The substituent includes the substituent described above.

Examples of the monovalent organic group represented by R^{a} and R^{b} include an alkyl group, an aryl group, and a group represented by —R¹⁰¹—COR¹⁰².

The number of carbon atoms of the alkyl group is preferably 1 to 20 and more preferably 1 to 10. The alkyl group may be any one of a linear alkyl group, a branched alkyl group, and a cyclic alkyl group. The alkyl group may not have a substituent or may have the substituent described above.

The number of carbon atoms of the aryl group is preferably 6 to 20 and more preferably 6 to 12. The aryl group may not have a substituent or may have the substituent described above.

In the group represented by —R¹⁰¹—COR¹⁻², R¹⁰¹ represents an arylene group and R¹⁰² represents an alkyl group or an aryl group.

The number of carbon atoms of the arylene group represented by R¹⁰¹ is preferably 1 to 20 and more preferably 1 to 10. The arylene group may be any one of a linear arylene group, a branched arylene group, and a cyclic arylene group. The arylene group may not have a substituent or may have the substituent described above.

The alkyl group and the aryl group represented by R¹⁰² include the groups described in R^{a} and R^{b} and the preferable ranges thereof are also the same.

In the substituent and the ligand represented by X², as the substituent other than a hydroxy group, an alkoxy group, an acyloxy group, a phosphoryloxy group, a sulfonyloxy group, an amino group, and an oxime group, a hydrocarbon group is preferable. Examples of the hydrocarbon group include an alkyl group, an alkenyl group, and an aryl group.

The alkyl group may be any one of a linear alkyl group, a branched alkyl group, and a cyclic alkyl group. The number of carbon atoms of the linear alkyl group is preferably 1 to 20, more preferably 1 to 12, and even more preferably 1 to 8. The number of carbon atoms of the branched alkyl group is preferably 3 to 20, more preferably 3 to 12, and even more preferably 3 to 8. The cyclic alkyl group may be any one of a monocyclic alkyl group or a polycyclic alkyl group. The number of carbon atoms of the cyclic alkyl group is preferably 3 to 20, more preferably 4 to 10, and even more preferably 6 to 10.

The number of carbon atoms of the alkenyl group is preferably 2 to 10, more preferably 2 to 8, and even more preferably 2 to 4.

The number of carbon atoms of the aryl group is preferably 6 to 18, more preferably 6 to 14, and even more preferably 6 to 10.

The hydrocarbon group may have a substituent and examples of the substituent include an alkyl group, a halogen atom (preferably a fluorine atom), a polymerizable group (for example, a vinyl group, a (meth)acryloyl group, a styryl group, an epoxy group, and an oxetane group), an amino group, an isocyanate group, an isocyanurate group, an ureido group, a mercapto group, a sulfide group, a sulfo group, a carboxyl group, a hydroxyl group, and an alkoxy group.

R¹ represents a hydrogen atom or an alkyl group. The number of carbon atoms of the alkyl group is preferably 1 to 5, more preferably 1 to 3, and even more preferably 1. The alkyl group is preferably any one of a linear alkyl group and a branched alkyl group and more preferably a linear alkyl group. In the alkyl group, the hydrogen atom may be partially or entirely substituted with a halogen atom (preferably a fluorine atom).

L¹ represents a single bond or a divalent linking group. Examples of the divalent linking group include an alkylene group, an arylene group, —O—, —S—, —CO—, —COO—, —OCO—, —SO₂—, —NR¹⁰— (in which R¹⁰ represents a hydrogen atom or an alkyl group and preferably represents a hydrogen atom), and a group obtained by combining these groups. A group obtained by combining at least one of an alkylene group, an arylene group, or an alkylene group, and —O— is preferable.

The number of carbon atoms of the alkylene group is preferably 1 to 30, more preferably 1 to 15, and even more preferably 1 to 10. The alkylene group may have a substituent or preferably does not have a substituent. The alkylene group may be any one of a linear alkylene group, a branched alkylene group, and a cyclic alkylene group. In addition, the cyclic alkylene group may be any one of a monocyclic alkylene group and a polycyclic alkylene group.

The number of carbon atoms of the arylene group is preferably 6 to 18, more preferably 6 to 14, and even more preferably 6 to 10. The arylene group is preferably a phenylene group.

The polymer may contain repeating units other than the repeating units represented by Formulae (MX2-1), (MX2-2), and (MX2-3).

As components forming other repeating units, the description of copolymerization components described in paragraphs 0068 to 0075 of JP2010-106268A (<0112> to <0118> in the present specification of corresponding US Patent App. No. 2011/0124824A) can be referred to, and the contents thereof are incorporated in the present specification.

Examples of preferable other repeating units include repeating units represented by Formulae (MX3-1) to (MX3-4).

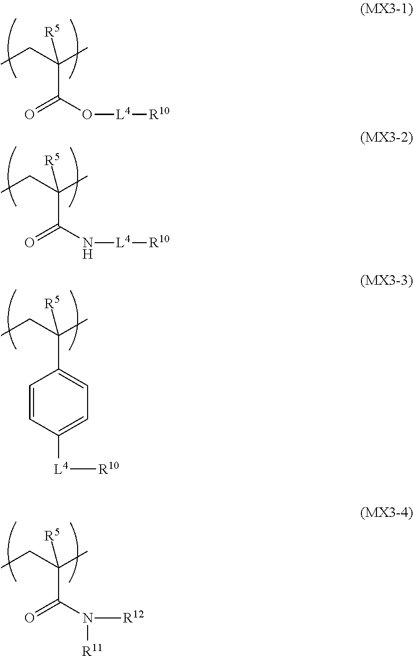

In Formulae (MX3-1) to (MX3-4), R⁵ represents a hydrogen atom or an alkyl group, L⁴ represents a single bond or a divalent linking group, and R¹⁰ represents an alkyl group or an aryl group. R¹¹ and R¹² each independently represent a hydrogen atom, an alkyl group, or an aryl group.

R⁵ is the same as R¹ in Formulae (MX2-1) to (MX2-3) and the preferable range thereof is also the same.

L⁴ is the same as L¹ in Formulae (MX2-1) to (MX2-3), and the preferable range thereof is also the same.

The alkyl group represented by R¹⁰ may be any one of a linear alkyl group, a branched alkyl group, and a cyclic alkyl group, and is preferably a cyclic alkyl group. The number of carbon atoms of the alkyl group is preferably 1 to 30, more preferably 1 to 20, and even more preferably 1 to 10. The alkyl group may have a substituent and examples of the substituent include the substituents described above.

The aryl group represented by R¹⁰ may be a monocyclic ring or a polycyclic ring and is preferably a monocyclic ring. The number of carbon atoms of the aryl group is preferably 6 to 18, more preferably 6 to 12, and even more preferably 6.

R¹⁰ is preferably a cyclic alkyl group or aryl group.

R₁₁ and R¹² each independently represent a hydrogen atom, an alkyl group, or an aryl group. Examples of the alkyl group and the aryl group include the same groups in R¹⁰ described above. An alkyl group is preferable. The alkyl group is preferably a linear alkyl group. The number of carbon atoms of the alkyl group is preferably 1 to 30, more preferably 1 to 20, even more preferably 1 to 10, and particularly preferably 1 to 5.

In a case where the polymer include other repeating units (preferably repeating units represented by Formulae (MX3-1) to (MX3-4)), a molar ratio between a total of the repeating units represented by Formulae (MX2-1) to (MX2-3) and a total of other repeating units is preferably 95:5 to 20:80 and more preferably 90:10 to 30:70. By increasing the content of the repeating units represented by Formulae (MX2-1) to (MX2-3) in the above range, moisture resistance and solvent resistance are likely to be further enhanced. In addition, by decreasing the content of the repeating units represented by Formulae (MX2-1) to (MX2-3) in the above range, heat resistance is likely to be further improved.

Specific examples of the polymer are as follows.

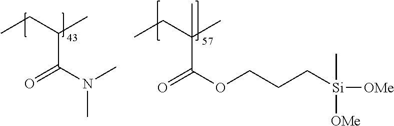

The weight-average molecular weight of the polymer is preferably 500 to 300000. The lower limit is more preferably 1000 or more and even more preferably 2000 or more. The upper limit is more preferably 250000 or less and even more preferably 200000 or less.

As the (meth)acrylic resin, a polymer including a constitutional unit derived from (meth)acrylic acid and/or ester thereof may be exemplified. Specifically, a polymer obtained by polymerizing at least one selected from (meth)acrylic acid, (meth)acrylic acid esters, (meth)acrylamide, or (meth)acrylonitrile may be exemplified.

Examples of the polyester resin include polymers that can be obtained by reaction of polyols (for example, ethylene glycol, propylene glycol, glycerine, and trimethylolpropane), and polybasic acids (for example, aromatic dicarboxylic acid such as terephthalic acid isophthalic acid, and naphthalene dicarboxylic acid, and an aromatic dicarboxylic acid in which the hydrogen atom of the aromatic nucleus in these groups is substituted with a methyl group, an ethyl group, a phenyl group, and the like, aliphatic dicarboxylic acid having 2 to 20 carbon atoms such as adipic acid, sebacic acid, and dodecanedicarboxylic acid, and alicyclic dicarboxylic acid such as cyclohexanedicarboxylic acid), and polymers that can be obtained by ring opening polymerization of cyclic ester compounds such as caprolactone monomers (for example, a polycaprolactone).

Examples of the epoxy resin include bisphenol A type epoxy resins, bisphenol F type epoxy resins, phenol novolac type epoxy resins, cresol novolac type epoxy resins, and aliphatic epoxy resins. Examples of commercially available products include the followings.

Examples of the bisphenol A type epoxy resins include JER827, JER828, JER834, JER1001, JER1002, JER1003, JER1055, JER1007, JER1009, and JER1010 (all manufactured by Japan Epoxy Resin Co. Ltd.), and EPICLON860, EPICLON1050, EPICLON1051, and EPICLON1055 (all manufactured by DIC Corporation).

Examples of the bisphenol F type epoxy resins include JER806, JER807, JER4004, JER4005, JER4007, and JER4010 (all manufactured by Japan Epoxy Resin Co. Ltd.), EPICLON830, and EPICLON835 (all manufactured by DIC Corporation), and LCE-21, and RE-602S (all manufactured by Nippon Kayaku Co., Ltd.).

Examples of the phenol novolac type epoxy resins include JER152, JER154, JER157S70, and JER157S65 (all manufactured by Japan Epoxy Resin Co. Ltd.), and EPICLON N-740, EPICLON N-770, and EPICLON N-775 (all manufactured by DIC Corporation).

Examples of the cresol novolac type epoxy resins include EPICLON N-660, EPICLON N-665, EPICLON N-670, EPICLON N-673, EPICLON N-680, EPICLON N-690, and EPICLON N-695 (all manufactured by DIC Corporation), and EOCN-1020 (all manufactured by Nippon Kayaku Co., Ltd.).

Examples of the aliphatic epoxy resins include ADEKA RESIN EP-4080S, ADEKA RESIN EP-4085S, and ADEKA RESIN EP-4088S (all manufactured by ADEKA CORPORATION), CELLOXIDE 2021P, CELLOXIDE 2081, CELLOXIDE 2083, CELLOXIDE 2085, EHPE3150, EPOLEAD PB 3600, and EPOLEAD PB 4700 (all manufactured by Daicel Corporation), and DENACOL EX-212L, EX-214L, EX-216L, EX-321L, and EX-850L (all manufactured by Nagase ChemteX Corporation).

In addition, ADEKA RESIN EP-4000S, ADEKA RESIN EP-4003S, ADEKA RESIN EP-4010S, and ADEKA RESIN EP-4011S (all manufactured by ADEKA CORPORATION), NC-2000, NC-3000, NC-7300, XD-1000, EPPN-501, and EPPN-502 (all manufactured by ADEKA CORPORATION), and JER1031S (manufactured by Japan Epoxy Resin Co. Ltd.) may be used.

In addition, the resin may have an acid group. Examples of the acid group include a carboxyl group, a phosphoric acid group, a sulfonic acid group, and a phenolic hydroxyl group. One of these acid groups may be used or two or more thereof may be used.

As the resin having an acid group, a polymer having a carboxyl group on a side chain thereof is preferable, and examples thereof include a methacrylic acid copolymer, an acrylic acid copolymer, an itaconic acid copolymer, a crotonic acid copolymer, a maleic acid copolymer, a partially esterified maleic acid copolymer, an alkali soluble phenol resin such as a novolac type resin, an acidic cellulose derivative having a carboxyl group on a side chain thereof, and a copolymer obtained by adding an acid anhydride to a polymer having a hydroxyl group. Particularly, a copolymer of (meth)acrylic acid and another monomer copolymerizable with (meth)acrylic acid is suitable. Examples of another monomer copolymerizable with (meth)acrylic acid include an alkyl(meth)acrylate, an aryl(meth)acrylate, and a vinyl compound. Examples of the alkyl(meth)acrylate and aryl(meth)acrylate include methyl(meth)acrylate, ethyl(meth)acrylate, propyl(meth)acrylate, butyl(meth)acrylate, isobutyl(meth)acrylate, pentyl(meth)acrylate, hexyl(meth)acrylate, octyl(meth)acrylate, phenyl(meth)acrylate, benzyl(meth)acrylate, tolyl(meth)acrylate, naphthyl(meth)acrylate, and cyclohexyl(meth)acrylate. Examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, a polystyrene macromonomer, a polymethyl methacrylate macromonomer, and an N-substituted maleimide monomer described in JP1999-300922A (JP-H10-300922A), such as N-phenylmaleimide and N-cyclohexylmaleimide. As the another monomer copolymerizable with the (meth)acrylic acid, only one monomer may be used, or two or more monomers may be used.

As the resin having an acid group, a benzyl(meth)acrylate/(meth)acrylic acid copolymer, a benzyl(meth)acrylate/(meth)acrylic acid/2-hydroxyethyl(meth)acrylate copolymer, and a multi-copolymer constituted of benzyl(meth)acrylate/(meth)acrylic acid/another monomer are preferable. In addition, a copolymer of 2-hydroxyethyl(meth)acrylate, and a 2-hydroxypropyl(meth)acrylate/polystyrene macromonomer/benzyl methacrylate/methacrylic acid copolymer, a 2-hydroxy-3 phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, and a 2-hydroxyethyl methacrylate/polystyrene macromonomer/benzyl methacrylate/methacrylic acid copolymer, which are described in JP1995-140654A (JP-H07-140654A), are also preferable.

As the resin having an acid group, a polymer (a) obtained by polymerizing monomer components including a compound represented by Formula (ED1) and/or a compound represented by Formula (ED2) (hereinafter, these compounds are sometimes referred to as “esther dimer”) is also preferable.

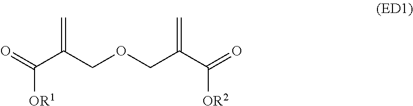

In Formula (ED1), R¹ and R² each independently represent a hydrogen atom or a hydrocarbon group having 1 to 25 carbon atoms, which may have a substituent.

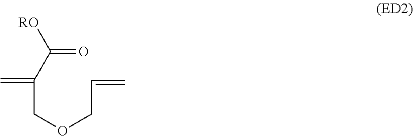

In Formula (ED2), R represents a hydrogen atom or an organic group having 1 to 30 carbon atoms. With respect to the specific example of Formula (ED2), the description of JP2010-168539A can be referred to.

In Formula (ED1), the hydrocarbon group having 1 to 25 carbon atom, represented by R¹ and R², which may have a substituent, is not particularly limited, and examples thereof include linear or branched alkyl groups such as a methyl group, an ethyl group, an n-propyl group, an isopropyl group, an n-butyl group, an isobutyl group, a tert-butyl group, a tert-amyl group, a stearyl group, a lauryl group, and a 2-ethylhexyl group; aryl groups such as phenyl; alicyclic groups such as a cyclohexyl group, a tert-butylcyclohexyl group, a dicyclopentadienyl group, a tricyclodecanyl group, an isobornyl group, an adamantyl group, and a 2-methyl-2-adamantyl group; alkyl groups substituted with an alkoxy group such as a 1-methoxyethyl group and a 1-ethoxyethyl group; and alkyl groups substituted with an aryl group such as a benzyl group. Among these, from the viewpoint of heat resistance, substituents of primary or secondary carbon, which are not easily eliminated by an acid or heat, such as a methyl group, an ethyl group, a cyclohexyl group, and a benzyl group, are preferable.

Regarding specific examples of ether dimers, it is possible to refer to, for example, Paragraph “0317” of JP2013-29760A, and the contents thereof are incorporated in the present specification. One ether dimer may be used or two or more ether dimmers may be used. Structures derived from the compound represented by Formula (ED) may be copolymerized with other monomers.

The resin having an acid group may include a structural unit derived from a compound represented by Formula (X).

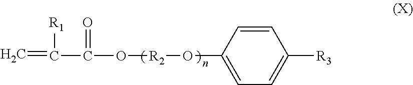

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may have a benzene ring. n represents an integer of 1 to 15.

In Formula (X), the number of carbon atoms of the alkylene group of R₂ is preferably 2 to 3. In addition, the number of carbon atoms of the alkyl group of R₃ is 1 to 20 and preferably 1 to 10, and the alkyl group of R₃ may include a benzene ring. Examples of the alkyl group including a benzene ring represented by R₃ include a benzyl group and a 2-phenyl(iso)propyl group.

Specific examples of the resin having an acid group include the following structures.

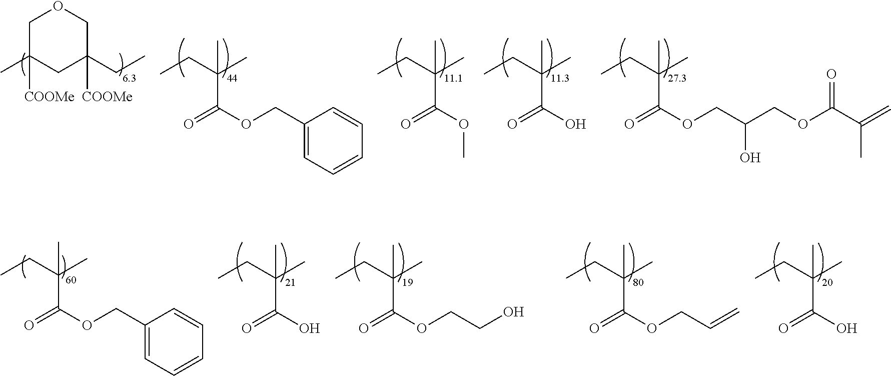

With respect to the resin having an acid group, the descriptions in paragraphs 0558 to 0571 of JP2012-208494A (<0685> to <0700> in the specification of corresponding US2012/0235099A), and paragraphs 0076 to 0099 of JP2012-198408A can be referred to, and the contents of which are incorporated in the present specification.

The acid value of the resin having an acid group is preferably 30 to 200 mgKOH/g. The lower limit is more preferably 50 mgKOH/g or more and even more preferably 70 mgKOH/g or more. The upper limit is more preferably 150 mgKOH/g or less and even more preferably 120 mgKOH/g or less.

In addition, the resin may have a polymerizable group. By the resin having a polymerizable group, a hard film can be formed.

Examples of the polymerizable group include a (meth)allyl group and a (meth)acryloyl group. Examples of the resin containing the polymerizable group include DIANAL NR series (manufactured by Mitsubishi Rayon Co., Ltd.), Photomer 6173 (a polyurethane acrylic oligomer containing COOH, manufactured by Diamond Shamrock Co. Ltd.), VISCOTE R-264 and KS RESIST 106 (both manufactured by Osaka Organic Chemical Industry, Ltd.), CYCLOMER P series (for example, ACA230AA) and PRAXEL CF200 series (all manufactured by Daicel Chemical Industries, Ltd.), Ebecryl 3800 (manufactured by Daicel-UCB Company, Ltd.), and AKURIKYUA RD-F8 (manufactured by Nippon Shokubai Co., Ltd.). In addition, the above-described epoxy resins may be used.

The content of the resin is preferably 15% by mass or more, more preferably 20% by mass or more, and even more preferably 25% by mass or more with respect to a total solid content of the infrared light absorbing composition. The upper limit is preferably 80% by mass or less, more preferably 70% by mass or less, and even more preferably 50% by mass or less.

The infrared light absorbing composition preferably contains at least one selected from a resin, gelatin, and a polymerizable compound, and more preferably contains at least one selected from gelatin and a polymerizable compound. According to the aspect, an infrared light absorbing layer having excellent heat resistance and solvent resistance is easily produced. In addition, in a case of using a polymerizable compound, a polymerizable compound and a photopolymerization initiator are preferably used in combination.

(Gelatin)

The infrared light absorbing composition preferably contains a gelatin. By incorporating the gelatin, an infrared light absorbing layer having excellent heat resistance is easily formed. Although the detailed mechanism is not clear, it is assumed that an associate is easily formed by the infrared absorber and the gelatin. Particularly, in a case of using an infrared absorber and a cyanine compound, an infrared light absorbing layer having excellent heat resistance is easily formed.

The gelatin includes acid treated gelatin and alkali treated gelatin (lime treatment or the like) depending on the synthesis method thereof, and any one of these can be preferably used. The molecular weight of the gelatin is preferably 10,000 to 1,000,000. In addition, denatured gelatin that is prepared by subjecting to a denaturing treatment utilizing the amino group or carboxyl group of the gelatin (for example, phthalate gelatin or the like) may be used. For the gelatin, inert gelatin (for example, NITTA GELATIN 750), phthalated gelatin (for example, NITTA GELATIN 801), and the like can be used.

In order to enhance the water resistance and the mechanical strength of the infrared light absorbing layer, it is preferable to harden the gelatin using various compounds. As a hardener, known hardeners of the related art can be used and examples thereof include aldehyde-based compounds such as formaldehyde and glutar aldehyde, compounds having a reactive ethylenically unsaturated bond described in U.S. Pat. No. 3,288,775A and the like, reactive olefin-containing compounds described in U.S. Pat. No. 3,642,486A, JP1974-13563B (JP-S49-13563B), and the like, aziridine-based compounds described in U.S. Pat. No. 3,017,280A or the like, epoxy-based compounds described in U.S. Pat. No. 3,091,537A, halogen carboxy aldehydes such as mucochloric acid, dioxanes such as dihydroxydioxane and dichlorodioxane, and inorganic hardeners such as chromium alum, and zirconium sulfate.

The content of the gelatin in the infrared light absorbing composition is preferably 1% to 99% by mass with respect to the total solid content of the infrared light absorbing composition. The lower limit is more preferably 10% by mass or more and even more preferably 20% by mass or more. The upper limit is more preferably 95% by mass or less and even more preferably 90% by mass or less.

(Polymerizable Compound)

The infrared light absorbing composition preferably contains a polymerizable compound. Examples of the polymerizable compound include compounds having a group having an ethylenically unsaturated bond, a cyclic ether (epoxy or oxetane) group, and a methylol group, and the like, and a compound having an ethylenically unsaturated bond is preferable. Examples of the group having an ethylenically unsaturated bond include a vinyl group, a (meth)allyl group, and a (meth)acryloyl group.

The polymerizable compound may be a monofunctional compound or a polyfunctional compound and is preferably a polyfunctional (a polymerizable compound having two or more polymerizable groups). By incorporating the polyfunctional compound, an infrared light absorbing layer having a three dimensional crosslinked product can be formed. Then, since the infrared light absorbing layer has a three dimensional crosslinked product, heat resistance and solvent resistance can be improved. The number of functional groups of the polymerizable compound is not particularly limited and is preferably 2 to 8 and more preferably 3 to 6.

As the polymerizable compound, for example, any one of chemical forms such as a monomer, a prepolymer, an oligomer, a mixture thereof, and a multimer thereof may be used.

The polymerizable compound is preferably a tri- to pentadecafunctional (meth)acrylate compound and more preferably a tri- to hexafunctional (meth)acrylate compound.

The molecular weight of the polymerizable compound is preferably less than 2000, more preferably 100 or more and less than 2000, and even more preferably 200 or more and less than 2000.

The polymerizable compound is preferably a compound including a group having an ethylenically unsaturated bond.

With respect to examples of the compound including a group having an ethylenically unsaturated bond, the descriptions in paragraphs 0033 to 0034 of JP2013-253224A can be referred to, and the contents thereof are incorporated in the present specification.

As specific examples thereof, ethyleneoxy-modified pentaerythritol tetraacrylate (as a commercially available product, NK ESTER ATM-35E; manufactured by Shin-Nakamura Chemical Co., Ltd.), dipentaerythritol triacrylate (as a commercially available product, KAYARAD D-330; manufactured by Nippon Kayaku Co., Ltd.), dipentaerythritol tetraacrylate (as a commercially available product, KAYARAD D-320; manufactured by Nippon Kayaku Co., Ltd.), dipentaerythritol penta(meth)acrylate (as a commercially available product, KAYARAD D-310; manufactured by Nippon Kayaku Co., Ltd.), dipentaerythritol hexa(meth)acrylate (as commercially available products, KAYARAD DPHA; manufactured by Nippon Kayaku Co., Ltd., A-DPH-12E; manufactured by Shin-Nakamura Chemical Co., Ltd.), and a structure in which ethylene glycol, and propylene glycol residues are interposed between these (meth)acryloyl groups are preferable. An oligomer type of these can be also used.

In addition, polymerizable compounds described in paragraphs 0034 to 0038 of JP2013-253224A can be referred to, and the contents thereof are incorporated in the present specification.

In addition, polymerizable monomers described in paragraph 0477 of JP2012-208494A (<0585> of the present specification of corresponding US Patent App. No. 2012/0235099) and the like may be exemplified and the contents thereof are incorporated in the present specification.

Further, diglycerine ethyleneoxide (EO)-modified (meth)acrylate (as a commercially available product, M-460; manufactured by Toagosei Co., Ltd.) is preferable. Pentaerythritol tetraacrylate (A-TMMT; manufactured by Shin-Nakamura Chemical Co., Ltd.), and 1,6-hexanediol diacrylate (KAYARAD HDDA; manufactured by Nippon Kayaku Co., Ltd.) are also preferable. An oligomer type of these can be also used. Examples thereof include RP-1040 (manufactured by Nippon Kayaku Co., Ltd.).

The compound including a group having an ethylenically unsaturated bond may further have an acid group such as a carboxyl group, a sulfonic acid group, or a phosphoric acid group.

Examples of the compound having an acid group include an ester of an aliphatic polyhydroxy compound and an unsaturated carboxylic acid. A polyfunctional monomer caused to have an acid group by being reacted with a nonaromatic carboxylic acid anhydride is preferable in an unreacted hydroxyl group of an aliphatic polyhydroxy compound. More preferably, an aliphatic polyhydroxy compound is pentaerythritol and/or dipentaerythritol. Examples of a commercially available product include M-305, M-510, and M-520 of ARONIX series, manufactured by Toagosei Co., Ltd., as a polybasic acid-modified acrylic oligomer.

The acid value of the compound having an acid group is preferably 0.1 to 40 mgKOH/g. The lower limit is more preferably 5 mgKOH/g or more. The upper limit is more preferably 30 mgKOH/g or less.

As the polymerizable compound, a compound having a caprolactone structure is also preferable aspect.

With respect to the compound having a caprolactone structure, the description of paragraphs 0042 to 0045 of JP2013-253224A can be referred to and the contents thereof are incorporated in the present specification.

Examples of commercially available products include SR-494 that is tetrafunctional acrylate having four ethyleneoxy chains, manufactured by Sartomer Co., Ltd., and DPCA-60 that is a hexafunctional acrylate having six pentyleneoxy chains and TPA-330 that is trifunctional acrylate having three isobutyleneoxy chains, manufactured by Nippon Kayaku Co., Ltd.

(Polymerization Initiator)

The infrared light absorbing composition may contain a polymerization initiator. As the polymerization initiator, a thermal polymerization initiator or a photopolymerization initiator may be used and a photopolymerization initiator is preferable. Hereinafter, a photopolymerization initiator will be mainly described in detail.

The content of the photopolymerization initiator is preferably 0.01% to 30% by mass with respect to the total solid content of the infrared light absorbing composition. The lower limit is more preferably 0.1% by mass or more and even more preferably 0.5% by mass or more. The upper limit is more preferably 20% by mass or less and even more preferably 15% by mass or less.

Only one photopolymerization initiator may be used or two or more photopolymerization initiators may be used. In a case of using two or more photopolymerization initiators, a total amount thereof is preferably in the above range.

The photopolymerization initiator is not particularly limited and can be appropriately selected according to purposes as long as the photopolymerization initiator initiates polymerization of a curable compound with light. In a case where the polymerization is initiated with light, it is preferable for the photopolymerization initiator to have photosensitivity from an ultraviolet range to visible light.

The photopolymerization initiator is preferably a compound having at least an aromatic group. Examples thereof include an acylphosphine compound, an acetophenone-based compound, an α-aminoketone compound, a benzophenone compound, a benzoin ether compound, a ketal derivative compound, a thioxanthone compound, an oxime compound, a hexaarylbiimidazole compound, a trihalomethyl compound, an azo compound, organic peroxide a diazonium compound, an iodonium compound, a sulfonium compound, an azinium compound, a benzoin ether compound, an onium salt compound (such as a metallocene compound), an organic boron salt compound, a disulfone compound, and a thiol compound.

As the photopolymerization initiator, the description of paragraphs 0217 to 0228 of JP2013-253224A can be referred to and the contents thereof are incorporated in the present specification.

As the oxime compound, IRGACURE-OXE01 (manufactured by BASF SE), IRGACURE-OXE02 (manufactured by BASF SE), TR-PBG-304 (manufactured by CHANGZHOU TRONLY NEW ELECTRONIC MATERIALS CO., LTD.), ADEKA ARKLS NCI-831 (manufactured by ADEKA Corporation), ADEKA ARKLS NCI-930 (manufactured by ADEKA Corporation), and the like, which are commercially available products, can be used.

As the acetophenone-based compound, IRGACURE-907, IRGACURE-369, and IRGACURE-379 (trade name: all manufactured by BASF SE), which are commercially available products, can be used. As the acylphosphine compound, IRGACURE-819 and DAROCUR-TPO (trade name: all manufactured by BASF SE), which are commercially available products, can be used.

The present invention can use an oxime compound having a fluorine atom as the photopolymerization initiator. Specific examples of the oxime compound having a fluorine atom include compounds disclosed in JP2010-262028A, compounds 24, and 36 to 40 disclosed in JP2014-500852A, and a compound (C-3) disclosed in JP2013-164471A. The contents thereof are incorporated in the present specification.

(Solvent)

The infrared light absorbing composition may contain a solvent. The solvent is not particularly limited and can be appropriately selected according to purposes as long as respective components of the infrared light absorbing composition can be evenly dissolved or dispersed in the solvent. For example, water or an organic solvent can be used, and an organic solvent is preferable.

Examples of the organic solvent suitably include alcohols (for example, methanol), ketones, esters, ethers, aromatic hydrocarbons, halogenated hydrocarbons, and dimethylformamide, dimethylacetamide, dimethylsulfoxide, and sulfolane. These may be used alone or may be used in combination of two or more thereof. In a case of using two or more solvents in combination, the organic solvent is preferably a mixed solution of two or more solvents selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, ethylene glycol monobutyl ether acetate, propylene glycol monomethyl ether, and propylene glycol monomethyl ether acetate.

Specific examples of the alcohols, aromatic hydrocarbons, and halogenated hydrocarbons include those described in paragraph 0136 of JP2012-194534A and the like, and the contents thereof are incorporated in the present specification. Specific examples of the esters, ketones, and ethers include those described in paragraph 0497 of JP2012-208494A (<0609> of the present specification of corresponding US Patent App. No. 2012/0235099) and further include n-amyl acetate, ethyl propionate, dimethyl phthalate, ethyl benzoate, methyl sulfate, acetone, methyl isobutyl ketone, diethyl ether, and ethylene glycol monobutyl ether acetate.

The amount of the solvent in the infrared light absorbing composition is preferably an amount in which the solid content of the composition is 10% to 90% by mass. The lower limit is more preferably 20% by mass or more. The upper limit is more preferably 80% by mass or less.

(Surfactant)

The infrared light absorbing composition may contain various surfactants from the viewpoint of further improving coatability.

As the surfactant, various surfactants such as a fluorine-based surfactant, a nonionic surfactant, a cation-based surfactant, an anion-based surfactant, and a silicone-based surfactant can be used.

By incorporating the fluorine-based surfactant in the infrared light absorbing composition, liquid characteristics (particularly, fluidity) in a case where the composition is prepared as a coating liquid are further improved and thus evenness of coating thickness and liquid saving properties can be further improved.

That is, in case of forming a film with a coating liquid using a composition containing the fluorine-based surfactant, the surface tension at the interface between a coated surface and the coating liquid is reduced. Accordingly, wettability to the coated surface is improved and coatability to the coated surface is improved. Therefore, a film that has small unevenness in thickness and has a homogeneous thickness can be more suitably formed.

The content of fluorine in the fluorine-based surfactant is preferably 3% to 40% by mass, more preferably 5% to 30% by mass, and even more preferably 7% to 25% by mass. A fluorine-based surfactant having a fluorine content in the above range is effective from the viewpoint of evenness of the thickness of a coated film and liquid saving properties and the solubility in the composition is also satisfactory.

Specific examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and RS-72-K (all manufactured by DIC Corporation), FLUORAD FC430, FLUORAD FC431, and FLUORAD FC171 (all manufactured by Sumimoto 3M Limited.), SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KH-40 (all manufactured by Asahi Glass Co., Ltd.), and PF636, PF656, PF6320, PF6520, and PF7002 (manufactured by OMNOVA Solutions, Inc.). As the fluorine-based surfactant, a block polymer can be used and specific examples thereof include compounds disclosed JP2011-89090A.

As the fluorine-based surfactant, a fluorine-containing polymer compound can be preferably used, the fluorine-containing polymer compound including: a repeating unit derived from a (meth)acrylate compound having a fluorine atom; and a repeating unit derived from a (meth)acrylate compound having two or more (preferably 5 or more) alkyleneoxy groups (preferably an ethyleneoxy group and a propyleneoxy group). The following compound is also exemplified as the fluorine-based surfactant used in the present invention.

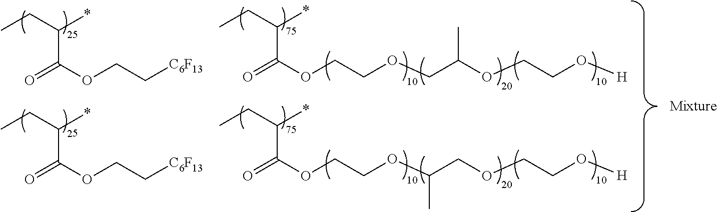

The weight-average molecular weight of the compound is preferably 3,000 to 50,000 and is, for example, 14,000.

In addition, a fluorine-containing polymer having an ethylenically unsaturated group at a side chain thereof can also be used as the fluorine surfactant. Specific examples thereof include compounds described in paragraphs 0050 to 0090 and paragraphs 0289 to 0295 of JP2010-164965A, for example, MEGAFACE RS-101, RS-102, and RS-718K manufactured by DIC Corporation.

Specific examples of the nonionic surfactant include glycerol, trimethylolpropane, trimethylolethane, an ethoxylate and a propoxylate thereof (for example, glycerol propoxylate and glycerin ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid esters (PLURONIC L10, L31, L61, L62, 10R5, 17R2, and 25R2 and TETRONIC 304, 701, 704, 901, 904, and 150R1 (all manufactured by BASF SE)); and SOLSPERSE 20000 (manufactured by Lubrication Technology Inc.). In addition, NCW-101, NCW-1001, and NCW-1002 (manufactured by Wako Pure Chemical Industries, Ltd.) can also be used.

Specific examples of the cationic surfactant include a phthalocyanine derivative (trade name: EFKA-745, manufactured by Morishita Co., Ltd.), an organosiloxane polymer KP341 (manufactured by Shin-Etsu Chemical Co., Ltd.), a (meth)acrylic acid (co)polymer POLYFLOW No. 75, No. 90, or No. 95 (manufactured by Kyoeisha Chemical Co., Ltd.), and W001 (manufactured by Yusho Co., Ltd.).

Specific examples of the anionic surfactant include W004, W005, and W017 (manufactured by Yusho Co., Ltd.), and SANDEDDO BL (manufactured by Sanyo Chemical Industries, Ltd.).

Examples of the silicone surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all manufactured by Dow Corning Corporation), TSF-4440, TSF-4300, TSF-4445, TSF-4460, and TSF-4452 (all manufactured by Momentive Performance Materials Inc.), KP341, KF6001, and KF6002 (all manufactured by Shin-Etsu Chemical Co., Ltd.), and BYK307, BYK323, and BYK330 (all manufactured by BYK-Chemie Japan K.K.).

The surfactant may be used alone or may be used in combination of two or more thereof.

The content of the surfactant is preferably 0.001% to 2.0% by mass and more preferably 0.005% to 1.0% by mass with respect to the total solid content of the composition.

The surfactant may be included not only in the infrared light absorbing layer but also in other layers.

In addition to the above components, the infrared light absorbing composition can further contain, for example, a dispersant, a sensitizer, a crosslinking agent, a curing accelerator, a filler, a thermal curing accelerator, a thermopolymerization inhibitor, a plasticizer, an adhesion accelerator, and other auxiliary agents (for example, conductive particles, a filler, an antifoaming agent, a flame retardant, a leveling agent, a peeling accelerator, an antioxidant, a fragrance, a surface tension adjuster, and a chain transfer agent).

The infrared light absorbing composition can be applied by a coating method such as a dropwise addition method (drop casting), a spin coater, a slit spin coater, a slit coater, screen printing, and applicator coating, and the like.

The dry condition is different depending on respective components, kinds of solvents, use ratio, and the like, the dry condition is at a temperature of 60° C. to 150° C. for about 30 seconds to 15 minutes.

In the method for forming the infrared light absorbing layer, other steps may be included. The other steps are not particularly limited, and can be appropriately selected according to purposes. Examples thereof include a preheating step (prebaking step), a curing treatment step, and a post-heating step (post-baking step).

The heating temperature in the preheating step and the post-heating step is typically 80° C. to 200° C. and is preferably 90° C. to 150° C. The heating time in the preheating step and the post-heating step is typically 30 to 240 seconds and is preferably 60 to 180 seconds.

The curing treatment step is a step of carrying out a curing treatment on a formed film, as necessary. In a case where this treatment is performed, the mechanical strength of the near infrared light absorbing layer is improved. In a case of using an infrared light absorbing composition including a polymerizable compound, it is preferable to perform the curing treatment step.

The curing treatment step is not particularly limited, and can be appropriately selected according to purposes. Examples thereof suitably include an entire surface exposure treatment and an entire surface heating treatment. Here, the expression “exposure” in the present invention is used as a meaning of including not only light in various wavelengths but also radioactive ray irradiation such as electron beams or X-rays.

The exposure is preferably performed through irradiation with radioactive rays and, as the radioactive rays that can be used in the exposure, particularly, ultraviolet rays such as electron beams, KrF, ArF, g-rays, h-rays, or i-rays or visible light are preferably used.

Examples of the exposure method include stepper exposure, exposure using a high pressure mercury lamp, and the like.

The exposure amount is preferably 5 to 3000 mJ/cm², more preferably 10 to 2000 mJ/cm², and even more preferably 50 to 1000 mJ/cm².

Examples of the method of the entire surface exposure treatment include a method for exposing the entire surface of the formed film. In a case where the infrared light absorbing composition contains a polymerizable compound, curing of the polymerizable components in the film is promoted by the entire surface exposure, and curing of the film further proceeds to improve the solvent resistance and the heat resistance of the infrared light absorbing layer.

A device for carrying out the entire surface exposure is not particularly limited, and can be appropriately selected according to purposes, and examples thereof suitably include an ultraviolet (UV) exposure machine such as a high pressure mercury lamp.

Examples of the entire surface heating treatment method include a method for heating the entire surface of the formed film. With the heating of the entire surface, the solvent resistance and the heat resistance of the infrared light absorbing layer are improved.

The heating temperature of the heating of the entire surface is preferably 120° C. to 250° C. and more preferably 160° C. to 220° C. In a case where the heating temperature is 120° C. or higher, the film hardness by the heating treatment is increased and in a case where the heating temperature is 250° C. or lower, decomposition of the components in the film can be suppressed.

The heating time for heating the entire surface is preferably 3 to 180 minutes and more preferably 5 to 120 minutes.

A device for heating the entire surface is not particularly limited, and can be appropriately selected among known devices according to purposes. Examples thereof include a dry oven, and a hot plate.

<Infrared Light Reflecting Layer>

The infrared light reflecting layer 16 is a layer having blocking performance (reflectivity) with respect to light in an infrared range. The infrared light reflecting layer 16 is formed of a laminate in which four layers of a first selective reflection layer 18a, a second selective reflection layer 20a, a first selective reflection layer 18b, and a second selective reflection layer 20b are laminated in this order from the infrared light absorbing layer 14. The first selective reflection layers 18a and 18b are layers which are formed by fixing a liquid crystal phase having a helical axis which rotates in a right direction and selectively reflect right circularly polarized light of a wavelength range in an infrared range. The second selective reflection layers 20a and 20b are layers which are formed by fixing a liquid crystal phase having a helical axis which rotates in a left direction and selectively reflect left circularly polarized light of a wavelength range in an infrared range.

Regarding the rotation direction, right direction rotation or left direction rotation is determined as the infrared light absorbing layer 14 is observed from a side indicated by a white arrow (from the antireflection layer 12) in FIG. 1.

The first selective reflection layers 18a and 18b and the second selective reflection layers 20a and 20b are layers formed by fixing liquid crystal phases (rod-like liquid crystal and disk-like liquid crystal) respectively having helical axes. The liquid crystal phases respectively having helical axes of each selective reflection layer are formed by a laminate of many layers and the liquid crystal compound is arranged such that the direction of the long axis is aligned to be parallel with the layer in one thin layer of the layers, for example. Then, the one thin layer is laminated such that the arrangement directions of the molecules become helical. The helical axis is typically arranged in a direction vertical to the surface of each selective reflection layer. Therefore, any one of the left and right circularly polarized light components corresponding to a helical pitch is selectively reflected.

The first selective reflection layer 18a and the second selective reflection layer 20a have substantially the same helical pitch and the first selective reflection layer 18b and the second selective reflection layer 20b have substantially the same helical pitch.

For example, the first selective reflection layer 18a and the second selective reflection layer 20a reflect a short wavelength in an infrared band and the first selective reflection layer 18b and the second selective reflection layer 20b reflect a long wavelength in an infrared band. That is, light in the infrared band is complimentarily reflected by using the four selective reflection layers.

As described above, in a case where a plurality of first selective reflection layers are included in the infrared light reflecting layer 16, from viewpoint of complimentarily reflecting light in the infrared band, the selective reflection wavelengths of each of the first selective reflection layers are preferably different. Here, the selective reflection wavelengths of two first selective reflection layers are different from each other and a difference between two selective reflection wavelengths is preferably at least more than 20 nm, more preferably 30 nm or more, and even more preferably 40 nm or more.

In a case where a plurality of second selective reflection layers are included in the infrared light reflecting layer 16, similar to the case where a plurality of first selective reflection layers are included in the infrared light reflecting layer, the selective reflection wavelengths of each of the second selective reflection layers are preferably different and the preferred aspect is as described above.

The term “selective reflection wavelength of the selective reflection layer” refers to an average value of two wavelengths showing a radius transmittance represented by the following equation: T½(%) in a case where a minimum value of the transmittance in the selective reflection layer is set to Tmin (%).

Equation for obtaining radius transmittance: T½=100−(100−Tmin)/2

More specifically, the wavelength showing the above-described radius transmittance for one selective reflection layer is present at two sides of a long wavelength side (λ1) and a short wavelength side (λ2), and the value of the selective reflection wavelength is represented by the average value of λ1 and λ2.

In FIG. 1, the aspect in which the infrared light reflecting layer 16 has a four layer structure is shown but there is no limitation to the aspect.

The total layer number of the first selective reflection layer and the second selective reflection layer is not particularly limited and for example, the total layer number of each of the selective reflection layers is preferably 1 to 10 and more preferably 1 to 5.

The total layer number of the first selective reflection layer and the total layer number of the second selective reflection layer are independent and may be the same or different. The total layer number of the first selective reflection layer and the total layer number of the second selective reflection layer are preferably the same.

The infrared light reflecting layer 16 may have two or more sets of one first selective reflection layer and one second selective reflection layer. At this time, it is preferable that the selective reflection wavelengths of the first selective reflection layer and the second selective reflection layer included each set are equal to each other.

In the infrared light reflecting layer 16, the selective reflection wavelength of at least one first selective reflection layer and the selective reflection wavelength of at least one second selective reflection layer are preferably equal to each other. The aspect in which at least one first selective reflection layer and at least one second selective reflection layer have the substantially the same helical pitch and exhibit opposite optical activities is preferable since both left and right circularly polarized light components having the substantially the same wavelength can be reflected.

In addition, the expression that the selective reflection wavelengths of the selective reflection layers are “equal to each other” does not mean that the selective reflection wavelengths are exactly equal to each other, and errors in a range of not causing optical effect are allowable. In the present specification, the expression that the selective reflection wavelengths of two selective reflection layers are “equal to each other” means that a difference between the selective reflection wavelengths of two selective reflection layers is 20 nm or less, and the difference is preferably 15 nm or less, and more preferably 10 nm or less.

In a case where two selective reflection layers whose selective reflection wavelengths are equal to each other and left and right rotations are different are laminated, the transmission spectrum of the laminate exhibits one strong peak in the selective reflection wavelength, and thus this case is preferable from the viewpoint of reflection performance.

The infrared light reflecting layer 16 preferably reflects light having a wavelength of at least 600 to 1200 nm, and the maximum value of the reflectivity of at least one of the first selective reflection layer or the second selective reflection layer at a wavelength of 650 nm to 1200 nm is more preferably 40% or more and even more preferably 45% or more. In all of the first selective reflection layers and all of the second selective reflection layers, the maximum value of the reflectivity at a wavelength of 650 nm to 1200 nm is preferably 40% or more and more preferably 45% or more.

The thickness of the first selective reflection layer and the second selective reflection layer is not particularly limited and is preferably about 1 to 8 μm (preferably about 2 to 7 μm). However, the thickness is not limited to these ranges. The kind and the concentration of a material used for forming each of the first selective reflection layer and the second selective reflection layer (mainly a liquid crystal compound and a chiral agent) and the lie are adjusted and thus each selective reflection layer having a desired helical pitch can be formed.

Each selective reflection layer (the first selective reflection layer and the second selective reflection layer) is preferably a layer in which a cholesteric liquid crystal phase is fixed (a layer in which a cholesteric liquid crystal compound is fixed). That is, the first selective reflection layer is preferably a layer formed by fixing a cholesteric liquid crystal phase having a helical axis which rotates in a right direction and the second selective reflection layer is preferably a layer formed by fixing a cholesteric liquid crystal phase having a helical axis which rotates in a left direction.

Each selective reflection layer is preferably formed by applying a liquid crystal compound having a polymerizable group (cholesteric liquid crystal compound), aligning the compound to a form cholesteric liquid crystal phase and then fixing the cholesteric liquid crystal phase by photopolymerization.

It is preferable to form each selective reflection layer by using a curable (polymerizable) liquid crystal composition. As an example of the liquid crystal composition, an aspect containing at least a rod-like liquid crystal compound having a polymerizable group, an optically active compound (chiral agent), and a polymerization initiator is preferable. Two or more kinds of each component may be included in the composition. For example, a polymerizable liquid crystal compound and a non-polymerizable liquid crystal compound can be used in combination. In addition, a low-molecular-weight liquid crystal compound and a high-molecular-weight liquid crystal compound can be used in combination. Further, in order to improve evenness in alignment, coating suitability, and film hardness, at least one selected from various additives of a horizontal alignment agent, an unevenness preventing agent, a cissing preventing agent, a polymerizable monomer, and the like may be contained. In addition, as necessary, a polymerization inhibitor, an antioxidant, an ultraviolet absorbent, a light stabilizer, a coloring material, a metal oxide fine particle, or the like can be added to the polymerizable liquid crystal composition in a range not causing deterioration in optical performance.

(Liquid Crystal Compound)

The liquid crystal compound that can be used may be a so-called rod-like liquid crystal compound or a so-called disk-like liquid crystal compound, and is not particularly limited. Of these, a rod-like liquid crystal compound is preferable.

Examples of a rod-like liquid crystal compound that can be used in the present invention include a rod-like nematic liquid crystal compound. Preferable examples of the rod-like nematic liquid crystal compound include azomethines, azoxys, cyanobiphenyls, cyanophenyl esters, benzoic acid esters, cyclohexanecarboxylic acid phenyl esters, cyanophenylcyclohexanes, cyano-substituted phenylpyrimidines, alkoxy-substituted phenylpyrimidines, phenyl dioxanes, tolans, and alkenylcyclohexyl benzonitriles. The rod-like nematic liquid crystal compound may be either a low-molecular-weight liquid crystal compound or a high-molecular-weight liquid crystal compound.

The liquid crystal compound may be polymerizable or non-polymerizable and a liquid crystal compound having a polymerizable group is preferably used. As described above, the first selective reflection layer and/or the second selective reflection layer is preferably a layer formed by using a liquid crystal compound having a polymerizable group. That is, the first selective reflection layer and/or the second selective reflection layer is preferably a layer formed by using these liquid crystal compounds having a polymerizable group and polymerizing these compounds.

The polymerizable group includes an unsaturated polymerizable group, an epoxy group, and an aziridinyl group, an unsaturated polymerizable group is preferable, and an ethylenically unsaturated polymerizable group (for example, an acryloyloxy group, or a methacryloyloxy group) is more preferable. The number of polymerizable groups of the liquid crystal compound is preferably 1 to 6 and more preferably 1 to 3.

Specific examples of the liquid crystal compound include compounds described in paragraphs 0031 to 0053 of JP2014-119605A and the contents thereof are incorporated in the present specification.

A bandwidth Δλ of the selective reflection by the first selective reflection layer and the second selective reflection layer is represented by Δλ=Δn×P using a refractive index anisotropy Δn of a liquid crystal compound (for example, a liquid crystal compound having a polymerizable group) to be used and a helical pitch P. Thus, in order to obtain a board bandwidth Δλ, a liquid crystal compound exhibiting high Δn is preferably used. Specifically, Δn of a liquid crystal compound at 30° C. is preferably 0.25 or more, more preferably 0.3 or more, and even more preferably 0.35 or more. The upper limit is not particularly limited and is 0.6 or less in most cases.

The refractive index anisotropy Δn is generally measured according to the method using a wedge-shaped liquid crystal cell described Liquid Crystal Handbook (edited by Liquid crystal handbook editing committee, published by Maruzen), p. 202. In a case where the compound is easily crystallized, the refractive index anisotropy can be measured by performing evaluation using a mixture with other liquid crystal compounds and estimating a value from extrapolation values thereof.

Examples of the liquid crystal compound exhibiting high Δn include compounds described in U.S. Pat. No. 6,514,578B, JP3999400B, JP4117832B, JP4517416B, JP4836335B, JP5411770B, JP5411771B, JP5510321B, JP5705465B, JP5721484B, and JP5723641B.

As another preferred aspect of the liquid crystal compound having a polymerizable group, a compound represented by Formula (5) is exemplified.

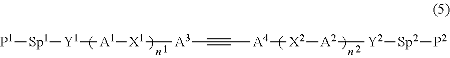

A¹ to A⁴ each independently represent an aromatic carbon ring or a heterocyclic ring which may have a substituent. Examples of the aromatic carbon ring include a benzene ring and a naphthalene ring. Examples of the heterocyclic ring include a furan ring, a thiophene ring, a pyrrole ring, a pyrroline ring, a pyrrolidine ring, an oxazole ring, an isoxazole ring, a thiazole ring, an isothiazole ring, an imidazole ring, an imidazoline ring, an imidazolidine ring, a pyrazole ring, a pyrazoline ring, a pyrazolidine ring, a triazole ring, a furazan ring, a tetrazole ring, a pyran ring, a thiine ring, a pyridine ring, a piperidine ring, an oxazine ring, a morpholine ring, a thiazine ring, a pyridazine ring, a pyrimidine ring, a pyrazine ring, a piperazine ring, and a triazine ring. Among these, A¹ to A⁴ each preferably represent an aromatic carbon ring and more preferably represent a benzene ring.

The kind of the substituent which may be substituted with the aromatic carbon ring or the heterocyclic ring is not particularly limited and examples thereof include a halogen atom, a cyano group, a nitro group, an alkyl group, a halogen-substituted alkyl group, an alkoxy group, an alkylthio group, an acyloxy group, an alkoxycarbonyl group, a carbamoyl group, an alkyl-substituted carbamoyl group, and an acylamino group having 2 to 6 carbon atoms.

X¹ and X² each independently represent a single bond, —COO—, —OCO—, —CH₂CH₂—, —OCH₂—, —CH₂O—, —CH═CH—, —CH═CH—COO—, —OCO—CH═CH—, or —C≡C—. Among these, a single bond, —COO—, or —C≡C— is preferable.

Y¹ and Y² each independently represent a single bond, —O—, —S—, —CO—, —COO—, —OCO—, —CONH—, —NHCO—, —CH═CH—, —CH═CH—COO—, —OCO—CH═CH—, or —C≡C—. Among these, —O— is preferable.

Sp¹ and Sp² each independently represent a single bond, or a carbon chain having 1 to 25 carbon atoms. The carbon chain may be any one of a linear carbon chain, a branched carbon chain, and a cyclic carbon chain. As the carbon chain, a so-called alkyl group is preferable. In the alkyl group, an alkyl group having 1 to 10 carbon atoms is preferable.

P¹ and P² each independently represent a hydrogen atom or a polymerizable group, and at least one of P¹ or P² represents a polymerizable group. Examples of the polymerizable group include polymerizable groups of the above-described liquid crystal compounds having a polymerizable group.

n¹ and n² each independently represent an integer of 0 to 2, and in a case where n¹ or n² is 2, a plurality of A¹'s, A²'s, X¹'s and X²'s may be the same as each other or may be different from each other.

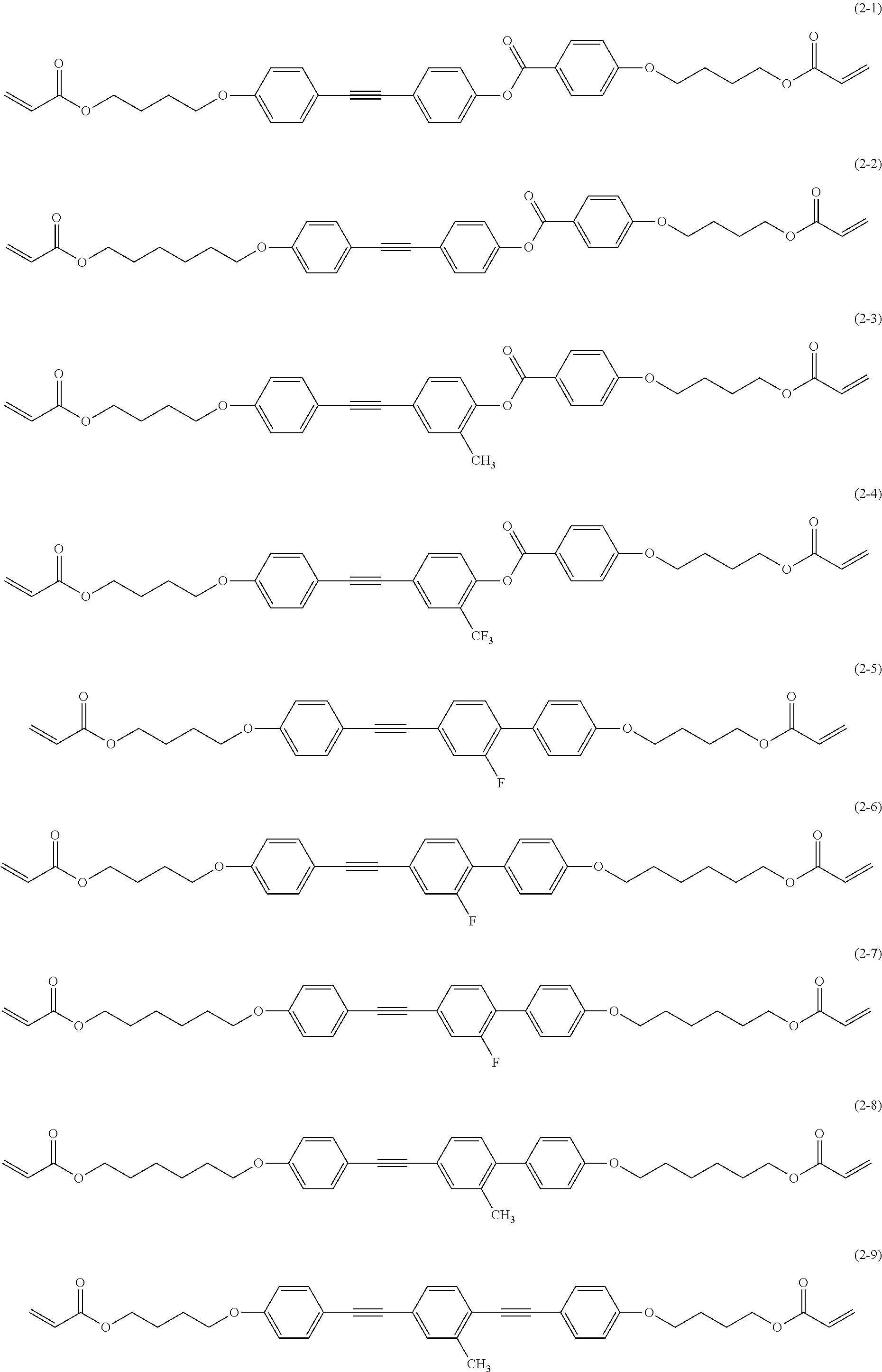

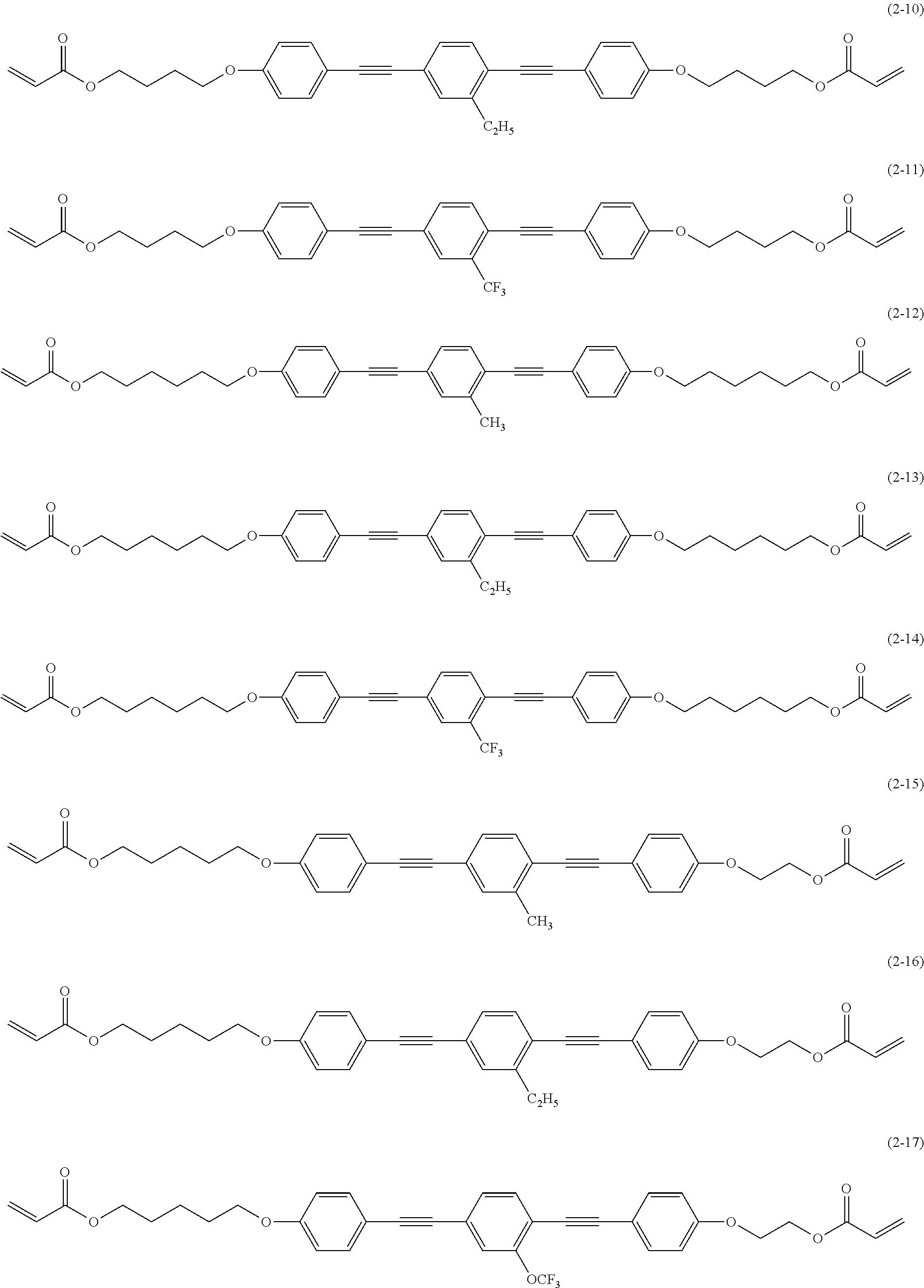

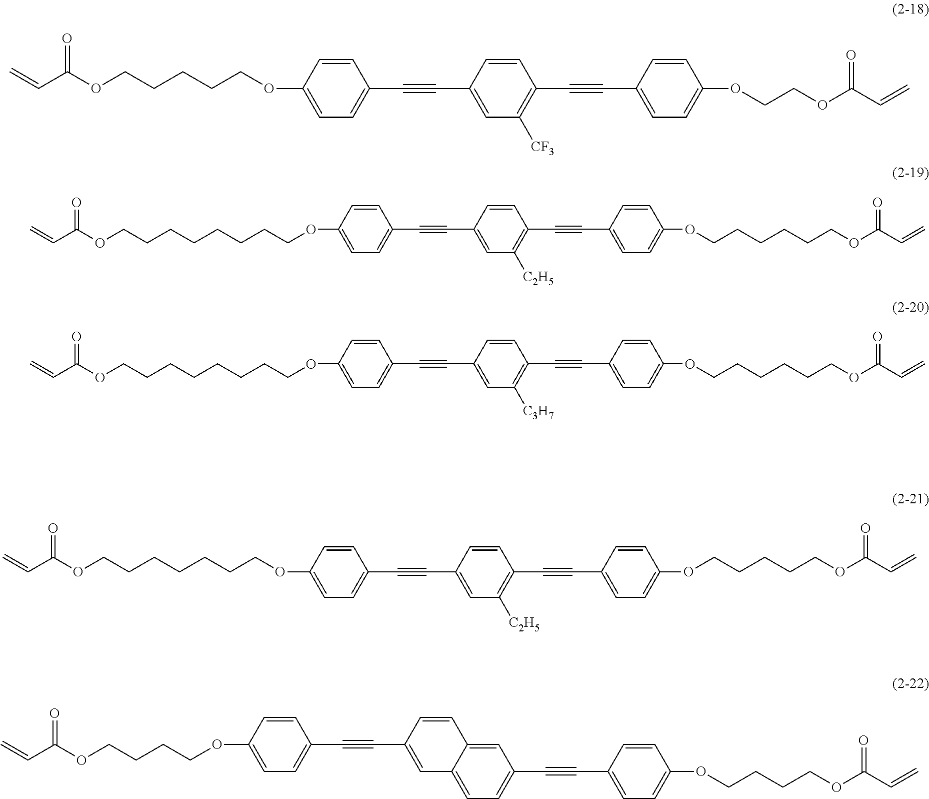

(Chiral Agent)

The liquid crystal composition exhibits a cholesteric liquid crystal phase and in order to exhibit the cholesteric liquid crystal phase, the liquid crystal composition preferably contains a chiral agent (optically active compound). However, in a case where the rod-like liquid crystal compound is a molecule having an asymmetric carbon atom, there may be a case where the composition cannot stably form a cholesteric liquid crystal phase even though a chiral agent is not added thereto. The chiral agent can be selected from various known chiral agents (for example, as described in Liquid crystal Device Handbook, Chapter. 3, Item 4-3, Chiral Agents for Twisted Nematic (TN) and Super-twisted nematic (STN), p. 199, by the 142nd Committee of the Japan Society for the Promotion of Science, 1989). The chiral agent generally contains an asymmetric carbon atom; however, an axial asymmetric compound or a planar asymmetric compound not containing an asymmetric carbon atom can also be used here as the chiral agent. Examples of the axial asymmetric compound or the planar asymmetric compound include binaphthyl, helicene, paracyclophane and derivatives thereof. The chiral agent may have a polymerizable group. In a case where the chiral agent has a polymerizable group and the rod-like liquid crystal compound to be used in combination also has a polymerizable group, a polymer may be formed through a polymerization reaction of the polymerizable chiral agent and the polymerizable rod-like liquid crystal compound, which has a repeating unit derived from the rod-like liquid crystal compound and a repeating unit derived from the chiral agent. In the aspect, the polymerizable group of the polymerizable chiral agent is preferably a group of the same type as that of the polymerizable group of the polymerizable rod-like liquid crystal compound. Accordingly, the polymerizable group of the chiral agent is also preferably an unsaturated polymerizable group, an epoxy group or an aziridinyl group, more preferably an unsaturated polymerizable group, and even more preferably an ethylenically unsaturated polymerizable group.

In addition, the chiral agent may be a liquid crystal compound.

The content of the chiral agent in the liquid crystal composition is preferably 1 to 30 mol % with respect to the liquid crystal compound to be used in combination. It is more preferable that the content of the chiral agent is lower in order that the compound does not have any influence on the liquid crystallinity of the composition. Accordingly, the chiral agent is preferably a compound having a strong torsion force in order that the compound could attain the desired helical pitch torsion alignment even though the amount of the chiral agent used is small. As the chiral agent having such a strong torsion force, for example, chiral agents described in JP2003-287623A may be used, and these can be preferably used in the present invention.

Specific examples of the chiral agent include compounds described in paragraphs 0055 to 0080 of JP2014-119605A, and the contents thereof are incorporated in the present specification.

The chiral agent mainly includes a right rotation chiral agent and a left rotation chiral agent, and it is preferable that a right rotation chiral agent is used in the production of the first selective reflection layer and a left rotation chiral agent is used in the production of the second selective reflection layer.

(Polymerization Initiator)

The liquid crystal composition used for forming each selective reflection layer is preferably a polymerizable liquid crystal composition and for the polymerizable liquid crystal composition, the liquid crystal composition preferably contains a polymerization initiator. In the present invention, it is preferable to conduct a curing reaction by ultraviolet irradiation and the polymerization initiator to be used is preferably a photopolymerization initiator that can initiate a polymerization reaction by ultraviolet irradiation. Examples of the photopolymerization initiator include α-carbonyl compounds (described in each of U.S. Pat. No. 2,367,661A and U.S. Pat. No. 2,367,670A), acyloin ethers (described in U.S. Pat. No. 2,448,828A), an α-hydrocarbon-substituted aromatic acyloin compounds (described in U.S. Pat. No. 2,722,512A), polynuclear quinone compounds (described in U.S. Pat. No. 3,046,127A and U.S. Pat. No. 2,951,758A), a combination of triallylimidazole dimer/p-aminophenyl ketone (described in U.S. Pat. No. 3,549,367A), acridine and phenazine compounds (described in JP1985-105667A (JP-S60-105667A) and U.S. Pat. No. 4,239,850A), and oxadiazole compounds (described in U.S. Pat. No. 4,212,970A).

The amount of the photopolymerization initiator used is preferably 0.1% to 20% by mass and more preferably 1% to 8% by mass with respect to the liquid crystal composition (in a case of a coating liquid, solid content).

(Alignment Controlling Agent)

The liquid crystal composition may contain an alignment controlling agent which contributes to the stable or quick formation of a cholesteric liquid crystal phase. Examples of the alignment controlling agent include a fluorine-containing (meth)acrylate-based polymer. Two or more kinds selected therefrom may be contained. Regarding the compounds, it is possible to reduce or substantially horizontally align the tilt angle of the molecules of the liquid crystal compound at the air interface of the layer. Here, “horizontal alignment” in the present specification indicates that the long axis of the liquid crystal molecules and the film surface are parallel, but there is no strict demand for the horizontal alignment to be parallel and, in the present specification, horizontal alignment has the meaning of an alignment at which an inclined angle made with a horizontal surface is less than 20 degrees. In a case where the liquid crystal compound is horizontally aligned in the vicinity of the air interface, the transparency in the visible light range is high and the reflectivity in the infrared range is increased since alignment defects are not easily generated.

Examples of a fluorine-containing (meth)acrylate-based polymer that can be used as the alignment controlling agent are described in paragraphs <0018> to <0043> of JP2007-272185A and the like.

Specific examples of the alignment controlling agent include compounds described in paragraphs 0081 to 0090 of JP2014-119605A.

(Method for Producing Infrared Light Reflecting Layer)

The method for producing the infrared light reflecting layer is not particularly limited and a method using the above-described liquid crystal composition is suitably used. More specifically, an example of the method for producing the infrared light reflecting layer is a production method which includes at least

(1) applying a curable liquid crystal composition to a surface of a predetermined substrate and setting the composition to a cholesteric liquid crystal phase state and

(2) forming a selective reflection layer by causing a curing reaction of the curable liquid crystal composition to proceed by ultraviolet irradiation and fixing the cholesteric liquid crystal phase.

It is also possible to produce an infrared light reflecting layer having the same constitution shown in FIG. 1 by repeating the steps of (1) and (2) 4 times on one surface of the substrate, while changing the kind of the liquid crystal composition.

The rotation direction of the cholesteric liquid crystal phase can be adjusted according to the kind of a liquid crystal or the kind of a chiral agent to be added, and the helical pitch (that is, central reflection wavelength) can be arbitrarily adjusted according to the material concentration thereof.

A liquid crystal composition including at least a liquid crystal compound and a right rotation chiral agent is preferably used in the production of the first selective reflection layer and a liquid crystal composition including at least a liquid crystal compound and a left rotation chiral agent is preferably used in the production of the second selective reflection layer.

In the step (1), first, a curable liquid crystal composition is applied to the surface of a predetermined substrate. The curable liquid crystal composition is preferably prepared in the form of a coating liquid obtained by dissolving and/or dispersing the material in a solvent. The coating liquid can be applied by various methods such as a wire bar coating method, an extrusion coating method, a direct gravure coating method, a reverse gravure coating method, and a die coating method.

Next, the curable liquid crystal composition which has been applied to the surface to form a coated film is set to a state of a cholesteric liquid crystal phase. In the aspect in which the curable liquid crystal composition is prepared in the form of a coating liquid which includes a solvent, there are cases where it is possible to set the cholesteric liquid crystal phase state by drying the coated film and removing the solvent. In addition, the coated film may be heated as desired to reach the temperature for transition to the cholesteric liquid crystal phase. For example, it is possible to stably set the cholesteric liquid crystal phase state by temporarily heating to the isotropic phase temperature and then cooling to the cholesteric liquid crystal phase transition temperature. The liquid crystal phase transition temperature of the curable liquid crystal composition is preferably in a range of 10° C. to 250° C. and more preferably in a range of 10° C. to 150° C. from the viewpoint of the manufacturing suitability or the like.

Next, in the step (2), the coated film which has been in a state of a cholesteric liquid crystal phase undergoes a curing reaction by the irradiation with ultraviolet rays. For the ultraviolet irradiation, a light source such as an ultraviolet lamp is used. In the step, the curing reaction of the liquid crystal composition is made to proceed by the irradiation with ultraviolet rays, a cholesteric liquid crystal phase is fixed, and a selective reflection layer is formed.

In order to promote the curing reaction, the ultraviolet irradiation may be performed under a condition of heating. In addition, the temperature during ultraviolet irradiation is preferably maintained in a temperature range in which a cholesteric liquid crystal phase is exhibited so as not to disturb the cholesteric liquid crystal phase.

In the step described above, the cholesteric liquid crystal phase is fixed and thus a selective reflection layer is formed. Here, regarding the “fixed” liquid crystal phase state, a state in which the alignment of the liquid crystal compound which is a cholesteric liquid crystal phase is maintained is the most typical and is a preferable aspect thereof. Without only being limited thereto, in detail, the “fixed” liquid crystal phase state has the meaning of a state in which there is no fluidity in the layer in a temperature range of generally 0° C. to 50° C., or under more severe conditions of −30° C. to 70° C. and moreover, in which it is possible to continue to stably keep the form of the alignment fixed without changes in the form of the alignment being generated by an external field or external force. In the present invention, the alignment state of the cholesteric liquid crystal phase is preferably fixed by the curing reaction which proceeds due to the ultraviolet irradiation.

In the present invention, it is sufficient as long as the optical properties of the cholesteric liquid crystal phase are maintained in a layer and it is no longer necessary for the liquid crystal composition in the selective reflection layer to exhibit the liquid crystallinity at the end. For example, the liquid crystal composition may be polymerized by the curing reaction and lose the liquid crystallinity.

The order of producing the first selective reflection layer and the second selective reflection layer is not particularly limited and any of these layers may be produced first (randomly).

<Laminate 10>

The laminate 10 having each member described above has a high transmittance in the visible light range. More specifically, the transmittance at a wavelength of 450 to 650 nm is preferably 90% or more and more preferably 95% or more. The upper limit is not particularly limited and is 100%.

In addition, the laminate 10 has a low transmittance in the infrared range. More specifically, the transmittance at a wavelength of 700 to 1100 nm is preferably 10% or less and more preferably 5% or less. The lower limit is not particularly limited and is 0%.

The transmittance of the laminate 10 is measured in a wavelength range of 300 to 1300 nm using an ultraviolet-visible near infrared spectrophotometer (U-4100 manufactured by Hitachi High-Technologies Corp.) (ref glass substrate).

All the layers constituting the laminate 10 may include a fluorine-containing compound. There may be cases where the infrared light reflecting layer includes a fluorine-containing compound which is unevenly distributed in the vicinity of the interface in order to prevent the alignment of the liquid crystal compound from being disturbed in the vicinity of the interface. There may be also cases where the infrared light absorbing layer and the antireflection layer include a fluorine-containing compound in order to improve coatability.

The term “fluorine-containing compound” is a compound including a fluorine atom.

The laminate 10 may include layers other than the antireflection layer 12, the infrared light absorbing layer 14, and the infrared light reflecting layer 16 described above.

Examples of other layers include a substrate such as a glass substrate or a resin substrate (preferably a transparent substrate), an adhesive layer, an adhesion layer, an undercoat layer, and a hard coat layer.

The laminate 10 can be produced by the respective methods described in the methods for producing each member described above.

More specifically, in order to produce the laminate 10, a kit including a composition for forming a first selective reflection layer (liquid crystal composition), a composition for forming a second selective reflection layer (liquid crystal composition), a composition for forming an infrared light absorbing layer (infrared light absorbing composition), and a composition for forming an antireflection layer (antireflection layer forming composition) is prepared.

Next, each member is formed by using each composition in order. For example, an infrared light reflecting layer may be produced by the above-described method, and then an infrared light absorbing layer may be produced on the produced infrared light reflecting layer by the above-described method. Thereafter, an antireflection layer may be produced on the infrared light absorbing layer by the above-described method.

In a case where the laminate is produced by using various compositions as described above, the laminate can be produced directly on various members.

### Modification Examples of First Embodiment

In the aspect of FIG. 1, the antireflection layer 12, the infrared light absorbing layer 14, and the infrared light reflecting layer 16 are sequentially laminated. However, the present invention is not limited to this aspect. For example, the positions of the infrared light absorbing layer 14 and the infrared light reflecting layer 16 may be reversed.

In addition, the aspect of FIG. 1 has the infrared light absorbing layer 14. However, the present invention is not limited to this aspect. For example, a predetermined infrared absorber may be included any one of the antireflection layer 12 and the infrared light reflecting layer 16 without providing the infrared light absorbing layer 14. In this case, for example, in a case where a predetermined infrared absorber is included in the infrared light reflecting layer 16, the infrared light reflecting layer 16 also has a function of absorbing infrared light.

For example, a predetermined infrared absorber may be included in a base layer, which will be described later, without providing the infrared light absorbing layer 14.

From the viewpoint that the transmittance in the visible light range is higher than the transmittance in the infrared range, an aspect having the infrared light absorbing layer is preferable.

<Use of Laminate>

The laminate can be applied to various uses, for example, an infrared light cut filter, and a heat insulating film.

In a case where the laminate of the present invention is used for an infrared light cut filter, the laminate is used for lenses having a function of absorbing infrared light (a camera lens such as a digital camera, a cellular phone, or a vehicle camera, and an optical lens such as a f-θ lens or a pickup lens), and an optical filter for a semiconductor light receiving element. In addition, the laminate is useful for a noise cut filter for a CCD camera and a filter for a CMOS image sensor.

Further, the laminate can be also preferably used for an organic electroluminescent (organic EL) element, a solar cell, and the like.

<Solid-State Imaging Device>

A solid-state imaging device of the present invention includes the laminate of the present invention. Regarding the details of the solid-state imaging device including the laminate, the descriptions of paragraphs 0106 to 0107 of JP2015-044188A and paragraphs 0010 to 0012 of JP2014-132333A can be referred to and the contents thereof are incorporated in the present specification.

### Second Embodiment

FIG. 2 shows a cross-sectional view of a laminate according to a second embodiment of the present invention.

As shown in FIG. 2, a laminate 100 includes an antireflection layer 12, an infrared light absorbing layer 14, an infrared light reflecting layer 16, and a base layer 22 in this order.

The laminate 100 of the second embodiment has the same members as in the laminate 10 of the above-described first embodiment except for the base layer 22. The same reference symbols are assigned to the same members and the detailed descriptions thereof are omitted. Hereinafter, the aspect of the base layer 22 will be mainly described in detail.

(Base Layer)

The base layer 22 is arranged to be adjacent to the infrared light reflecting layer 16. Since the base layer 22 is arranged to be adjacent to the infrared light reflecting layer 16, the alignment of the liquid crystal compound included in the infrared light reflecting layer 16 is further controlled and the transmission properties of the laminate are more preferable.

The base layer has a function of more accurately regulating the alignment direction of a liquid crystal compound in a liquid crystal phase (particularly a cholesteric liquid crystal phase) in the first selective reflection layer and the second selective reflection layer.

A material used for the base layer is preferably a polymer of an organic compound and a polymer which is crosslinkable itself or a polymer which is a crosslinked by a crosslinking agent is frequently used. Needless to say, a polymer having both functions can be used.

Examples of the polymer include polymers such as polymethyl methacrylate, acrylic acid/methacrylic acid copolymers, styrene/malein imide copolymers, polyvinyl alcohols and denatured polyvinyl alcohols, poly(N-methylol acrylamide), styrene/vinyl toluene copolymers, polyethylene chlorosulfonate, nitrocellulose, polyvinyl chloride, chlorinated polyolefin, polyesters, polyimides, vinyl acetate/vinyl chloride copolymers, ethylene/vinyl acetate copolymers, carboxymethyl cellulose, gelatin, polyethylene, polypropylene and polycarbonate, and compounds such as a silane coupling agent.

The thickness of the base layer is preferably 0.1 to 2.0 μm.

As the base layer, an alignment layer which is subjected to a rubbing treatment (for example, an alignment layer including polyvinyl alcohol) can be used. In addition, as the base layer, a photo alignment layer can be also used.

A preferred aspect of the polymer is preferably a polymer having a polymerizable group.

In addition, another aspect of the polymer is preferably a polymer having a cyclic hydrocarbon group. The cyclic hydrocarbon group may be a non-aromatic cyclic hydrocarbon group or an aromatic cyclic hydrocarbon group.

### Third Embodiment

FIG. 3 shows a cross-sectional view of a laminate according to a third embodiment of the present invention.

As shown in FIG. 3, a laminate 200 includes an antireflection layer 12, an infrared light absorbing layer 14, an infrared light reflecting layer 16, and an antireflection layer 12 in this order.

The laminate 200 of the third embodiment has the same members as in the laminate 10 of the above-described first embodiment except that two antireflection layers 12 are provided. The same reference symbols are assigned to the same members and the detailed descriptions thereof are omitted.

In the third embodiment, the antireflection layer 12 is arranged on each of the surfaces of the infrared light absorbing layer 14 and the surface of the infrared light reflecting layer 16 in the laminate 200. That is, the antireflection layer 12 is arranged on both surfaces of the laminate 200.

In a case where two antireflection layers 12 are arranged as shown in the third embodiment, during light incidence on the laminate 200 and light emission from the laminate 200, reflection of light at the surface of the laminate 200 (particularly visible light) is prevented and thus the transmittance of light which penetrates the laminate 200 (particularly visible light) is improved.

### EXAMPLES

Hereinafter, the present invention will be described in more detail with reference to examples. Materials, use amounts, ratios, treatment contents, treatment sequences, and the like of the following examples can be appropriately changed unless the changes cause deviance from the gist of the present invention. Accordingly, the range of the present invention will not be restrictively interpreted by the following specific examples. In addition, “%” and “parts” are based on mass, unless otherwise specified.

<Preparation of Cholesteric Liquid Crystal Mixture (Coating Liquid (R1))>

The following compound 1, compound 2, fluorine-containing horizontal alignment agent, chiral agent, polymerization initiator, and cyclohexanone were mixed to prepare a coating liquid having the following composition. The obtained coating liquid was used as a coating liquid (R1) as a cholesteric liquid crystal mixture.

| | | |
|---|---|---|
| Compound 1 | 80 | parts by mass |
| Compound 2 | 20 | parts by mass |
| Fluorine-containing horizontal | 0.1 | parts by mass |
| alignment agent 1 | | |
| Fluorine-containing horizontal | 0.007 | parts by mass |
| alignment agent 2 | | |
| Right rotation chiral agent LC756 | 3.95 | parts by mass |
| (manufactured by BASF SE) | | |
| Polymerization initiator | 4 | parts by mass |

| | |
|---|---|
| IRGACURE 819 (manufactured | |
| by Ciba Japan K.K.) | |
| Solvent (cyclohexanone) | amount to make the |
| | solute concentration |
| | of 40% by mass |

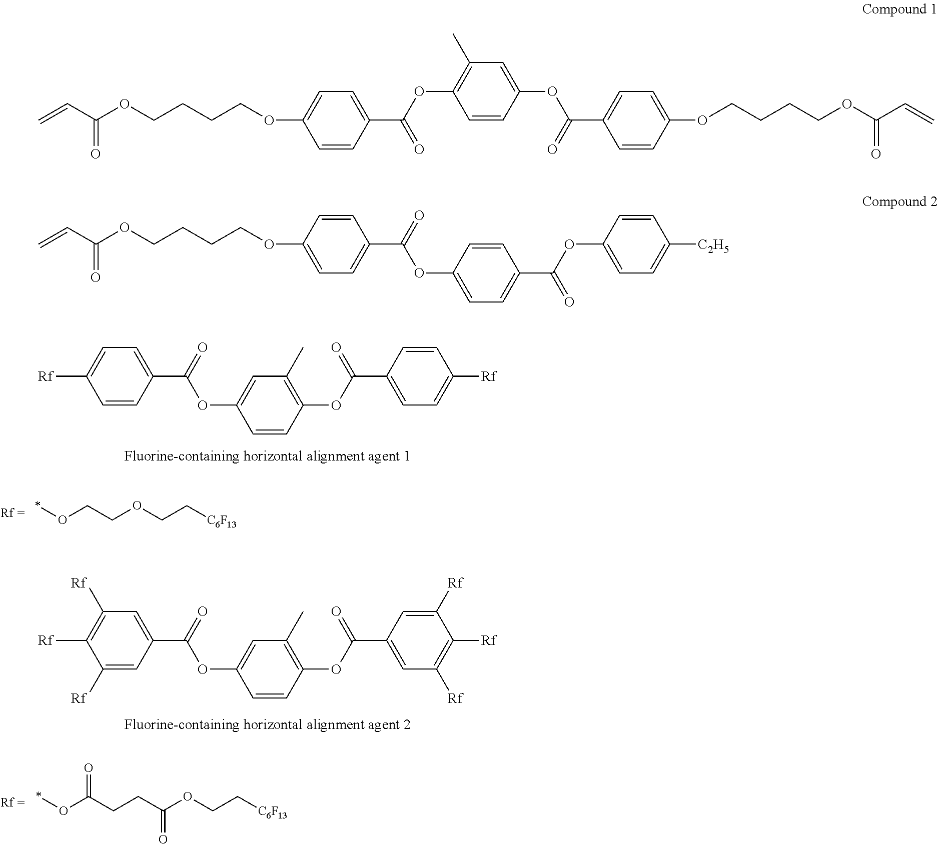

<Preparation of Cholesteric Liquid Crystal Mixture (Coating Liquid (R2))>

A cholesteric liquid crystal mixture (coating liquid (R2)) was prepared in the same manner as in the preparation of the cholesteric liquid crystal mixture (coating liquid (R1)) except that the amount of the right rotation chiral agent LC756 (manufactured by BASF SE) was changed to 3.47 parts by mass.

<Preparation of Cholesteric Liquid Crystal Mixture (Coating Liquid (R3))>

A cholesteric liquid crystal mixture (coating liquid (R3)) was prepared in the same manner as in the preparation of the cholesteric liquid crystal mixture (coating liquid (R1)) except that the amount of the right rotation chiral agent LC756 (manufactured by BASF SE) was changed to 3.10 parts by mass.

<Preparation of Cholesteric Liquid Crystal Mixture (Coating Liquid (R4))>

A cholesteric liquid crystal mixture (coating liquid (R4)) was prepared in the same manner as in the preparation of the cholesteric liquid crystal mixture (coating liquid (R1)) except that the amount of the right rotation chiral agent LC756 (manufactured by BASF SE) was changed to 2.80 parts by mass.

<Preparation of Cholesteric Liquid Crystal Mixture (Coating Liquid (L1))>

The following compound 1, compound 2, fluorine-containing horizontal alignment agent, chiral agent, polymerization initiator, and cyclohexanone were mixed to prepare a coating liquid having the following composition. The obtained coating liquid was used as a coating liquid (L1) as a cholesteric liquid crystal mixture. The “Bu” in the following formula represents a butyl group.

| | | |
|---|---|---|
| Compound 1 | 80 | parts by mass |
| Compound 2 | 20 | parts by mass |
| Fluorine-containing horizontal | 0.1 | parts by mass |
| alignment agent 1 | | |
| Fluorine-containing horizontal | 0.007 | parts by mass |
| alignment agent 2 | | |
| Left rotation chiral agent (A) | 6.0 | parts by mass |
| Polymerization initiator | 4 | parts by mass |

| | |
|---|---|
| IRGACURE 819 (manufactured | |
| by Ciba Japan K.K.) | |
| Solvent (cyclohexanone) | amount to make the |
| | solute concentration |
| | of 40% by mass |

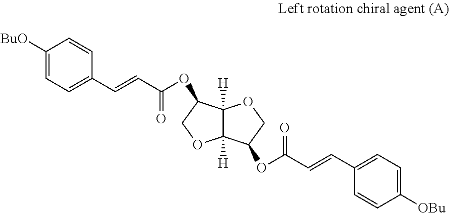

<Preparation of Cholesteric Liquid Crystal Mixture (Coating Liquid (L2))>

A cholesteric liquid crystal mixture (coating liquid (L2)) was prepared in the same manner as in the preparation of the cholesteric liquid crystal mixture (coating liquid (L1)) except that the amount of the left rotation chiral agent (A) was changed to 5.4 parts by mass.

<Preparation of Cholesteric Liquid Crystal Mixture (Coating Liquid (L3))>

A cholesteric liquid crystal mixture (coating liquid (L3 was prepared in the same manner as in the preparation of the cholesteric liquid crystal mixture (coating liquid (L1)) except that the amount of the left rotation chiral agent (A) was changed to 4.7 parts by mass.

<Preparation of Cholesteric Liquid Crystal Mixture (Coating Liquid (L4))>

A cholesteric liquid crystal mixture (coating liquid (L4) was prepared in the same manner as in the preparation of the cholesteric liquid crystal mixture (coating liquid (L1)) except that the amount of the left rotation chiral agent (A) was changed to 4.3 parts by mass.

<Preparation of Composition 1 for Base Layer>

The following components were mixed to prepare a composition 1 for a base layer.

| | | |
|---|---|---|
| CYCLOMER P (manufactured by | 20.3 | parts by mass |
| Daicel Chemical Industries, Ltd.) | | |
| Megafac-F781 (manufactured by | 0.8 | parts by mass |
| DIC Corporation) | | |
| (0.2% by mass propylene glycol | | |
| monomethyl ether acetate solution) | | |
| Propylene glycol monomethyl ether | 78.9 | parts by mass |

<Formation of Infrared Light Reflecting Layer>

The composition 1 for a base layer prepared above was applied to a glass substrate using a spin coater (manufactured by Mikasa Co., Ltd.) at a thickness of 0.1 μm to form a coated film. Next, preheating (prebaking) was performed on the glass substrate having the coated film at 100° C. for 120 seconds. Next, post-heating (post-baking) was performed on the glass substrate having the coated film at 220° C. for 300 seconds to obtain a base layer 1.

The coating liquid (R1) was applied to the glass substrate having the base layer 1 formed thereon by a spin coater at room temperature in such a manner that the film thickness thereof after drying was 5 μm, and thus a coated film was formed. Next, the glass substrate having the coated film was dried at room temperature for 30 seconds to remove the solvent from the coated film and then heated in an atmosphere at 90° C. for 2 minutes to form a cholesteric liquid crystal phase. Subsequently, the coated film was irradiated with UV rays using an electrodeless lamp “D BULB” (90 mW/cm) manufactured by Fusion UV systems, Inc., at an output of 60% for 6 to 12 seconds to fix the cholesteric liquid crystal phase, thereby preparing a cholesteric liquid crystal film (FR1) formed by fixing the cholesteric liquid crystal phase on the glass substrate.

The coating liquid (L1) was applied to the cholesteric liquid crystal film (FR1) by a spin coater at room temperature in such a manner that the film thickness thereof after drying was 5 μm and thus a coated film was formed. Next, the glass substrate having the coated film was dried at room temperature for 30 seconds to remove the solvent from the coated film, and then heated in an atmosphere at 90° C. for 2 minutes to form a cholesteric liquid crystal phase at 35° C. Subsequently, the coated film was irradiated with UV rays using an electrodeless lamp “D BULB” (90 mW/cm) manufactured by Fusion UV systems, Inc., at an output of 60% for 6 to 12 seconds to fix the cholesteric liquid crystal phase, thereby preparing a cholesteric liquid crystal film (FL1).

Through the above treatment, a cholesteric liquid crystal laminate (FRL-1) formed by fixing two layers of cholesteric liquid crystal phase was prepared on the glass substrate. The prepared cholesteric liquid crystal laminate (FRL-1) had a satisfactory surface state not having any significant defects or streaks.

As a result of measuring the transmission spectra of the cholesteric liquid crystal films (FR1) and (FL1), the selective reflection wavelength of each cholesteric liquid crystal film was 750 nm and 755 nm. In addition, as a result of measuring the transmission spectrum of the cholesteric liquid crystal laminate (FRL-1), one strong peak was observed in the vicinity of 750 nm. Thus, it was found that the selective reflection wavelengths of the cholesteric liquid crystal layers formed by applying the coating liquid (R1) and the coating liquid (L1) were equal to each other.

Next, as a result of measuring the haze value of the cholesteric liquid crystal laminate (FRL-1), the average value obtained by measuring the value three times was 0.3%.

Further, as a result of calculating the HTP of the chiral agents used for the coating liquid (R1) and the coating liquid (L1) by the following equation, the HTP of each chiral agent was 54 μm⁻¹ and 35 μm⁻¹ and both HTP values were 30 μm⁻¹ or more.

Regarding the chiral agents used for the coating liquids (R2, R3, R4, L2, L3, and L4), the HTP was calculated in the same manner and as a result, the HTP was 30 μm⁻¹ or more.

Equation: HTP=1/{(helical pitch length (μm))×(% by mass concentration of chiral agent in solid content)}

(where the helical pitch length (μm) was calculated by (selective reflection wavelength (μm))/(average refractive index of solid contents) on the assumption that the average refractive index of solid contents was 1.5.)

Cholesteric liquid crystal films (FR2, FR3, FR4, FL2, FL3, and FL4) were respectively prepared in the same manner as in the preparation of the cholesteric liquid crystal film (FR1) except that the coating liquids (R2, R3, R4, L2, L3, and L4) were used instead of using the coating liquid (R1).

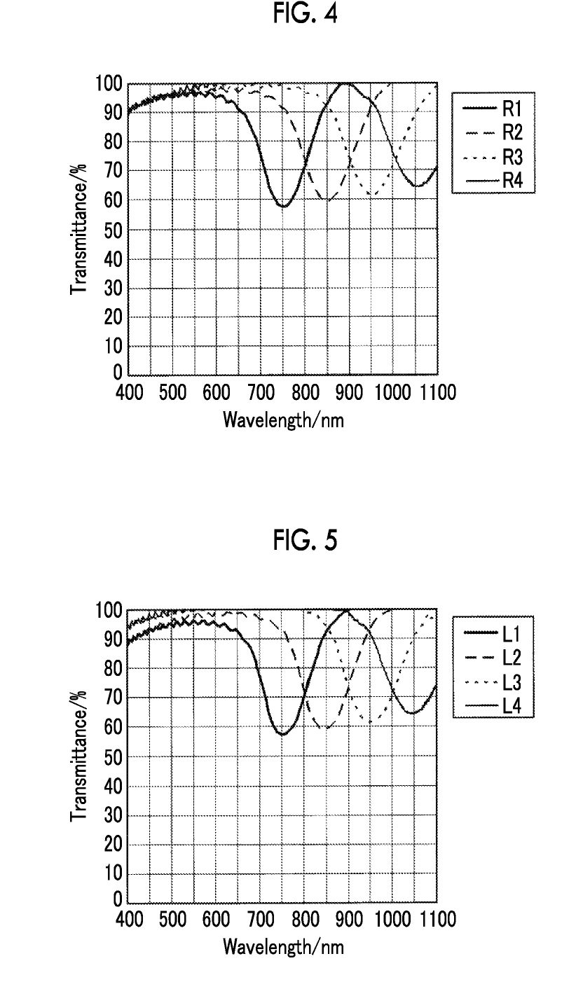

The spectrum measurement results thereof are shown in FIGS. 4 and 5. In FIG. 4, the transmission spectra of the cholesteric liquid crystal films (FR1), (FR2), (FR3), and (FR4) correspond to R1, R2, R3, and R4, respectively. In addition, in FIG. 5, the transmission spectra of the cholesteric liquid crystal films (FL1), (FL2), (FL3), and (FL4) correspond to L1, L2, L3, and L4, respectively.

The selective reflection wavelengths of the cholesteric liquid crystal films (FR2), (FR3), and (FR4) containing the right rotation chiral agent were equal to the selective reflection wavelengths of the cholesteric liquid crystal films (FL2), (FL3), and (FL4) containing the left rotation chiral agent, respectively.

Next, as in the preparation of the cholesteric liquid crystal laminate (FRL-1), the coating liquid (R2) and the coating liquid (L2), the coating liquid (R3) and the coating liquid (L3), and the coating liquid (R4) and the coating liquid (L4) were respectively combined to prepare cholesteric liquid crystal laminates. As a result of measuring the haze values of the prepared laminates (FRL-2, 3, and 4) using a haze meter, the average value of each laminate obtained by measuring the value three times was 0.3%.

<Preparation of Coating Liquid (R5)>

A compound 2-11, a fluorine-containing horizontal alignment agent, a chiral agent, a polymerization initiator, and a solvent were mixed to prepare a coating liquid (R5) having the following composition. The refractive index anisotropy Δn of the following compound 2-11 was 0.375.

| | | |
|---|---|---|
| Compound 2-11 | 100 | parts by mass |
| Fluorine-containing horizontal | 0.1 | parts by mass |
| alignment agent 1 | | |
| Fluorine-containing horizontal | 0.007 | parts by mass |
| alignment agent 2 | | |
| Right rotation chiral agent LC756 | 2.2 | parts by mass |
| (manufactured by BASF SE) | | |
| Polymerization initiator: ADEKA | 4 | parts by mass |

| | |
|---|---|
| ARKLS NCI-831 (manufactured | |
| by ADEKA Corporation) | |
| Solvent (cyclohexanone) | amount to make the |
| | solute concentration |
| | of 40% by mass |

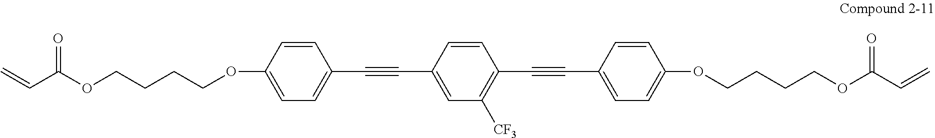 [SMILES: C=CC(=O)OCCCCOc1ccc(C#Cc2ccc(C#Cc3ccc(OCCCCOC(=O)C=C)cc3)c(C(F)(F)F)c2)cc1]

<Preparation of Coating Liquid (L5)>

A compound 2-11, a fluorine-containing horizontal alignment agent, a chiral agent, a polymerization initiator, and a solvent were mixed to prepare a coating liquid (L5) having the following composition.

| | | |
|---|---|---|
| Compound 2-11 | 100 | parts by mass |
| Fluorine-containing horizontal | 0.1 | parts by mass |
| alignment agent 1 | | |
| Fluorine-containing horizontal | 0.007 | parts by mass |
| alignment agent 2 | | |
| Left rotation chiral agent (A) | 3.3 | parts by mass |
| Polymerization initiator: ADEKA | 4 | parts by mass |

| | |
|---|---|
| ARKLS NCI-831 (manufactured by | |
| ADEKA Corporation) | |
| Solvent (cyclohexanone) | amount to make the |
| | solute concentration |
| | of 40% by mass |

<Formation of Infrared Light Reflecting Layer>

Cholesteric liquid crystal films (FR5 and FL5) were respectively prepared in the same manner as in the preparation of the cholesteric liquid crystal film (FR1) except that the coating liquids (R5 and L5) were used instead of using the coating liquid (R1).

The selective reflection wavelength of the cholesteric liquid crystal film (FR5) containing the right rotation chiral agent was equal to the selective reflection wavelength of the cholesteric liquid crystal film (FL5) containing the left rotation chiral agent.

<Preparation of Infrared Light Absorbing Composition 1>

8.04 parts by mass of the following resin A, 1.4 parts by mass of the following infrared absorber 1 (maximum absorption wavelength: 760 nm), 0.07 parts by mass of KAYARAD DPHA (manufactured by Nippon Kayaku Co., Ltd.) as a polymerizable compound, 0.265 parts by mass of MEGAFACE RS-72K (fluorine-containing polymer having an ethylenically unsaturated group at a side chain thereof) (manufactured by DIC Corporation), 0.38 parts by mass of the following compound as a photopolymerization initiator, and 82.51 parts by mass of propylene glycol monomethyl ether acetate (PGMEA) as a solvent were mixed and stirred. Then, the mixture was filtered using a nylon filter having a pore diameter of 0.5 μm (manufactured by NIHON PALL LTD.) to prepare an infrared light absorbing composition 1.

Resin A: Compound (weight-average molecular weight (Mw): 41000) below

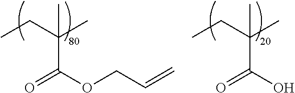

Infrared absorber 1: Structure below

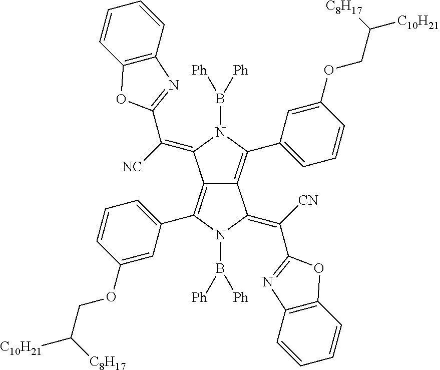

Photopolymerization initiator: Structure below

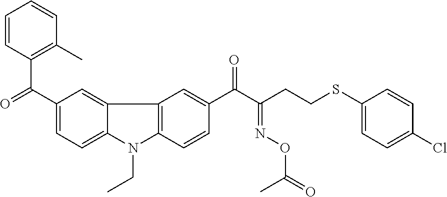 [SMILES: CCn1c2ccc(C(=O)/C(CCSc3ccc(Cl)cc3)=N/OC(C)=O)cc2c2cc(C(=O)c3ccccc3C)ccc21]

<Infrared Light Absorbing Composition 2>

In 69.5 parts by mass of ion exchange water, 0.5 parts by mass of the following infrared absorber 2 (maximum absorption wavelength: 710 nm) was dissolved and further 30.0 parts by mass of a 10% by mass gelatin aqueous solution was added thereto and stirred. Thus, an infrared light absorbing composition 2 was prepared.

Infrared absorber 2: Structure below

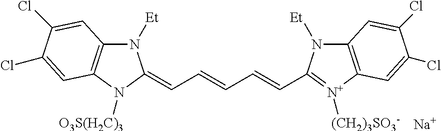

<Infrared Light Absorbing Composition 3>

45 parts by mass of the following infrared absorber 3 (maximum absorption wavelength: 910 nm) (copper complex), 49.9 parts by mass of the following resin, 5 parts by mass of IRGACURE-OXE02 (manufactured by BASF SE), 0.1 parts by mass of tris(2,4-pentandionate)aluminum (III) (manufactured by Toyo Seikan Group Holdings, Ltd.), 66.7 parts by mass of cyclohexanone, and 0.5 parts by mass of water were mixed to prepare an infrared light absorbing composition 3.

Infrared absorber 3 (copper complex): Structure below

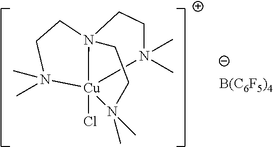

Resin: Structure below

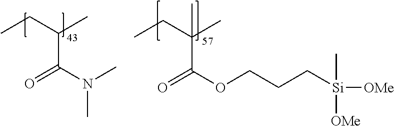

<Infrared Light Absorbing Composition 4>

12.5 parts by mass of the following resin A, 2.38 parts by mass of the following infrared absorber 4 (maximum absorption wavelength: 820 nm), 2.38 parts by mass of KAYARAD DPHA (manufactured by Nippon Kayaku Co., Ltd.) as a polymerizable compound, 2.7 parts by mass of MEGAFACE RS-72K (fluorine-containing polymer having an ethylenically unsaturated group at a side chain thereof) (manufactured by DIC Corporation), 2.61 parts by mass of the following compound as a photopolymerization initiator, and 76.54 parts by mass of propylene glycol monomethyl ether acetate (PGMEA) as a solvent were mixed and stirred. Then, the mixture was filtered using a nylon filter having a pore diameter of 0.5 μm (manufactured by NIHON PALL LTD.) to prepare an infrared light absorbing composition 4.

Infrared absorber 4: Structure below

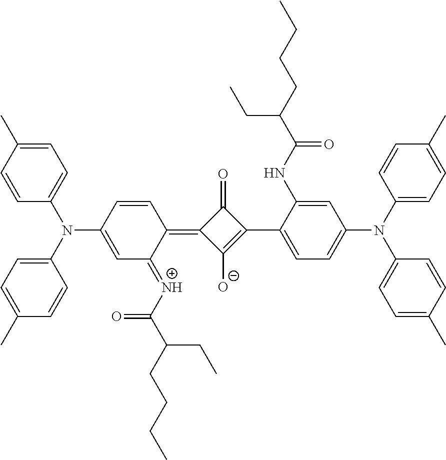 [SMILES: CCCCC(CC)C(=O)Nc1cc(N(c2ccc(C)cc2)c2ccc(C)cc2)ccc1C1=C([O-])/C(=C2/C=CC(N(c3ccc(C)cc3)c3ccc(C)cc3)=C/C2=[NH+]\C(=O)C(CC)CCCC)C1=O]

Photopolymerization initiator: Structure below

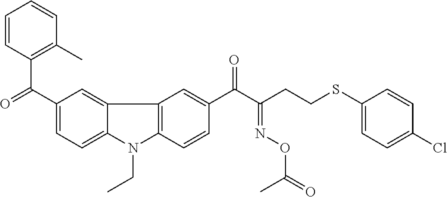 [SMILES: CCn1c2ccc(C(=O)/C(CCSc3ccc(Cl)cc3)=N/OC(C)=O)cc2c2cc(C(=O)c3ccccc3C)ccc21]

<Low Refractive Dispersion 1>

First, tetramethoxysilane (TMOS) was prepared as a silicon alkoxide (A) and trifluoropropyl trimethoxysilane (TFPTMS) was prepared as a fluoroalkyl group-containing silicon alkoxide (B). The materials were weighed such that in a case where the mass of the silicon alkoxide (A) was set to 1, the ratio (mass ratio) of the fluoroalkyl group-containing silicon alkoxide (B) was 0.6, and these materials were put into a separable flask, thereby obtaining a mixture. Propylene glycol monomethyl ether acetate (PGMEA) was added as an organic solvent (E) to the mixture in an amount of 1.0 part by mass with respect to 1 part by mass of the mixture, and the materials were stirred at a temperature of 30° C. for 15 minutes to prepare a first liquid. As the silicon alkoxide (A), an oligomer obtained by polymerizing a monomer thereof to a degree of polymerization of about 3 to 5 in advance was used.

In addition, separately from the first liquid, ion exchange water (C) in an amount of 1.0 part by mass with respect to 1 part by mass of the mixture and formic acid (D) in an amount of 0.01 parts by mass with respect to 1 part by mass of the mixture were put into a beaker and mixed, followed by stirring at a temperature of 30° C. for 15 minutes. Thus, a second liquid was prepared. Next, the temperature of the prepared first liquid was kept at a temperature of 55° C. in a water bath and then the second liquid was added to the first liquid, thereby stirring the liquids for 60 minutes in a state in which the temperature was kept. Thus, a hydrolyzate of the silicon alkoxide (A) and the fluoroalkyl group-containing silicon alkoxide (B) was obtained.

Then, the obtained hydrolyzate and silica sol (F) in which rosary-like colloidal silica particles (average particle diameter of rosary-like particles: 15 nm, D₁/D₂: 5.5, D₁: 80 nm) were dispersed were stirred and mixed at such a ratio that the amount of the SiO₂ component in silica sol (F) was 200 parts by mass with respect to 100 parts by mass of the SiO₂ component in the hydrolyzate, thereby obtaining a low refractive dispersion 1.

The rosary-like colloidal silica particles are formed of a plurality of spherical colloidal silica particles and metal oxide-containing silica which is mutually bonded to the plurality of rosary-like colloidal silica particles. The average particle diameter of the spherical colloidal silica particles measured by a dynamic light scattering method is set to D₁ (nm) and the average particle diameter of the spherical colloidal silica particles obtained from the specific surface area S m²/g of the spherical colloidal silica particles measured by a nitrogen adsorption method by an equation D₂=2720/S is set to D₂ (nm). The details are described in JP2013-253145A.

### Example 1

### Production of Infrared Light Cut Filter>

The coating liquid (R1), the coating liquid (L1), the coating liquid (R2), the coating liquid (L2), the coating liquid (R3), the coating liquid (L3), the coating liquid (R4), and the coating liquid (L4) were sequentially applied and laminated onto on the substrate on which the base layer had been formed in the same procedure as in the above description of <Formation of Infrared Light Reflecting Layer>, and thus an infrared light reflecting layer (F-IR) was produced.

The infrared light absorbing composition 1 was applied to the infrared light reflecting layer (F-IR) by a spin coater (manufactured by Mikasa Co., Ltd.) to form a coated film. Thereafter, preheating (prebaking) was performed on the coated film at 100° C. for 120 seconds and then entire surface exposure was performed at an exposure dose of 1000 mJ/cm² using an i-ray stepper. Next, post-heating (post-baking) was performed at 220° C. for 300 seconds to obtain an infrared light absorbing layer 1 having a film thickness of 0.7 μm.

Further, a low refractive composition 1 prepared in the following procedure was applied to the infrared light absorbing layer 1 using a spin coater (manufactured by Mikasa Co., Ltd.) to form a coated film. Then, preheating (prebaking) was performed on the coated film at 100° C. for 120 seconds. Next, post-heating (post-baking) was performed at 220° C. for 300 seconds and an antireflection layer 1 having a film thickness of 0.1 μm was provided. According to the above procedure, an infrared light cut filter 1 was produced.

<Preparation of Low Refractive Composition 1>

| | | |
|---|---|---|
| Low refractive dispersion 1 | 75.3 | parts by mass |
| Surfactant 1: fluorine- | 0.1 | parts by mass |
| containing surfactant | | |
| Organic solvent 1: | 24.6 | parts by mass |

ethyl lactate

### Example 2

An infrared light cut filter 2 was produced in the same procedure as in Example 1 except that instead of using the infrared light absorbing composition 1, the infrared light absorbing composition 2 was used to form an infrared light absorbing layer 2 in the following procedure.

(Production of Infrared Light Absorbing Layer 2)

The infrared light absorbing composition 2 prepared above was applied to the infrared light reflecting layer (F-IR) using a spin coater (manufactured by Mikasa Co., Ltd.) to form a coated film. Then, preheating (prebaking) was performed on the coated film at 100° C. for 120 seconds. Next, post-heating (post-baking) was performed at 220° C. for 300 seconds to obtain an infrared light absorbing layer 2 having a film thickness of 0.2 μm.

### Example 3

An infrared light cut filter 3 was produced in the same procedure as in Example 1 except that instead of using the infrared light absorbing composition 1, the infrared light absorbing composition 3 was used to form an infrared light absorbing layer 3 in the following procedure.

(Production of Infrared Light Absorbing Layer 3)

The infrared light absorbing composition 3 prepared above was applied to the infrared light reflecting layer (F-IR) using a spin coater in such a manner that the film thickness thereof after drying was 100 μm, and a heating treatment was performed using a hot plate at 150° C. for 3 hours. Thus, the infrared light absorbing layer 3 was prepared.

### Example 4

An infrared light cut filter 4 was produced in the same procedure as in Example 1 except that instead of using the infrared light absorbing composition 1, the infrared light absorbing composition 4 was used to form an infrared light absorbing layer 4 in the following procedure.

(Production of Infrared Light Absorbing Layer 4)

The infrared light absorbing composition 4 was applied to the infrared light reflecting layer (F-IR) using a spin coater (manufactured by Mikasa Co., Ltd.) to form a coated film. Then, preheating (prebaking) was performed on the coated film at 100° C. for 120 seconds. Thereafter, entire surface exposure was performed at an exposure dose of 1000 mJ/cm² using an i-ray stepper. Next, post-heating (post-baking) was performed at 220° C. for 300 seconds to obtain an infrared light absorbing layer 4 having a film thickness of 0.7 μm.

### Example 5

An infrared light cut filter 5 was produced in the same procedure as in Example 1 except that instead of forming the antireflection layer 1, an antireflection layer 2 was formed in the following procedure.

(Preparation of Low Refractive Dispersion 2)

A low refractive dispersion 2 was prepared in the same procedure as in the preparation of the low refractive dispersion 1 except that the rosary-like colloidal silica particles included in the low refractive dispersion 1 were changed to hollow particles. Specifically, the hydrolyzate and the hollow silica particles were stirred and mixed at such a ratio that the amount of the hollow particles was 200 parts by mass with respect to 100 parts by mass of the SiO₂ component in the hydrolyzate and thus a low refractive dispersion 2 was obtained.

A low refractive composition 2 prepared in the following procedure was applied to the infrared light absorbing layer 1 using a spin coater (manufactured by Mikasa Co., Ltd.) to form a coated film. Then, preheating (prebaking) was performed on the coated film at 100° C. for 120 seconds. Thereafter, entire surface exposure was performed at an exposure dose of 1000 mJ/cm² using an i-ray stepper. Subsequently, post-heating (post-baking) was performed at 220° C. for 300 seconds to obtain an antireflection layer 2 having a film thickness of 0.1 μm.

(Preparation of Low Refractive Composition 2)

| | | |
|---|---|---|
| Low refractive dispersion 2 | 50.0 | parts by mass |
| KAYARAD DPHA (manufactured by | 2.7 | parts by mass |
| Nippon Kayaku Co., Ltd.) | | |
| IRGACURE-OXE02 (manufactured | 5.0 | parts by mass |
| by BASF SE) | | |
| Surfactant 1: fluorine-containing surfactant | 0.1 | parts by mass |
| Organic solvent 1: ethyl lactate | 41.9 | parts by mass |

### Example 6

The infrared light cut filter 1 prepared in Example 1 was turned over and the antireflection layer 1 was formed on the substrate surface on which the antireflection layer 1 was not provided in the same procedure as in Example 1 using the low refractive composition 1. Thus, an infrared light cut filter 6 having the antireflection layers 1 formed on both surfaces thereof was obtained.

### Example 7

An infrared light cut filter 7 was produced in the same procedure as in Example 1 except that the base layer 1 was not provided.

### Example 8

An infrared light cut filter 8 was produced in the same procedure as in Example 1 except that instead of forming the antireflection layer 1, an antireflection layer 3 was formed in the following procedure.

(Synthesis of Siloxane Resin)

A hydrolysis condensation reaction was conducted using methyl triethoxysilane. The solvent used at this case was ethanol. The weight-average molecular weight of the obtained siloxane resin A-1 was about 10000. The above weight-average molecular weight was confirmed by gel permeation chromatography (GPC) according to the above-described procedure.

The following composition components were mixed with a stirrer to prepare a low refractive composition 3.

<Preparation of Low Refractive Composition 3>

| | | |
|---|---|---|
| Siloxane resin A-1 | 20 | parts by mass |
| Propylene glycol monomethyl | 64 | parts by mass |
| ether acetate (PGMEA) | | |
| 3-ethoxypropionate (EEP) | 16 | parts by mass |
| Emulsogen COL-020 | 2 | parts by mass |

(manufactured by Clariant)

(Formation of Antireflection Layer 3)

The infrared light absorbing layer 1 was spin-coated with the obtained low refractive composition 3 using a spin coater (manufactured by Mikasa Co., Ltd.) at 1000 rpm to form a coated film. The obtained coated film was heated on a hot plate at 100° C. for 2 minutes and heated at 230° C. for 10 minutes immediately after heating. Thus, an antireflection layer 3 having a film thickness of 0.1 μm was formed.

### Example 9

An infrared light cut filter 9 was produced in the same procedure as in Example 1 except that the infrared light absorbing layer 1 was not provided.

### Example 10

An infrared light cut filter 10 was produced in the same procedure as in Example 1 except that the infrared light absorbing layer 1 was not provided and the base layer 1 was changed to the following base layer 2.

(Preparation of Composition 2 for Base Layer)

The following components were mixed to prepare a composition 2 for a base layer.

| | | |
|---|---|---|
| CYCLOMER P (manufactured by | 20.3 | parts by mass |
| Daicel Chemical Industries, Ltd.) | | |
| Infrared absorber 1 above | 6.0 | parts by mass |
| Megafac-F781 (manufactured | 0.8 | parts by mass |
| by DIC Corporation) | | |
| (0.2 by mass propylene glycol | | |
| monomethyl ether acetate solution) | | |
| Propylene glycol monomethyl ether | 78.9 | parts by mass |

The composition 2 for a base layer prepared above was applied to the glass substrate using a spin coater (manufactured by Mikasa Co., Ltd.) to form a coated film. Then, preheating (prebaking) was performed on the coated film at 100° C. for 120 seconds. Next, post-heating (post-baking) was performed at 220° C. for 300 seconds to obtain a base layer 2 having a film thickness of 0.3 μm.

### Example 11

An infrared light cut filter 11 was produced in the same procedure as in Example 1 except that the infrared light absorbing layer 1 was not provided and the antireflection layer was changed to the following antireflection layer 4.

<Preparation of Low Refractive Composition 4>

| | | |
|---|---|---|
| Low refractive dispersion 1 | 75.3 | parts by mass |
| Infrared absorber 1 above | 3.0 | parts by mass |
| Surfactant 1: fluorine- | 0.1 | parts by mass |
| containing surfactant | | |
| Organic solvent 1: ethyl lactate | 24.6 | parts by mass |

The low refractive composition 4 prepared above was applied to the infrared light reflecting layer (F-IR) using a spin coater (manufactured by Mikasa Co., Ltd.) to form a coated film. Then, preheating (prebaking) was performed on the coated film at 100° C. for 120 seconds. Subsequently, post-heating (post-baking) was performed at 220° C. for 300 seconds to provide an antireflection layer 4 having a film thickness of 0.3 μm.

### Example 12

An infrared light cut filter 12 was produced in the same procedure as in Example 1 except that instead of forming the antireflection layer 1, an antireflection layer 5 was formed in the following procedure.

(Formation of Antireflection Layer 5)

A low refractive material OPSTAR-TU2361 manufactured by JSR Corporation was applied to the infrared light absorbing layer 1 using a spin coater (manufactured by Mikasa Co., Ltd.) to form a coated film having a film thickness of 0.1 μm. Thereafter, the coated film was dried at 60° C. for 1 minute and then entire surface exposure was performed on the coated film at an exposure dose of 300 mJ/cm² under nitrogen purge using an i-ray stepper to form an antireflection layer 5.

### Example 13

### Production of Infrared Light Cut Filter

The coating liquid (R5) and the coating liquid (L5) were sequentially applied and laminated onto the substrate on which the base layer had been formed in the same procedure as in the above description of <Formation of Infrared Light Reflecting Layer>, and thus an infrared light reflecting layer (F-IR-2) was produced.

An infrared light cut filter 13 was produced in the same procedure as in Example 1 except that instead of using the infrared light reflecting layer (F-IR), the infrared light reflecting layer (F-IR-2) was used.

### Comparative Example 1

An infrared light cut filter C1 was produced in the same procedure as in Example 1 except that the antireflection layer was not provided.

### Comparative Example 2

An infrared light cut filter C2 was produced in the same procedure as in Example 1 except that the antireflection layer and the infrared light absorbing layer were not provided.

<<Various Evaluations>>

<Measurement Accuracy>

The transmittance of the infrared light cut filter obtained in each example and comparative example was measured by using an ultraviolet-visible near infrared spectrophotometer (U-4100 manufactured by Hitachi High-Technologies Corp.). A case where a value of (lowest transmittance at 450 to 650 nm)/(highest transmittance 700 to 1100 nm) was 95 or greater was determined as “AA”, a case where the value was less than 95 and 90 or greater was determined as “A”, a case where the value was less than 90 and 80 or greater was determined as “B”, and a case where the value was less than 80 was determined as “C”.

<Productivity>

A case where the number of layers included in the infrared light cut filter obtained in each example and comparative example was 15 or less was determined as “A”, and a case where the number of layers was less than 15 was determined as “B”.

<Angular Dependence>

The incidence angle was changed to being vertical to (at an angle of 0 degree) and an angle of 30 degrees to the surface of the infrared light cut filter and a wavelength shift amount in which the transmittance of the slope was 50% due to a decrease in the spectral transmittance in the visible range at a wavelength of 600 nm or more to the near-infrared range was evaluated based on the following standards. More specifically, the term “shift amount” means a difference between a wavelength position X in which the transmittance at a wavelength of 600 nm or more in a case where an incidence ray was incident on the surface of the infrared light cut filter in a vertical direction was 50%, and a wavelength position Y in which the transmittance at a wavelength of 600 nm or more in a case where an incidence ray was incident on the surface of the infrared light cut filter in an oblique direction was 50%.

A: less than 5 nm

B: 5 nm or more

<Solvent Resistance>

A case where the maximum of a change in transmittance at 400 to 1200 nm in a case where the infrared light cut filter obtained in each example and comparative example was immersed in cyclohexanone for 5 minutes was 1% or less was determined as “A”, a case where the maximum was more than 1% and 5% or less was determined as “B”, and a case where the maximum was more than 5% or less was determined as “C”.

In Table 1, “1” to “3” in the column “infrared light absorbing layer” mean that the infrared light absorbing layers were produced by using the respective infrared light absorbing compositions 1 to 3.

In Table 1, the term “one surface” of “position” in the column of the antireflection layer means that the antireflection layer is arranged on only one outermost surface of the infrared light cut filter and the term “both surfaces” means that the antireflection layers were arranged on both outermost surfaces of the infrared light cut filter.

In Table 1, the term “inorganic particle content” represents a content of inorganic particles (silica particles) in the antireflection layer with respect to the total mass of the antireflection layer.

In Table 1, the symbol “*1” of Example 10 means that infrared absorber 1 is included in the base layer. The symbol “*2” of Example 11 means that the infrared absorber 1 is included in the antireflection layer.

TABLE 1

| | Infrared | Antireflection layer | | | | | | | | |
|---|---|---|---|---|---|---|---|---|---|---|
| | light | Low | | | Inorganic | | Evaluation | | | |
| | absorbing | refractive | Refractive | | particle content | | Pro- | Measurement | Solvent | Angular |
| | layer | composition | index | Position | (% by mass) | Base layer | ductivity | accuracy | resistance | dependence |
| Example 1 | 1 | 1 | 1.2 | One surface | 99 | 1 | A | A | A | A |
| Example 2 | 2 | 1 | 1.2 | One surface | 99 | 1 | A | A | A | A |
| Example 3 | 3 | 1 | 1.2 | One surface | 99 | 1 | A | A | A | A |
| Example 4 | 4 | 1 | 1.2 | One surface | 99 | 1 | A | A | A | A |
| Example 5 | 1 | 2 | 1.3 | One surface | 65 | 1 | A | B | B | A |
| Example 6 | 1 | 1 | 1.2 | Both surfaces | 99 | 1 | A | AA | A | A |
| Example 7 | 1 | 1 | 1.2 | One surface | 99 | Not provided | A | B | A | A |
| Example 8 | 1 | 3 | 1.4 | One surface | — | 1 | A | B | B | A |
| Example 9 | — | 1 | 1.2 | One surface | 99 | 1 | A | B | A | B |
| Example 10 | —(*1) | 1 | 1.2 | One surface | 99 | 2 | A | B | A | A |
| Example 11 | —(*2) | 4 | 1.3 | One surface | 75 | 1 | A | A | B | A |
| Example 12 | 1 | TU2361 | 1.3 | One surface | — | 1 | A | B | A | A |
| Example 13 | 1 | 1 | 1.2 | One surface | 99 | 1 | A | A | A | A |
| Comparative | 1 | — | — | — | — | Provided | A | C | C | A |
| Example 1 | | | | | | | | | | |
| Comparative | — | — | — | — | — | Provided | A | C | C | B |
| Example 2 | | | | | | | | | | |

As shown in Table 1, in the infrared light cut filter of the present invention, it was confirmed that the transmittance in the infrared range was low relative to the transmittance in the visible light range and excellent effect could be obtained.

Particularly, in comparison of Examples 1 and 5, it was confirmed that in a case where the content of the inorganic particles was 70% by mass (more preferably 90% by mass) or more, the solvent resistance was further excellent.

In comparison of Examples 1, 5, and 8, it was confirmed that in a case where the refractive index of the antireflection layer was less than 1.30 (preferably 1.25 or less), the measurement accuracy was further excellent.

In comparison of Examples 1 and 6, it was confirmed that in a case where the antireflection layers were provided both surfaces, the measurement accuracy was further excellent.

In comparison of Examples 1 and 7, it was confirmed that in a case where the base layer was provided, the measurement accuracy was further excellent.

In comparison of Examples 1 and 9, it was confirmed that in a case where the infrared light absorbing layer was provided, the measurement accuracy and the angular dependence were further excellent.

On the other hand, in Comparative Examples 1 and 2 in which the antireflection layer was not provided, the desired effect was not obtained.

### EXPLANATION OF REFERENCES

10, 100, 200: laminate

12: antireflection layer

14: infrared light absorbing layer

16: infrared light reflecting layer

18a, 18b: first selective reflection layer

20a, 20b second selective reflection layer

22: base layer

What is claimed is:

1. A laminate comprising:
an antireflection layer having a refractive index of 1.45 or less; and
an infrared light reflecting layer,
wherein the infrared light reflecting layer includes a first selective reflection layer which is formed by fixing a liquid crystal phase having a helical axis which rotates in a right direction, and a second selective reflection layer which is formed by fixing a liquid crystal phase having a helical axis which rotates in a left direction,
wherein the antireflection layer includes inorganic particles, and
wherein a content of the inorganic particles with respect to a total mass of the antireflection layer is 95% by mass or more.

2. The laminate according to claim 1, wherein at least one of the first selective reflection layer or the second selective reflection layer includes a liquid crystal compound having a refractive index anisotropy Δn of 0.25 or more at 30° C.

3. The laminate according to claim 1,
wherein at least one of the first selective reflection layer or the second selective reflection layer is a layer that is formed by using a compound represented by Formula (5), 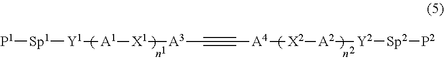
in Formula (5), A¹ to A⁴ each independently represent an aromatic carbon ring or heterocyclic ring which may have a substituent; X¹ and X² each independently represent a single bond, —COO—, —OCO—, —CH₂CH₂—, —OCH₂—, —CH₂O—, —CH═CH—, —CH═CH—COO—, —OCO—CH═CH—, or —C≡C—; Y¹ and Y² each independently represent a single bond, —O—, —S—, —CO—, —COO—, —OCO—, —CONH—, —NHCO—, —CH═CH—, —CH═CH—COO—, —OCO—CH═CH—, or —C≡C—; Sp¹ and Sp² each independently represent a single bond, or a carbon chain having 1 to 25 carbon atoms; P¹ and P² each independently represent a hydrogen atom or a polymerizable group; at least one of P¹ or P² represents a polymerizable group; n¹ and n² each independently represent an integer of 0 to 2; and in a case where n¹ or n² is 2, a plurality of A¹'s, A²'s, X¹'s and X²'s may be the same as each other or different from each other.

4. The laminate according to claim 1,
wherein the antireflection layer or the infrared light reflecting layer includes an infrared absorber, or an infrared light absorbing layer including an infrared absorber is further provided.

5. The laminate according to claim 4,
wherein the infrared absorber has maximum absorption in a wavelength range of 600 to 1200 nm.

6. The laminate according to claim 1,
wherein the inorganic particles are formed of silica.

7. The laminate according to claim 1,
wherein the antireflection layer is a layer that is formed by using a particle aggregate in which a plurality of silica particles are linked in a chain shape.

8. The laminate according to claim 1,
wherein the antireflection layers are respectively arranged on both surfaces of the infrared light reflecting layer.

9. The laminate according to claim 1,
wherein a refractive index of the antireflection layer is 1.35 or less.

10. The laminate according to claim 1,
wherein a refractive index of the antireflection layer is 1.25 or less.

11. The laminate according to claim 1, further comprising:
a base layer which is arranged to be adjacent to the infrared light reflecting layer.

12. The laminate according to claim 1 used for an infrared light cut filter.

13. A solid-state imaging device comprising:
the laminate according to a claims 1.

14. A method for producing the laminate according to claim 4 comprising:
applying a liquid crystal composition including at least a liquid crystal compound and a right rotation chiral agent, and a liquid crystal composition including at least a liquid crystal compound and a left rotation chiral agent in a random order to form the infrared light reflecting layer;
applying an infrared light absorbing composition including an infrared absorber to the infrared light reflecting layer to form the infrared light absorbing layer; and
applying an antireflection layer forming composition including inorganic particles to the infrared light absorbing layer to form the antireflection layer.
